(19) United States
(12) Patent Application Publication
(10) Pub. No.: US 2013/0045445 A1
(43) Pub. Date: Feb. 21, 2013

(54) ACTINIC-RAY- OR RADIATION-SENSITIVE RESIN COMPOSITION, ACTINIC-RAY- OR RADIATION-SENSITIVE RESIN FILM THEREFROM AND METHOD OF FORMING PATTERN USING THE COMPOSITION

(71) Applicants: Toshiya TAKAHASHI, Shizuoka (JP); Hideaki TSUBAKI, Shizuoka (JP); Hiroshi TAMAOKI, Shizuoka (JP); Shuji HIRANO, Shizuoka (JP); Hiroo TAKIZAWA, Shizuoka (JP)

(72) Inventors: Toshiya TAKAHASHI, Shizuoka (JP); Hideaki TSUBAKI, Shizuoka (JP); Hiroshi TAMAOKI, Shizuoka (JP); Shuji HIRANO, Shizuoka (JP); Hiroo TAKIZAWA, Shizuoka (JP)

(73) Assignee: FUJIFILM CORPORATION, Tokyo (JP)

(21) Appl. No.: 13/587,299

(22) Filed: Aug. 16, 2012

(30) Foreign Application Priority Data
Aug. 17, 2011 (JP) 2011-178534

(51) Int. Cl. G03F 7/004; G03F 7/20; G03F 7/027

(52) U.S. Cl. 430/285.1; 430/270.1; 430/281.1; 430/286.1; 430/325

(57) ABSTRACT

Provided is an actinic-ray- or radiation-sensitive resin composition including a resin (P) comprising a repeating unit (A) containing a group that when exposed to actinic rays or radiation, is decomposed to thereby generate an acid and a repeating unit (B) containing a group that when acted on by an acid, is decomposed to thereby increase its solubility in an alkali developer, and any of compounds (Q) of general formula (1) below.

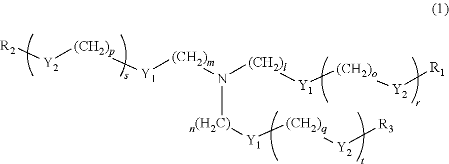

### CROSS-REFERENCE TO RELATED APPLICATIONS

This application is based upon and claims the benefit of priority from prior Japanese Patent Application No. 2011-178534, filed Aug. 17, 2011, the entire contents of which are incorporated herein by reference.

### BACKGROUND OF THE INVENTION

1. Field of the Invention

The present invention relates to an actinic-ray- or radiation-sensitive resin composition, an actinic-ray- or radiation-sensitive resin film therefrom and a method of forming a pattern using the composition. More particularly, the present invention relates to a composition that is suitable for use in, for example, an ultramicrolithography process applicable to a process for manufacturing a super-LSI or a high-capacity microchip, a process for fabricating a nanoimprint mold, a process for producing a high-density information recording medium, etc., and other photofabrication processes, and relates to a relevant film and method of forming a pattern. Further more particularly, the present invention relates to a composition, film and method of forming a pattern that can find appropriate application in, for example, the microfabrication of semiconductor devices by electron beams or soft X-rays such as EUV light.

2. Description of the Related Art

In the microfabrication by lithography, in recent years, the formation of an ultrafine pattern on the order of tens of nanometers is increasingly required in accordance with the realization of high integration for integrated circuits. In accordance with this requirement, the trend of exposure wavelength toward a short wavelength, for example, from g-rays to i-rays and further to a KrF excimer laser light is seen. Moreover, now, the development of lithography using electron beams, X-rays or EUV light besides the excimer laser light is progressing.

Further, the microfabrication using a resist composition is not only directly used in the manufacturing of integrated circuits but also, in recent years, finds application in the fabrication of so-called imprint mold structures, etc.

Basic compounds may be added to the resist compositions (see, for example, patent references 1 to 4). Basic compounds fulfill the role of, for example, quenching any deprotection reaction by an acid generated upon exposure.

In recent years, the lithography using X-rays, soft X-rays or electron beams is positioned as the next-generation or next-next-generation pattern forming technology. When this lithography technology is applied, it is especially an important task to simultaneously attain high sensitivity and favorable performance in pattern shape, roughness characteristic and reduction of residue defects.

### PATENT LITERATURE

Patent reference 1: Jpn. Pat. Appln. KOKAI Publication No. (hereinafter referred to as JP-A-) 2010-77404,
Patent reference 2: JP-A-2010-85971,
Patent reference 3: JP-A-2010-256856, and
Patent reference 4: JP-A-2011-085926.

### Non-Patent Literature

Non-patent reference 1: “Fundamentals of nanoimprint and its technology development/application deployment—technology of nanoimprint substrate and its latest technology deployment” edited by Yoshihiko Hirai, published by Frontier Publishing (issued in June, 2006).

### BRIEF SUMMARY OF THE INVENTION

It is an object of the present invention to provide an actinic-ray- or radiation-sensitive resin composition that can simultaneously attain high sensitivity, favorable pattern shape, favorable roughness characteristic and favorable iso/dense bias characteristic. It is further objects of the present invention to provide an actinic-ray- or radiation-sensitive resin film therefrom and a method of forming a pattern using the composition.

The inventors have conducted extensive and intensive studies with a view toward solving the above problem. As a result, the inventions illustrated below have been completed.

[1] An actinic-ray- or radiation-sensitive resin composition comprising:

a resin (P) comprising a repeating unit (A) containing a group that when exposed to actinic rays or radiation, is decomposed to thereby generate an acid and a repeating unit (B) containing a group that when acted on by an acid, is decomposed to thereby increase its solubility in an alkali developer, and

any of compounds (Q) of general formula (1) below,

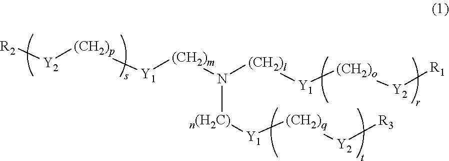

in which

each of l, m, o, p and q independently is an integer of 1 or greater,

n is an integer of 2 or greater,

each of r and s independently is an integer of 1 or greater,

t is an integer of 0 or greater,

each of —Y₁— and —Y₂— independently represents —O—, —S— or —CO—,

each of R₁ and R₂ independently represents a hydrogen atom, an alkyl group, an aryl group or an aralkyl group, and

R₃ represents a hydrogen atom, an alkyl group, an aryl group or an aralkyl group when n is 3 or greater and t is 1 or greater, and represents an alkyl group, an aryl group or an aralkyl group when n is 3 or greater and t is 0, and represents an aryl group or an aralkyl group when n is 2.

[2] The composition according to item [1], wherein the repeating unit (A) is any of repeating units of general formulae (2), (3) and (4) below,

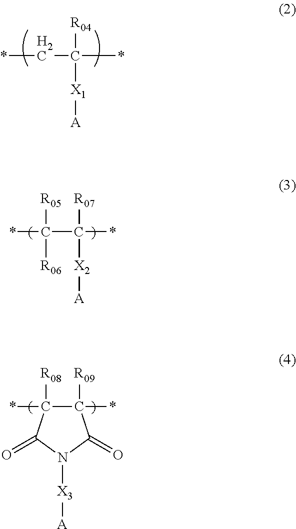

in which

each of R₀₄, R₀₅ and R₀₇ to R₀₉ independently represents a hydrogen atom, an alkyl group, a cycloalkyl group, a halogen atom, a cyano group or an alkoxycarbonyl group,

R₀₆ represents a cyano group, a carboxyl group, —CO—OR₂₅ or —CO—N(R₂₆)(R₂₇) in which R₂₆ and R₂₇ may be bonded to each other to thereby form a ring in cooperation with a nitrogen atom,

each of X₁ to X₃ independently represents a single bond, an arylene group, an alkylene group, a cycloalkylene group, —O—, —SO₂—, —CO—, —N(R₃₃)— or a bivalent connecting group comprised of a combination of these,

R₂₅ represents an alkyl group, a cycloalkyl group, an alkenyl group, an aryl group or an aralkyl group,

each of R₂₆, R₂₇ and R₃₃ independently represents a hydrogen atom, an alkyl group, a cycloalkyl group, an alkenyl group, an aryl group or an aralkyl group, and

A represents a structural moiety that when exposed to actinic rays or radiation, is decomposed to thereby generate an acid.

[3] The composition according to item [1] or [2], wherein R₁ and R₂ are hydrogen atoms.

[4] The composition according to item [3], wherein —Y₁— is —O—.

[5] The composition according to item [4], wherein —Y₂— is —O—.

[6] The composition according to any of items [1] to [5], wherein the repeating unit (B) is expressed by general formula (5) or (6) below,

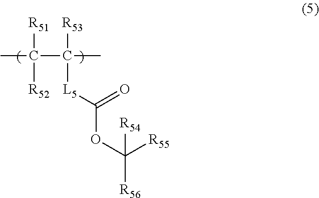

in which

each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents a single bond or a bivalent connecting group,

L₅ represents a single bond or a bivalent connecting group, provided that when a ring is formed in cooperation with R₅₂, L₅ represents a trivalent connecting group, and

R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and provided that R₅₅ and R₅₆ are not simultaneously hydrogen atoms,

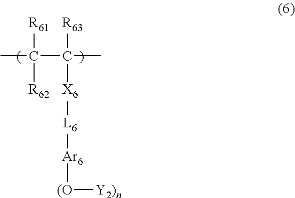

in which,

each of R₆₁, R₆₂ and R₆₃ independently represents a hydrogen atom, an alkyl group, a cycloalkyl group, a halogen atom, a cyano group or an alkoxycarbonyl group, provided that R₆₂ may be bonded to Ar₆ to thereby form a ring, which R₆₂ represents a single bond or a bivalent connecting group,

X₆ represents a single bond, —COO— or —CONR₆₄— in which R₆₄ represents a hydrogen atom or an alkyl group, provided that R₆₄ may be bonded to R₆₂ to thereby form a ring, which R₆₄ represents a single bond or a bivalent connecting group,

L₆ represents a single bond or an alkylene group,

Ar₆ represents a (n+1)-valent aromatic ring group, provided that Ar₆ may be bonded to R₆₂ to thereby form a ring, which Ar₆ represents a (n+2)-valent aromatic ring group,

Y₂, when n≧2 each independently, represents a hydrogen atom or a group that when acted on by an acid, is cleaved, provided that at least one of Y₂s is a group that when acted on by an acid, is cleaved, and

n is an integer of 1 to 4.

[7] The composition according to any of items [1] to [6], wherein the resin (P) further comprises any of repeating units (C) of general formula (7) below,

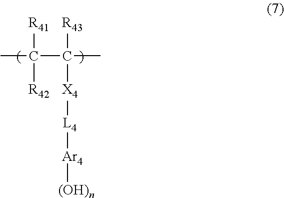

in which

each of R₄₁, R₄₂ and R₄₃ independently represents a hydrogen atom, an alkyl group, a halogen atom, a cyano group or an alkoxycarbonyl group,

X₄ represents a single bond, —COO— or —CONR₆₄— in which R₆₄ represents a hydrogen atom or an alkyl group,

L₄ represents a single bond or an alkylene group,

Ar₄ represents a (n+1)-valent aromatic ring group, provided that Ar₄ may be bonded to R₄₂ to thereby form a ring, which Ar₄ represents a (n+2)-valent aromatic ring group, and

n is an integer of 1 to 4.

[8] The composition according to item [7], wherein the repeating unit (C) has a hydroxystyrene structure.

[9] The composition according to any of items [1] to [8], further comprising a basic compound other than the compounds (Q).

[10] The composition according to item [9], wherein the basic compound contains no hydroxyl group.

[11] The composition according to any of items [1] to [10] for use in a pattern formation including exposure by EUV.

[12] An actinic-ray- or radiation-sensitive resin film formed from the composition according to any of items [1] to [11].

[13] A method of forming a pattern, comprising:

exposing the film according to item [12] to light, and

developing the exposed film.

[14] The method according to item [13], wherein the exposure is carried out by EUV light.

The present invention has made it feasible to provide an actinic-ray- or radiation-sensitive resin composition that can simultaneously attain high sensitivity, favorable pattern shape, favorable roughness characteristic and favorable iso/dense bias characteristic and to provide an actinic-ray- or radiation-sensitive resin film therefrom and a method of forming a pattern using the composition.

### DETAILED DESCRIPTION OF THE INVENTION

Embodiments of the present invention will be described in detail below.

Herein, the groups and atomic groups for which no statement is made as to substitution or nonsubstitution are to be interpreted as including those containing no substituents and also those containing substituents. For example, the “alkyl groups” for which no statement is made as to substitution or nonsubstitution are to be interpreted as including not only the alkyl groups containing no substituents (unsubstituted alkyl groups) but also the alkyl groups containing substituents (substituted alkyl groups).

Further, herein, the term “actinic rays” or “radiation” means, for example, brightline spectra from a mercury lamp, far ultraviolet represented by an excimer laser, soft X-rays such as extreme ultraviolet (EUV) light, X-rays, or electron beams (EB). The term “light” means actinic rays or radiation. The term “exposure to light” means not only irradiation with light, such as light from a mercury lamp, far ultraviolet, X-rays or EUV light, but also lithography using particle beams, such as electron beams and ion beams.

The actinic-ray- or radiation-sensitive resin composition of the present invention comprises [1] a resin (P) comprising a repeating unit (A) containing a group that when exposed to actinic rays or radiation, is decomposed to thereby generate an acid and a repeating unit (B) containing a group that when acted on by an acid, is decomposed to thereby increase its solubility in an alkali developer, and [2] a basic compound (Q) with a structure to be specified hereinafter.

The inventors have found that high sensitivity, favorable pattern shape, favorable roughness characteristic and favorable iso/dense bias characteristic can be simultaneously attained by the use of a composition comprising a resin (P) comprising a repeating unit (A) containing a group that when exposed to actinic rays or radiation, is decomposed to thereby generate an acid together with a basic compound (Q) with a specified structure. Further, the inventors have found that this effect can be exerted particularly strikingly when a pattern is formed on an acidic substrate.

The above components of the composition will be described in sequence below.

[1] Resin

The composition of the present invention comprises a resin (P).

<Repeating Unit (A)>

The resin (P) comprises a repeating unit (A) containing a group that when exposed to actinic rays or radiation, is decomposed to thereby generate an acid.

The repeating unit (A) is not limited as long as it contains a group that when exposed to actinic rays or radiation, is decomposed to thereby generate an acid. Preferably, the repeating unit (A) is one having a structure that when exposed to actinic rays or radiation, generates an acid anion in a side chain of the resin.

It is preferred for the repeating unit (A) to be, for example, one expressed by any of general formulae (2) to (4) below.

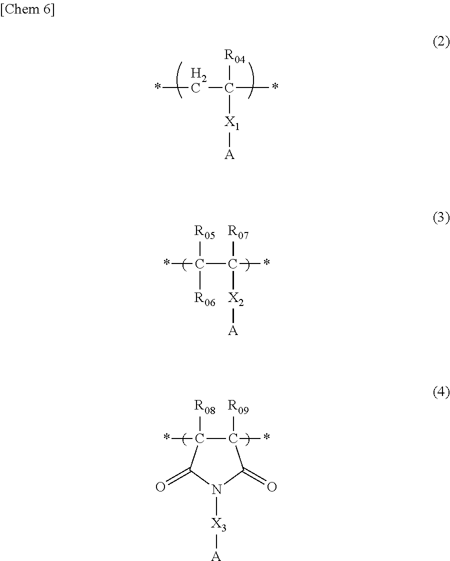

In the formulae, each of R₀₄, R⁰⁵ and R₀₇ to R₀₉ independently represents a hydrogen atom, an alkyl group, a cycloalkyl group, a halogen atom, a cyano group or an alkoxycarbonyl group.

R₀₆ represents a cyano group, a carboxyl group, —CO—OR₂₅ or —CO—N(R₂₆)(R₂₇). R₂₆ and R₂₇ may be bonded to each other to thereby form a ring in cooperation with the nitrogen atom.

Each of X₁ to X₃ independently represents a single bond, an arylene group, an alkylene group, a cycloalkylene group, —O—, —SO₂—, —CO—, —N(R₃₃)— or a bivalent connecting group comprised of a combination of these.

R₂₅ represents an alkyl group, a cycloalkyl group, an alkenyl group, an aryl group or an aralkyl group.

Each of R₂₆, R₂₇ and R₃₃ independently represents a hydrogen atom, an alkyl group, a cycloalkyl group, an alkenyl group, an aryl group or an aralkyl group.

A represents a structural moiety that when exposed to actinic rays or radiation, is decomposed to thereby generate an acid.

The alkyl group represented by each of R₀₄, R₀₅ and R₀₇ to R₀₉ in general formulae (2) to (4) above is preferably an optionally substituted one having 20 or less carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having 8 or less carbon atoms is more preferred.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. Among these, a fluorine atom is most preferred.

The alkyl group contained in the alkoxycarbonyl group is preferably the same as the alkyl group represented by each of R₀₄, R₀₅ and R₀₇ to R₀₉.

The alkyl group represented by each of R₂₅ to R₂₇ and R₃₃ is preferably an optionally substituted one having 20 or less carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having 8 or less carbon atoms is more preferred.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

The alkenyl group is preferably an optionally substituted one having 2 to 6 carbon atoms, such as a vinyl group, a propenyl group, an allyl group, a butenyl group, a pentenyl group, a hexenyl group or a cyclohexenyl group.

The aryl group is preferably an optionally substituted monocyclic or polycyclic aromatic group having 6 to 14 carbon atoms. As the aryl group, there can be mentioned, for example, a phenyl group, a tolyl group, a chlorophenyl group, a methoxyphenyl group, a naphthyl group or the like. Aryl groups may be bonded to each other to thereby form a bi-ring.

As the aralkyl group, there can be mentioned an optionally substituted one having 7 to 15 carbon atoms, such as a benzyl group, a phenethyl group or a cumyl group.

The ring formed by the mutual bonding of R₂₆ and R₂₇ in cooperation with a nitrogen atom is preferably a 5- to 8-membered ring. In particular, there can be mentioned, for example, pyrrolidine, piperidine or piperazine.

The arylene group represented by each of X₁ to X₃ is preferably an optionally substituted one having 6 to 14 carbon atoms. As this arylene group, there can be mentioned, for example, a phenylene group, a tolylene group, a naphthylene group or the like.

The alkylene group may be linear or branched. The linear alkylene group preferably has 2 to 20 carbon atoms, more preferably 3 to 18 carbon atoms and further more preferably 4 to 16 carbon atoms. The branched alkylene group preferably has 4 to 20 carbon atoms, more preferably 5 to 18 carbon atoms. As this alkylene group, there can be mentioned, for example, an ethylene group, a propylene group, a butylene group, a hexylene group, an octylene group or the like.

The cycloalkylene group is preferably an optionally substituted one having 5 to 8 carbon atoms, such as a cyclopentylene group or a cyclohexylene group.

As preferred examples of substituents that may be introduced in the individual groups in general formulae (2) to (4) above, there can be mentioned a hydroxyl group; a halogen atom (fluorine, chlorine, bromine or iodine); a nitro group; a cyano group; an amido group; a sulfonamido group; any of the alkyl groups mentioned above as being represented by R₀₄ to R₀₉, R₂₅ to R₂₇ and R₃₃; an alkoxy group, such as a methoxy group, an ethoxy group, a hydroxyethoxy group, a propoxy group, a hydroxypropoxy group or a butoxy group; an alkoxycarbonyl group, such as a methoxycarbonyl group or an ethoxycarbonyl group; an acyl group, such as a formyl group, an acetyl group or a benzoyl group; an acyloxy group, such as an acetoxy group or a butyryloxy group; and a carboxyl group. Each of these substituents preferably has 8 or less carbon atoms.

A represents a structural moiety that when exposed to actinic rays or radiation, is decomposed to thereby generate an acid. For example, there can be mentioned any of the structural moieties introduced in a photoinitiator for photocationic polymerization, a photoinitiator for photoradical polymerization, a photo-achromatic agent and photo-discoloring agent for dyes and any of generally known compounds that when exposed to light, generate an acid, employed in microresists, etc.

The structural moiety represented by A is preferably an ionic one, more preferably a structural moiety that when exposed to actinic rays or radiation, generates an acid in a side chain of resin.

As the structural moiety that when exposed to actinic rays or radiation, generates an acid in a side chain of resin, there can be mentioned, for example, an onium structural moiety, such as a diazonium salt, an ammonium salt, a phosphonium salt, an iodonium salt, a sulfonium salt, a selenonium salt or an arsonium salt.

More preferably, A is an ionic structural moiety containing a sulfonium salt or an iodonium salt. In particular, it is preferred for A that when exposed to actinic rays or radiation, generates an anion in a side chain to be any of the groups of general formulae (ZI) and (ZII) below. In the formulae, the line extending from Z⁻ to the left represents a bonding hand extending toward the principal chain of the repeating unit (A).

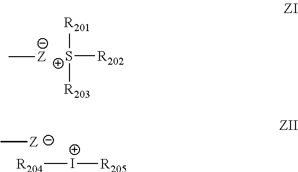

In general formula (ZI) above,

each of R₂₀₁, R₂₀₂ and R₂₀₃ independently represents an organic group.

The number of carbon atoms of each of the organic groups represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure, and the ring within the same may contain an oxygen atom, a sulfur atom, an ester bond, an amido bond or a carbonyl group. As the group formed by bonding of two of R₂₀₁ to R₂₀₃, there can be mentioned an alkylene group (for example, a butylene group or a pentylene group).

Z⁻ represents an acid anion occurring as a result of decomposition upon exposure to actinic rays or radiation. Z⁻ is preferably a normucleophilic anion. As the normucleophilic anion, there can be mentioned, for example, a sulfonate anion, a carboxylate anion, a phosphate anion, a sulfonylimide anion, a bis(alkylsulfonyl)imide anion, a tris(alkylsulfonyl)methyl anion or the like.

The nonnucleophilic anion is an anion whose capability of inducing a nucleophilic reaction is extremely low and is an anion capable of inhibiting any temporal decomposition by intramolecular nucleophilic reaction. This enhances the temporal stability of the resist and thus the temporal stability of the composition.

The organic groups represented by R₂₀₁, R₂₀₂ and R₂₀₃ include an aryl group, an alkyl group, a cycloalkyl group, a cycloalkenyl group, an indolyl group and the like. With respect to the cycloalkyl group and cycloalkenyl group, at least one of the carbon atoms constituting the ring may be a carbonyl carbon.

Preferably, at least one of R₂₀₁, R₂₀₂ and R₂₀₃ is an aryl group. More preferably, all three of R₂₀₁ to R₂₀₃ are aryl groups.

Each of the aryl groups represented by R₂₀₁, R₂₀₂ and R₂₀₃ is preferably a phenyl group or a naphthyl group, more preferably a phenyl group.

Among the alkyl groups, cycloalkyl groups and cycloalkenyl groups represented by R₂₀₁, R₂₀₂ and R₂₀₃, a linear or branched alkyl group having 1 to 10 carbon atoms (for example, a methyl group, an ethyl group, a propyl group, a butyl group or a pentyl group), a cycloalkyl group having 3 to 10 carbon atoms (for example, a cyclopentyl group, a cyclohexyl group or a norbonyl group) and a cycloalkenyl group having 3 to 10 carbon atoms (for example, a pentadienyl group or a cyclohexenyl group) ate preferred.

Substituents may further be introduced in these organic groups, such as aryl, alkyl, cycloalkyl, cycloalkenyl and indolyl groups, represented by R₂₀₁, R₂₀₂ and R₂₀₃. As the substituents, there can be mentioned a nitro group, a halogen atom such as a fluorine atom, a carboxyl group, a hydroxyl group, an amino group, a cyano group, an alkyl group (preferably having 1 to 15 carbon atoms), an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an arylthio group (preferably having 6 to 14 carbon atoms), a hydroxyalkyl group (preferably having 1 to 15 carbon atoms), an alkylcarbonyl group (preferably having 2 to 15 carbon atoms), a cycloalkylcarbonyl group (preferably having 4 to 15 carbon atoms), an arylcarbonyl group (preferably having 7 to 14 carbon atoms), a cycloalkenyloxy group (preferably having 3 to 15 carbon atoms), a cycloalkenylalkyl group (preferably having 4 to 20 carbon atoms) and the like. The appropriate substituents are not limited to these.

With respect to the cycloalkyl and cycloalkenyl groups as the substituents that may further be introduced in the groups represented by R₂₀₁, R₂₀₂ and R₂₀₃, at least one of the carbon atoms constituting the ring may be a carbonyl carbon.

Still further substituents may be introduced in the substituents that may be introduced in the groups represented by R₂₀₁, R₂₀₂ and R₂₀₃. Examples of such still further substituents are the same as those mentioned above in connection with the substituents that may be introduced in the groups represented by R₂₀₁, R₂₀₂ and R₂₀₃. Such still further substituents are preferably an alkyl group and a cycloalkyl group.

When at least one of R₂₀₁ to R₂₀₃ is not an aryl group, as preferred structures, there can be mentioned cationic structures, such as the compounds set forth in sections 0046 and 0047 of JP-A-2004-233661 and sections 0040 to 0046 of JP-A-2003-35948, the compounds of formulae (I-1) to (1-70) shown as examples in US Patent Application Publication No. 2003/0224288 and the compounds of formulae (IA-1) to (IA-54) and (IB-1) to (IB-24) shown as examples in US Patent Application Publication No. 2003/0077540.

In general formula (ZII) above, each of R₂₀₄ and R₂₀₅ independently represents an aryl group, an alkyl group or a cycloalkyl group. These aryl, alkyl and cycloalkyl groups are the same as set forth above in connection with R₂₀₁ to R₂₀₃ of general formula (ZI).

Each of the aryl groups represented by R₂₀₄ to R₂₀₇ may be an aryl group with a heterocyclic structure containing an oxygen atom, a nitrogen atom, a sulfur atom or the like. As the aryl group with a heterocyclic structure, there can be mentioned, for example, a pyrrole residue (group formed by the loss of one hydrogen atom from pyrrole), a furan residue (group formed by the loss of one hydrogen atom from furan), a thiophene residue (group formed by the loss of one hydrogen atom from thiophene), an indole residue (group formed by the loss of one hydrogen atom from indole), a benzofuran residue (group formed by the loss of one hydrogen atom from benzofuran), a benzothiophene residue (group formed by the loss of one hydrogen atom from benzothiophene) or the like.

Substituents may further be introduced in the aryl, alkyl and cycloalkyl groups represented by R₂₀₄ and R₂₀₅. The substituents are also the same as those optionally introduced in the aryl, alkyl and cycloalkyl groups represented by R₂₀₁ to R₂₀₃ of general formula (ZI) above.

Z⁻ represents an acid anion generated by the decomposition upon exposure to actinic rays or radiation, preferably a normucleophilic anion. As such, there can be mentioned any of those set forth above in connection with Z⁻ of general formula (ZI).

As other preferred examples of A that when exposed to actinic rays or radiation, generates a cation in a side chain, there can be mentioned the groups of general formulae (ZCI) and (ZCII) below. In the formulae, the line extending from S⁺ or I⁺ to the left represents a bonding hand extending toward the principal chain of the repeating unit (A).

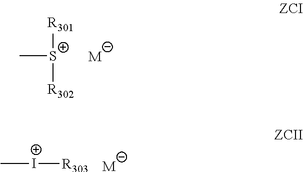

In general formulae (ZCI) and (ZCII) above,

each of R₃₀₁ and R₃₀₂ independently represents an organic group.

Each of the organic groups represented by R₃₀₁ and R₃₀₂ has generally 1 to 30 carbon atoms, preferably 1 to 20 carbon atoms.

R₃₀₁ and R₃₀₂ may be bonded to each other to thereby form a ring structure. An oxygen atom, a sulfur atom, an ester bond, an amido bond or a carbonyl group may be contained in the ring. As the group formed by the bonding, there can be mentioned an alkylene group (for example, a butylene group or a pentylene group).

As particular examples of the organic groups represented by R₃₀₁ and R₃₀₂, there can be mentioned, for example, the aryl groups, alkyl groups, cycloalkyl groups, etc. mentioned above as examples of R₂₀₁ to R₂₀₃ in general formula (ZI) above.

M⁻ represents a normucleophilic anion-containing compound. As the same, there can be mentioned, for example, a sulfonate anion-containing compound, a carboxylate anion-containing compound, a phosphate anion-containing compound, a sulfonylimido anion-containing compound, a bis(alkylsulfonyl)imido anion-containing compound, a tris(alkylsulfonyl)methyl anion-containing compound or the like.

R₃₀₃ represents an organic group. The organic group represented by R₃₀₃ has generally 1 to 30 carbon atoms, preferably 1 to 20 carbon atoms. As particular examples of the organic groups represented by R₃₀₃, there can be mentioned, for example, the aryl groups, alkyl groups, cycloalkyl groups, etc. mentioned above as examples of R₂₀₄ and R₂₀₅ in general formula (ZII) above.

Using the resin (P) comprising the repeating unit (A) containing a group that when exposed to actinic rays or radiation, is decomposed to thereby generate an acid is especially effective in the inhibition of any diffusion of generated acid leading to enhancements of resolution and line edge roughness.

Nonlimiting preferred specific examples of the groups A are shown below.

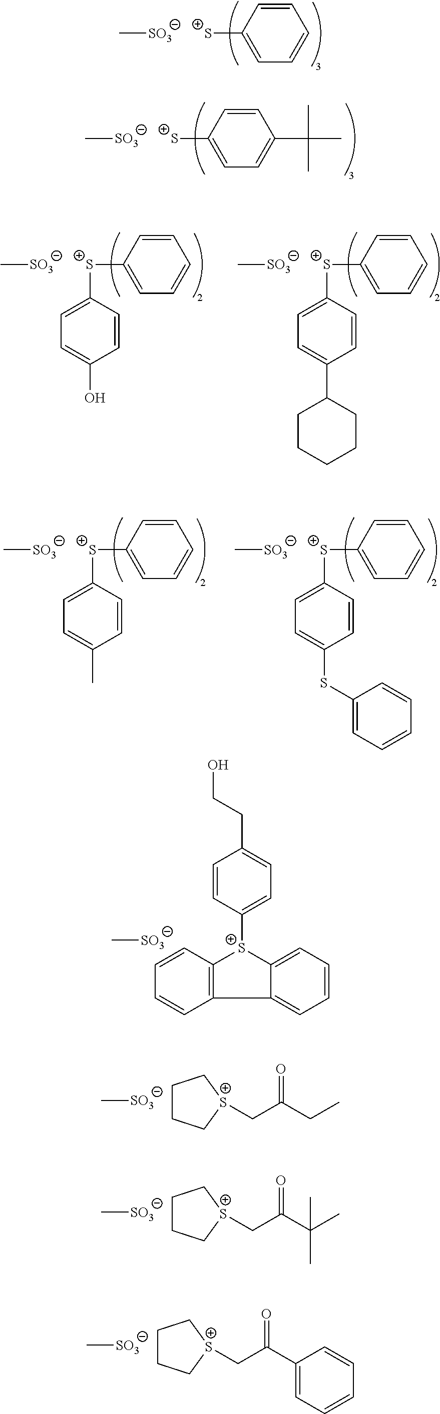

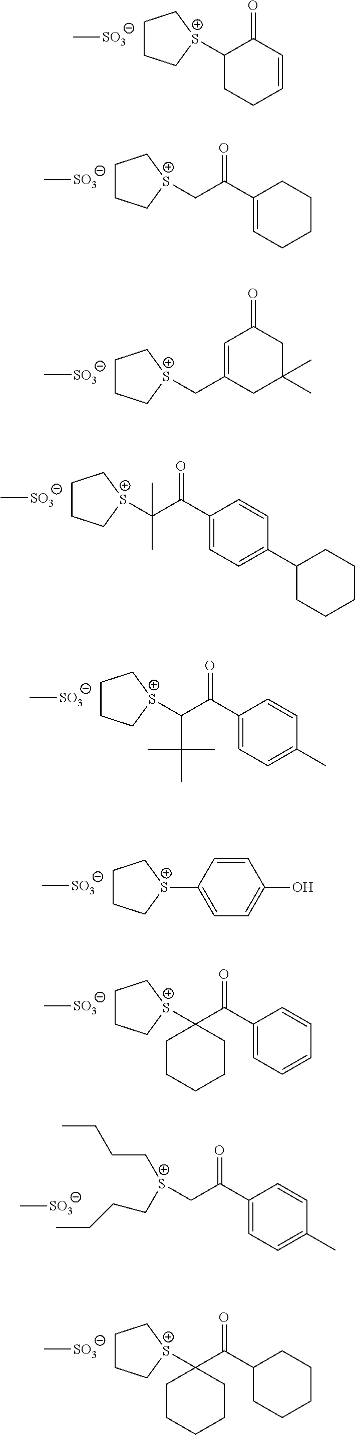

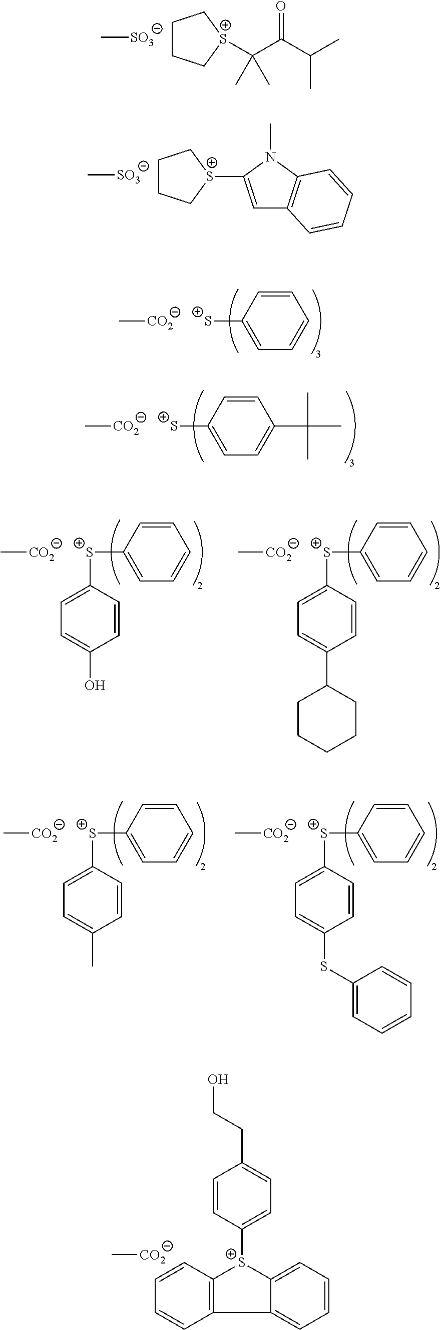

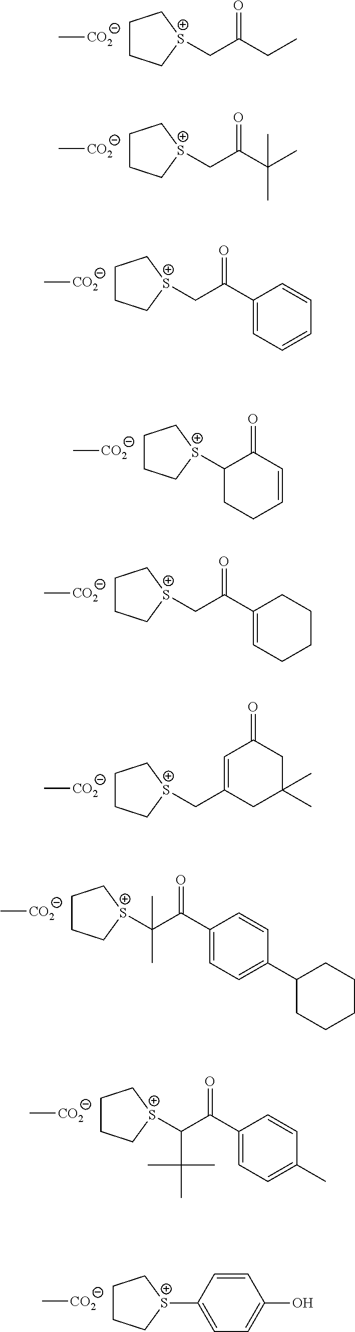

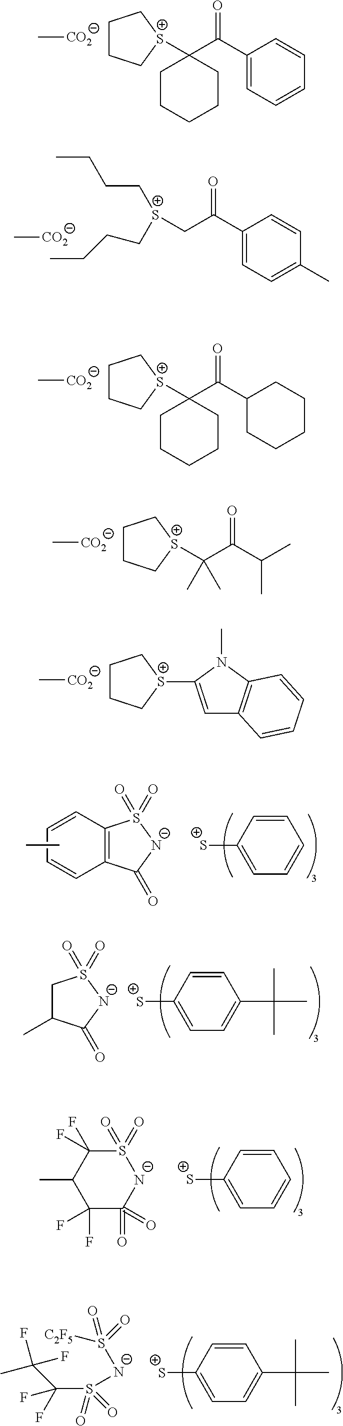

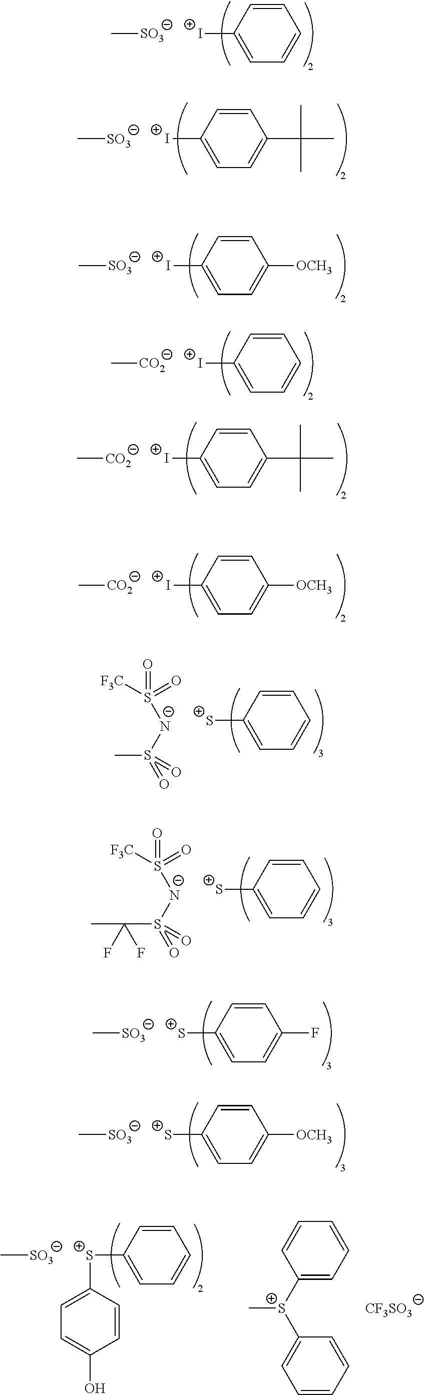

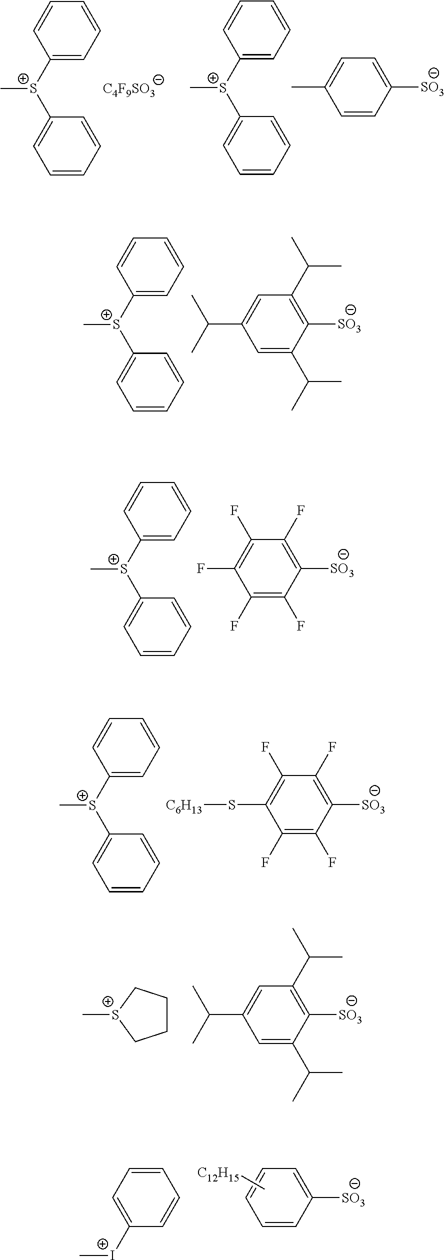

In the resin (P) according to the present invention, the content of repeating unit (A) based on all the repeating units is preferably in the range of 0.5 to 80 mol %, more preferably 1 to 60 mol % and most preferably 2 to 40 mol %. One type of repeating unit (A) may be used alone, or two or more types thereof may be used in combination.

The method of synthesizing the monomer corresponding to any of the repeating units (A) is not particularly limited. For example, in the instance of an onium structure, there can be mentioned a synthetic method in which an acid anion containing a polymerizable unsaturated bond corresponding to the repeating unit is exchanged with a halide of a known onium salt.

More specifically, a metal ion salt (for example, a salt of sodium ion, potassium ion or the like) or ammonium salt (an ammonium or triethylammonium salt or the like) of an acid containing a polymerizable unsaturated bond corresponding to the repeating unit and an onium salt containing a halide ion (chloride ion, bromide ion, iodide ion or the like) are agitated together in the presence of water or methanol to thereby accomplish an anion exchange reaction. The reaction liquid is subjected to liquid separation/washing operations using water and an organic solvent, such as dichloromethane, chloroform, ethyl acetate, methyl isobutyl ketone or tetrahydroxyfuran. Thus, the desired monomer corresponding to any of the repeating units (A) can be obtained.

Alternatively, the synthesis can be accomplished by agitating the mixture in the presence of water and an organic solvent capable of separation from water, such as dichloromethane, chloroform, ethyl acetate, methyl isobutyl ketone or tetrahydroxyfuran, to thereby accomplish an anion exchange reaction and subjecting the reaction liquid to liquid separation with water/washing operations.

Particular examples of the repeating units (A) are shown below, which however in no way limit the scope of the present invention.

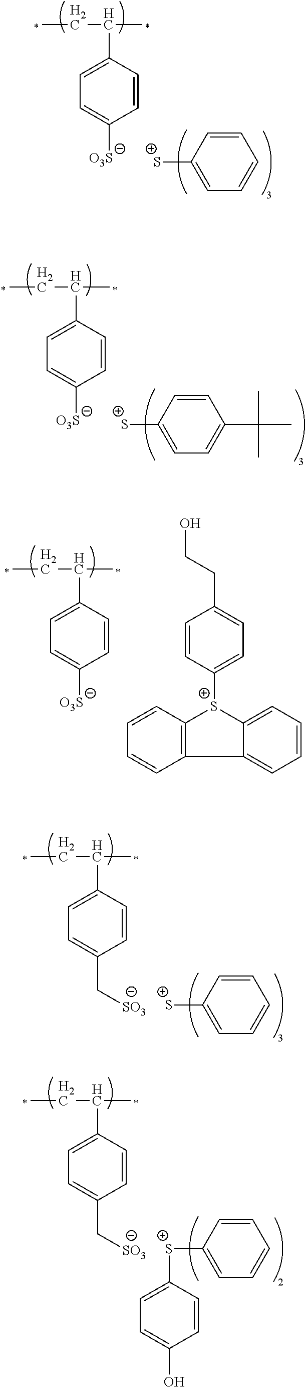

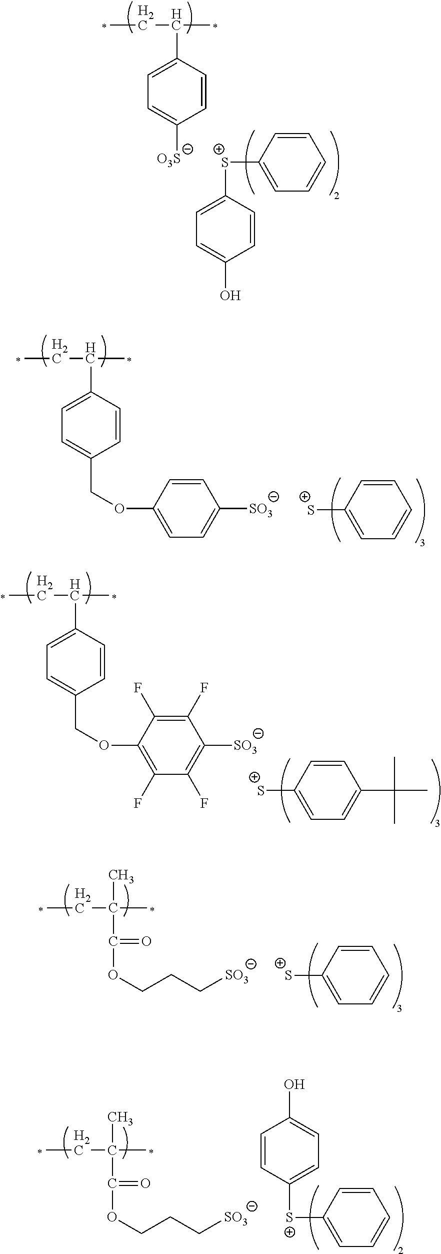

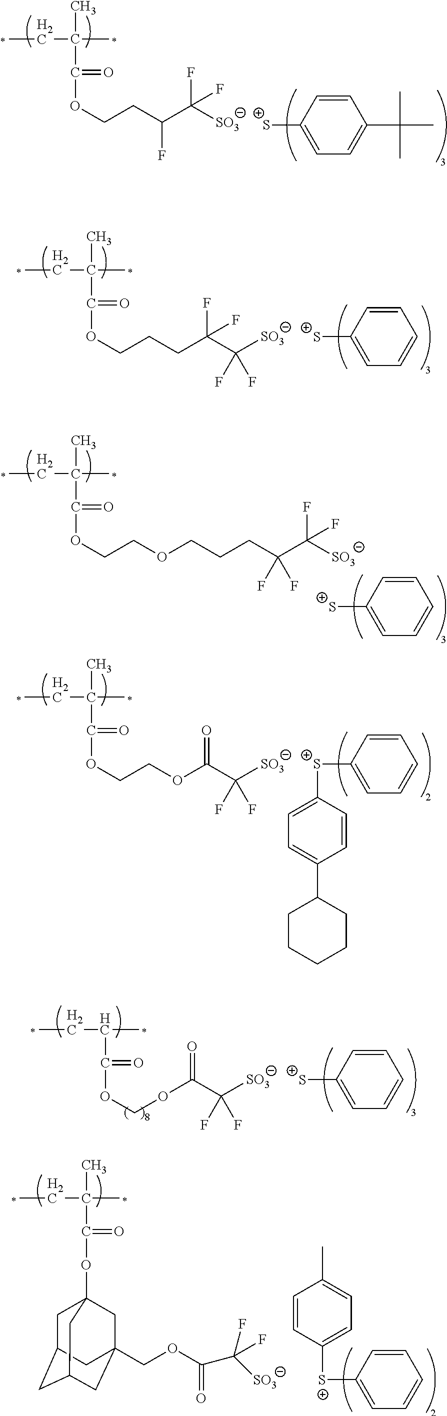

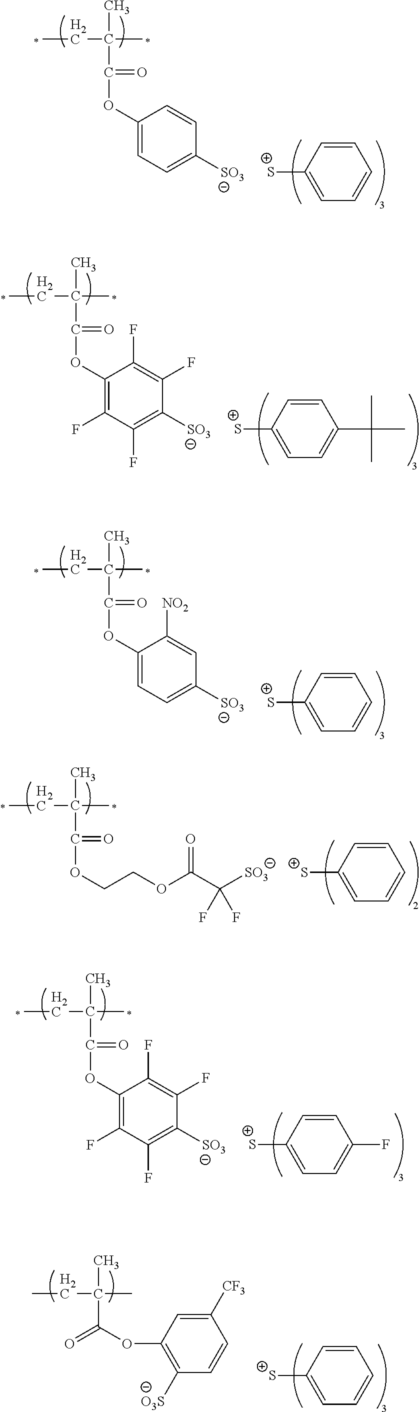

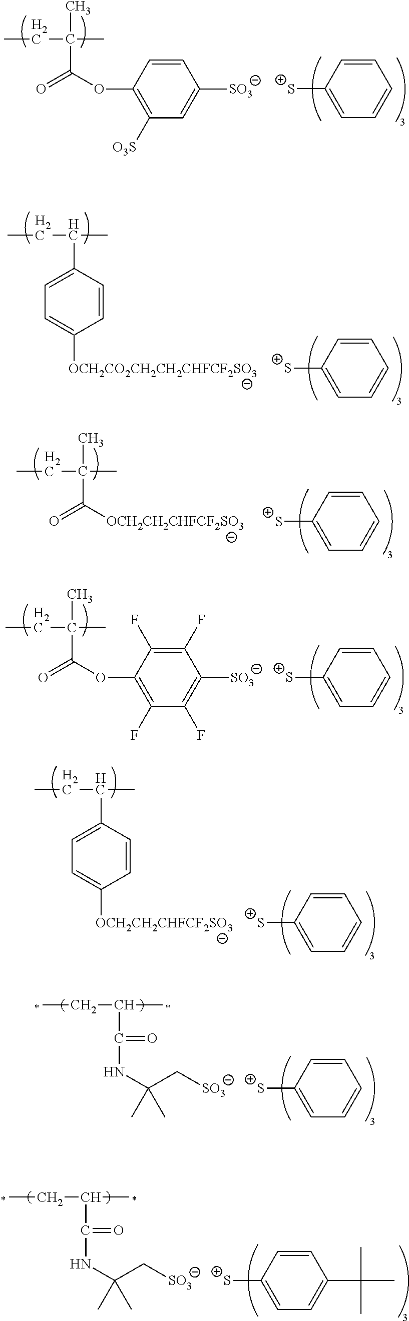

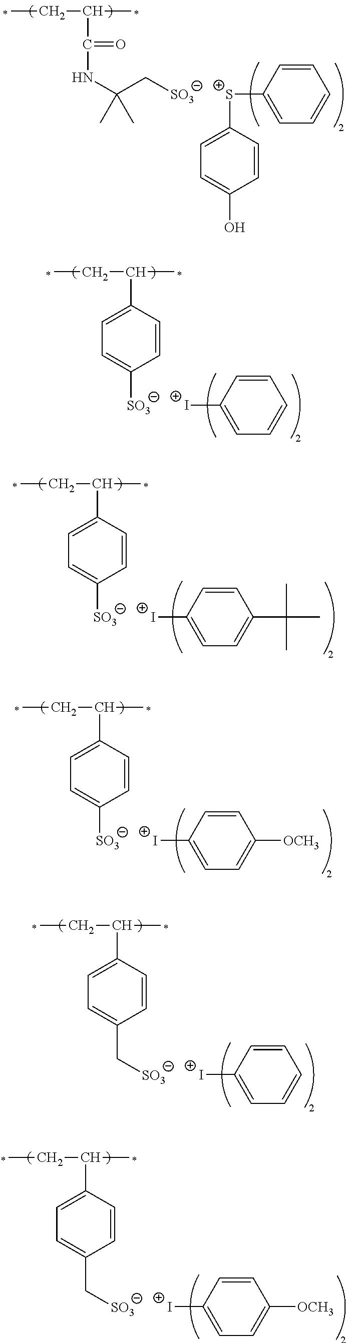

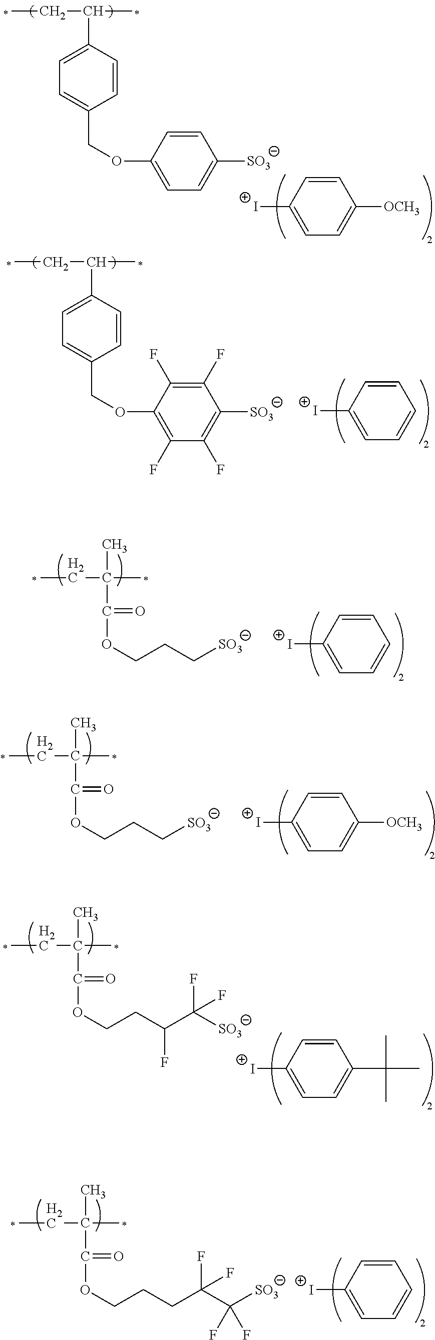

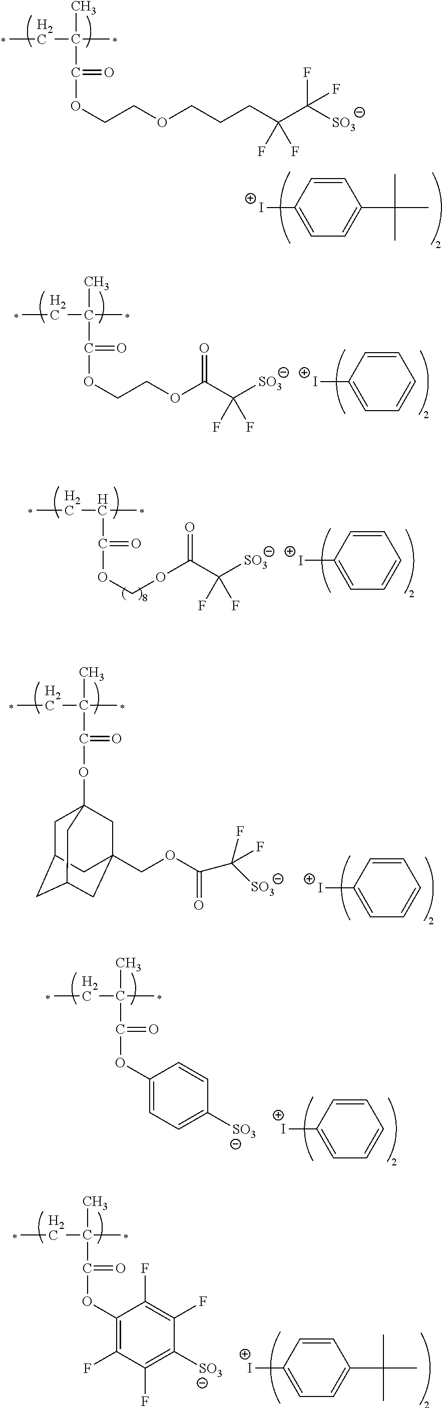

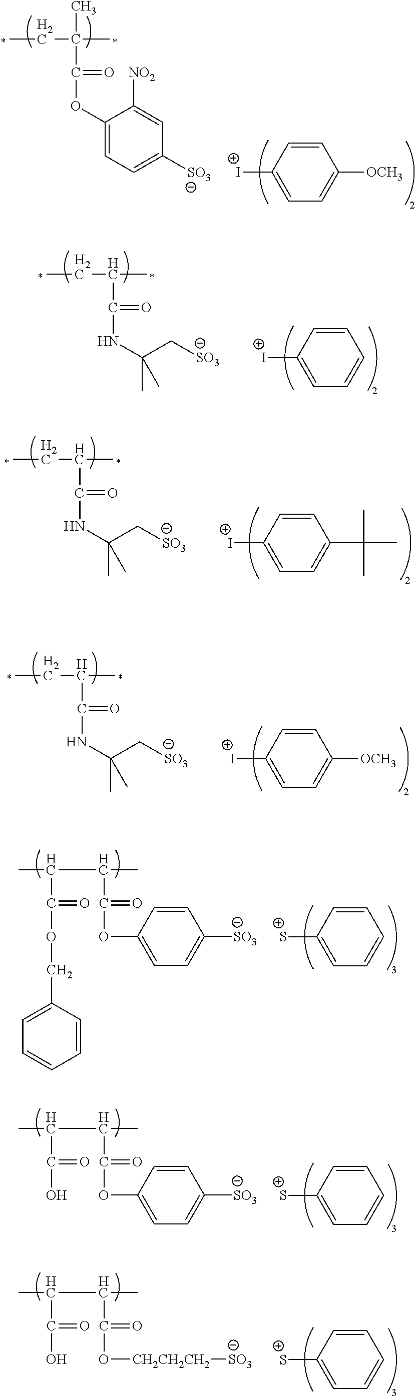

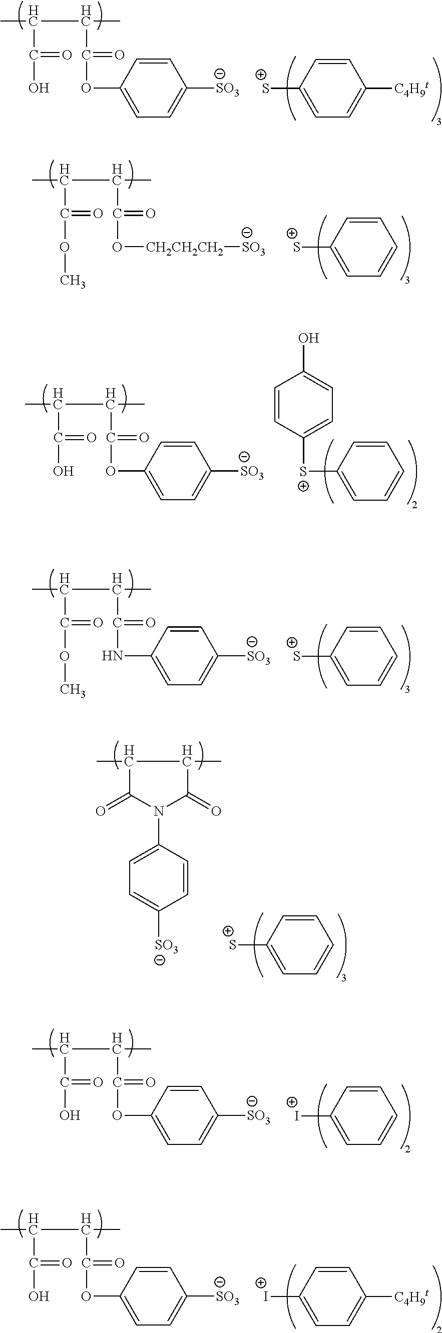

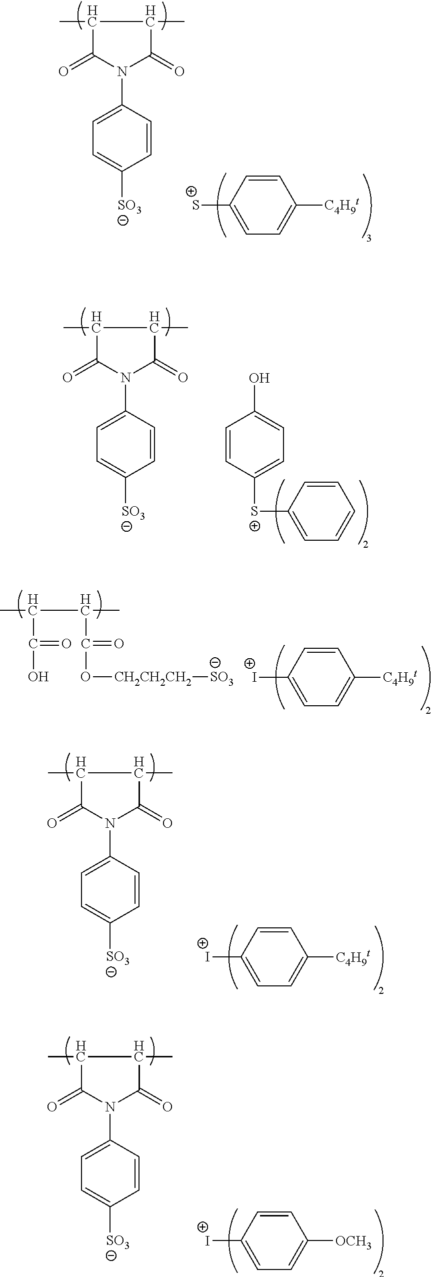

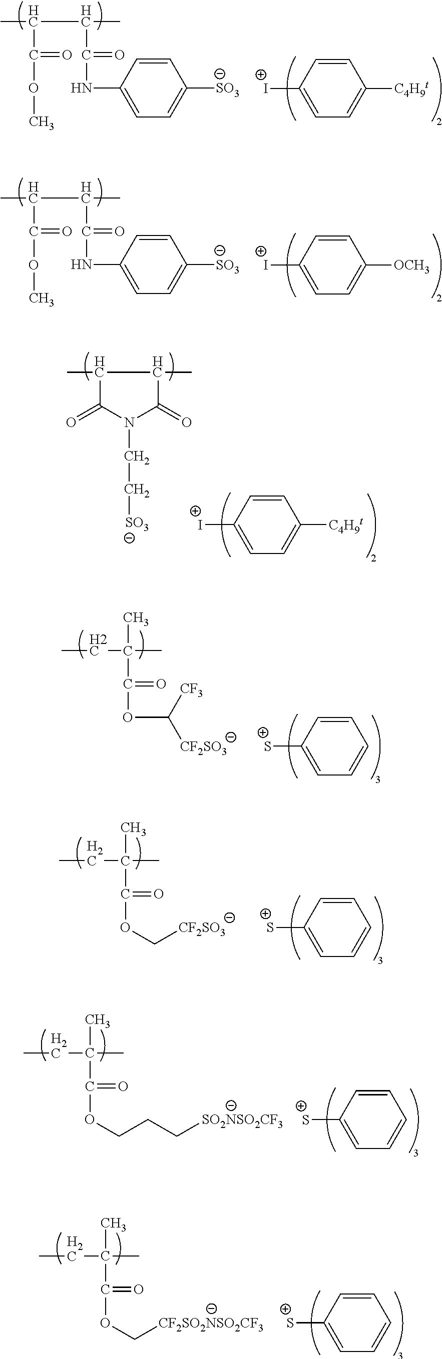

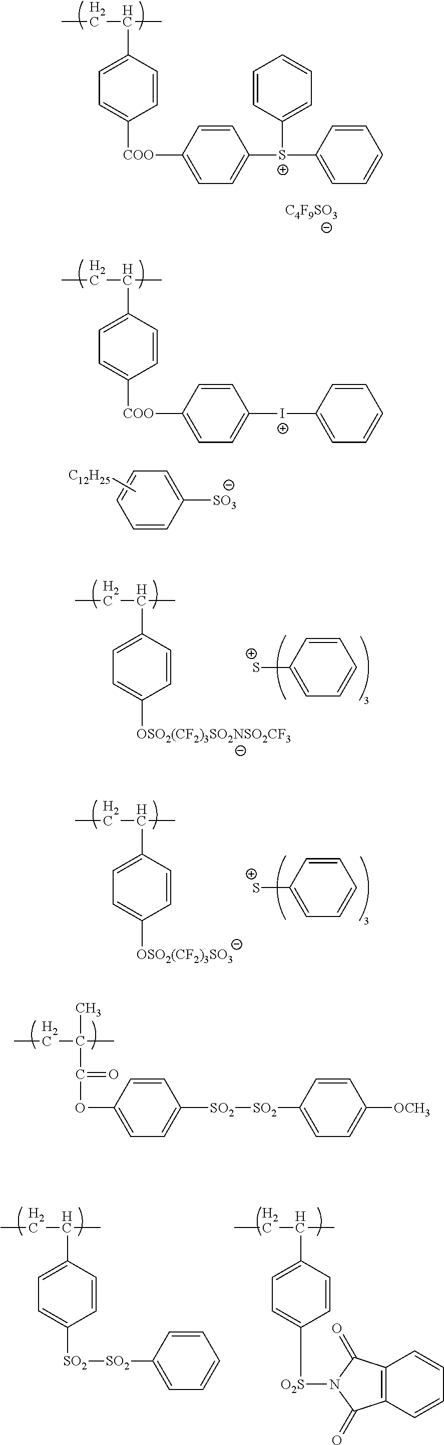

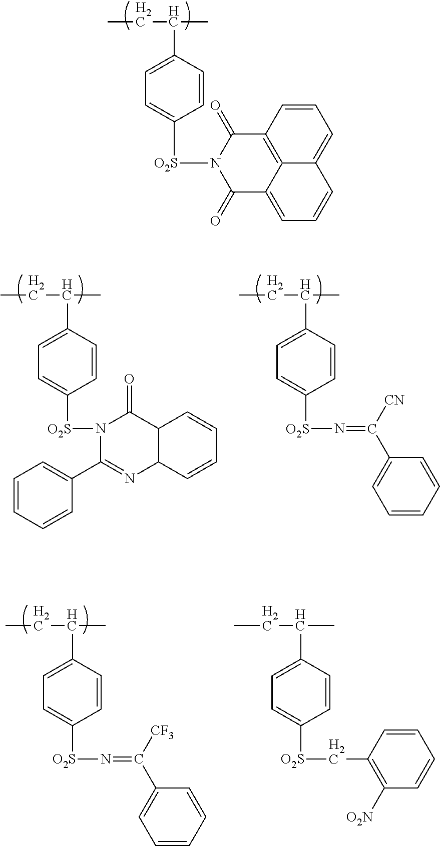

Moreover, the repeating unit (A) may be one containing a nonionic acid generating moiety, such as, for example, any of compounds (a31) to (a126) and (a145) to (a196) disclosed by way of example in JP-A-H10-221852.

<Repeating Unit (B)>

The resin (P) comprises a repeating unit (B) containing an acid-decomposable group. The repeating unit (B) contains a group that when acted on by an acid, is decomposed to thereby produce an alkali soluble group.

As the alkali soluble group, there can be mentioned a phenolic hydroxyl group, a carboxyl group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali soluble groups, there can be mentioned a phenolic hydroxyl group, a carboxyl group, a fluoroalcohol group (preferably hexafluoroisopropanol) and a sulfonate group.

The acid-decomposable group is preferably a group as obtained by substituting the hydrogen atom of any of these alkali soluble groups with an acid eliminable group.

As the acid eliminable group, there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, a monovalent aromatic ring group, a combination of an alkylene group and a monovalent aromatic ring group or an alkenyl group. R₃₆ and R₃₇ may be bonded with each other to thereby form a ring structure.

Each of R₀₁ to R₀₂ independently represents a hydrogen atom, an alkyl group, a cycloalkyl group, a monovalent aromatic ring group, a combination of an alkylene group and a monovalent aromatic ring group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit (B) is preferably any of those of general formula (5), below.

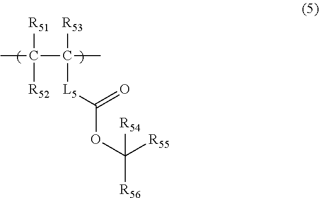

In general formula (5),

each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents a single bond or a bivalent connecting group.

L₅ represents a single bond or a bivalent connecting group, provided that when a ring is formed in cooperation with R₅₂, L₅ represents a trivalent connecting group.

R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and provided that R₅₅ and R₅₆ are not simultaneously hydrogen atoms.

General formula (5) will be described in greater detail below.

As a preferred alkyl group represented by each of R₅₁ to R₅₃ in general formula (5), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred, and an alkyl group having up to 3 carbon atoms is most preferred.

The alkyl group contained in the alkoxycarbonyl group is preferably the same as that represented by each of R₅₁ to R₅₃ above.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is most preferred.

As preferred substituents that can be introduced in these groups, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

When R₅₂ is a bivalent connecting group and forms a ring in cooperation with L₅, the connecting group is preferably an alkylene group. The alkylene group is preferably an alkylene group having 1 to 8 carbon atoms, such as a methylene group, an ethylene group, a propylene group, a butylene group, a hexylene group or an octylene group. An alkylene group having 1 to 4 carbon atoms is more preferred, and an alkylene group having 1 or 2 carbon atoms is most preferred. The ring formed by the mutual bonding of R₅₂ and L₅ is most preferably a 5- or 6-membered ring.

In formula (5), each of R₅₁ and R₅₃ is more preferably a hydrogen atom, an alkyl group or a halogen atom, most preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is more preferably a hydrogen atom, an alkyl group, a halogen atom or an alkylene group (forming a ring in cooperation with L₅), most preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring in cooperation with L₅) or an ethylene group (forming a ring in cooperation with L₅).

As the bivalent connecting group represented by L₅, there can be mentioned an alkylene group, a bivalent aromatic ring group, —COO-L₁-, —O-L₁-, a group comprised of a combination of two or more thereof or the like. In the formulae, L₁ represents an alkylene group, a cycloalkylene group, a bivalent aromatic ring group or a group comprised of an alkylene group combined with a bivalent aromatic ring group.

L₅ is preferably a single bond, any of the groups of the formula —COO-L₁- or a bivalent aromatic ring group. When the exposure is conducted using an ArF excimer laser, a single bond or —COO-L₁- is preferred from the viewpoint that the absorption in the region of 193 nm can be reduced. L₁ is preferably an alkylene group having 1 to 5 carbon atoms, more preferably a methylene group or a propylene group.

The alkyl group represented by each of R₅₄ to R₅₆ is preferably one having 1 to 20 carbon atoms, more preferably one having 1 to 10 carbon atoms and most preferably one having 1 to 4 carbon atoms, such as a methyl group, an ethyl group, an n-propyl group, an isopropyl group, an n-butyl group, an isobutyl group or a t-butyl group.

The cycloalkyl group represented by each of R₅₅ and R₅₆ is preferably one having 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group.

The ring formed by the mutual bonding of R₅₅ and R₅₆ preferably has 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group. When R₅₅ and R₅₆ are bonded to each other to thereby form a ring, R₅₄ is preferably an alkyl group having 1 to 3 carbon atoms, more preferably a methyl group or an ethyl group.

The monovalent aromatic ring group represented by each of R₅₅ and R₅₆ is preferably one having 6 to 20 carbon atoms. As such, there can be mentioned, for example, a phenyl group, a naphthyl group or the like.

When either R₅₅ or R₅₆ is a hydrogen atom, it is preferred for the other to be a monovalent aromatic ring group.

When the exposure is conducted using an ArF excimer laser, it is preferred for each of R₅₅ and R₅₆ to independently represent a hydrogen atom, an alkyl group or a cycloalkyl group from the viewpoint that the absorption in the region of 193 nm can be reduced.

As the method of synthesizing the monomers corresponding to the repeating units of general formula (5), use can be made of a routine process for synthesizing esters containing a polymerizable group. The method is not particularly limited.

Particular examples of the repeating units (B) of general formula (5) are shown below, which however in no way limit the scope of the present invention.

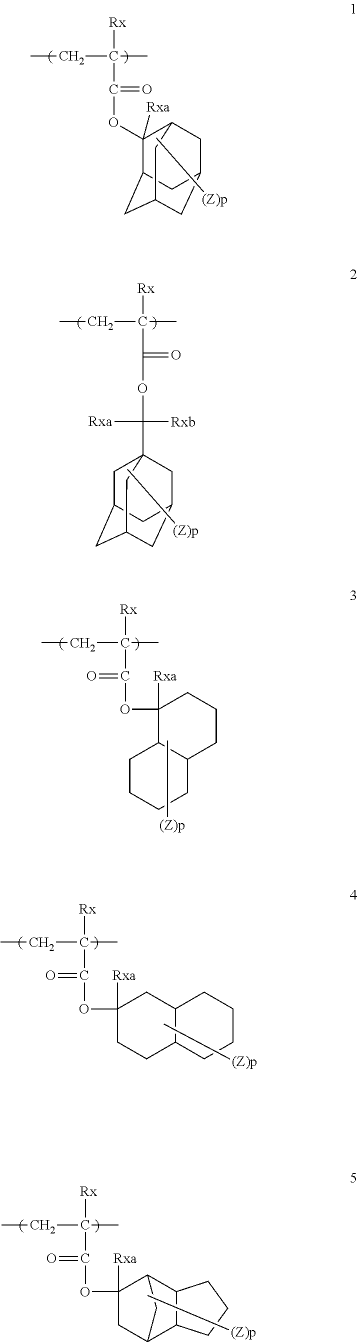

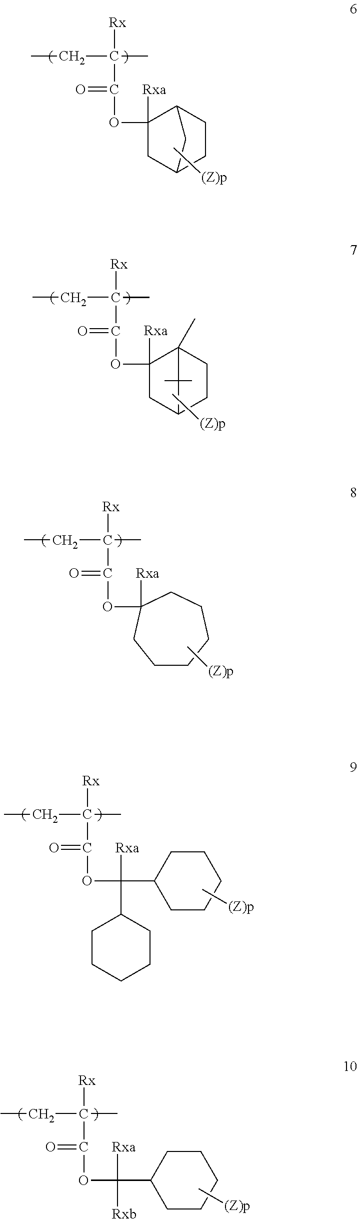

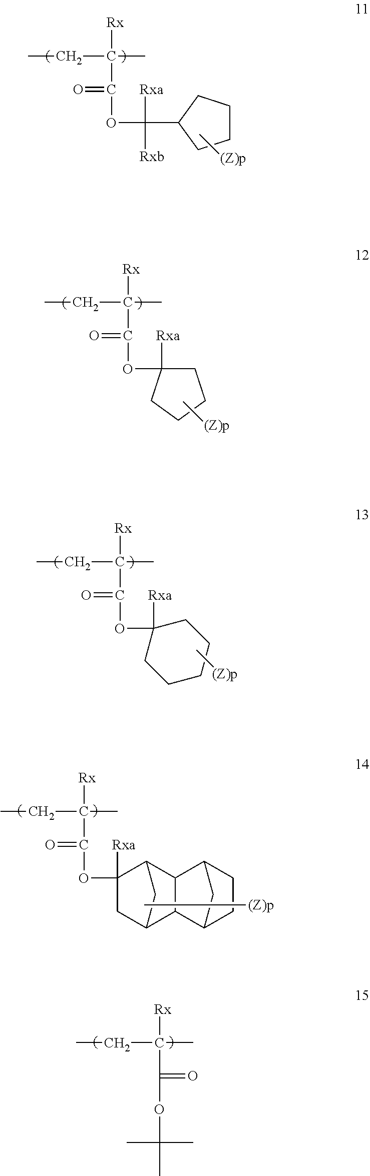

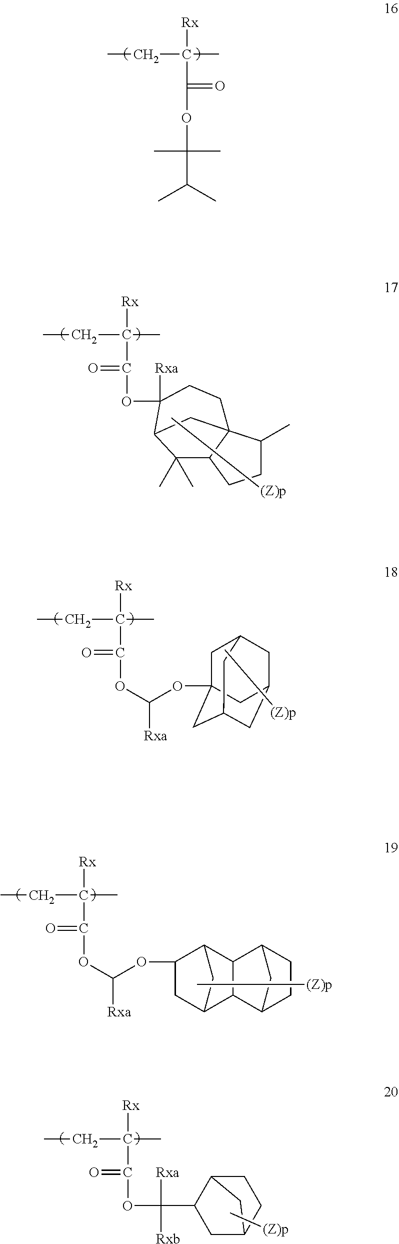

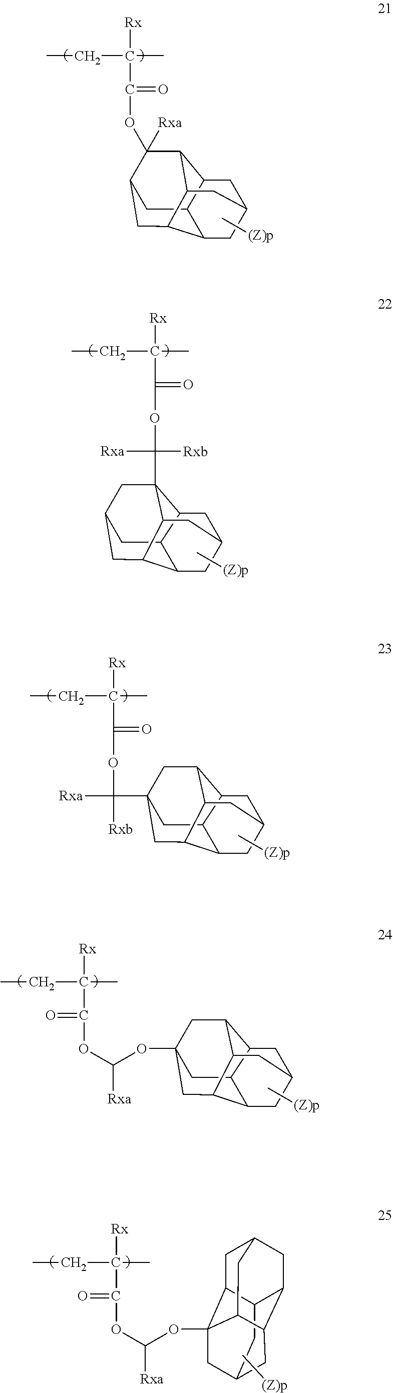

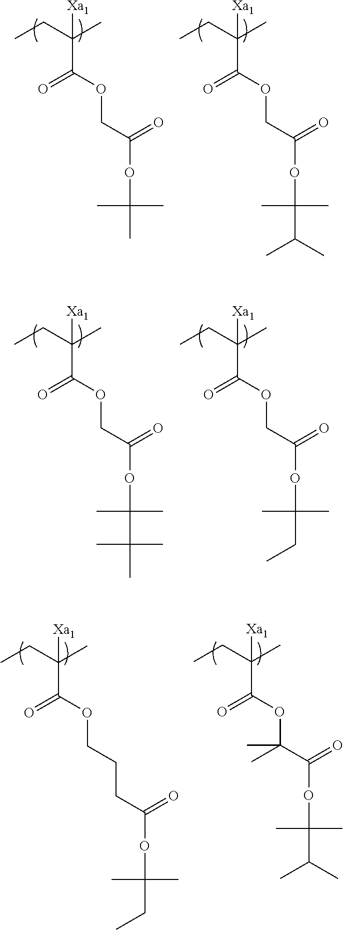

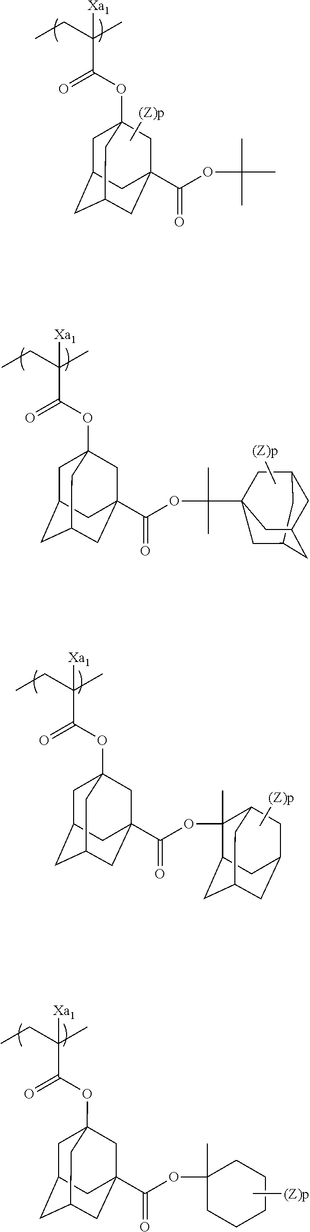

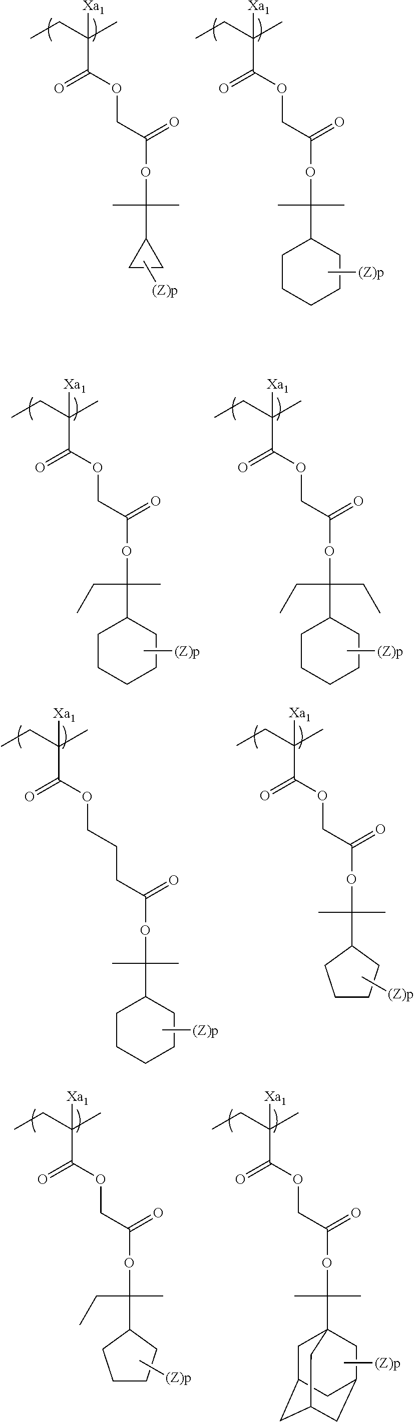

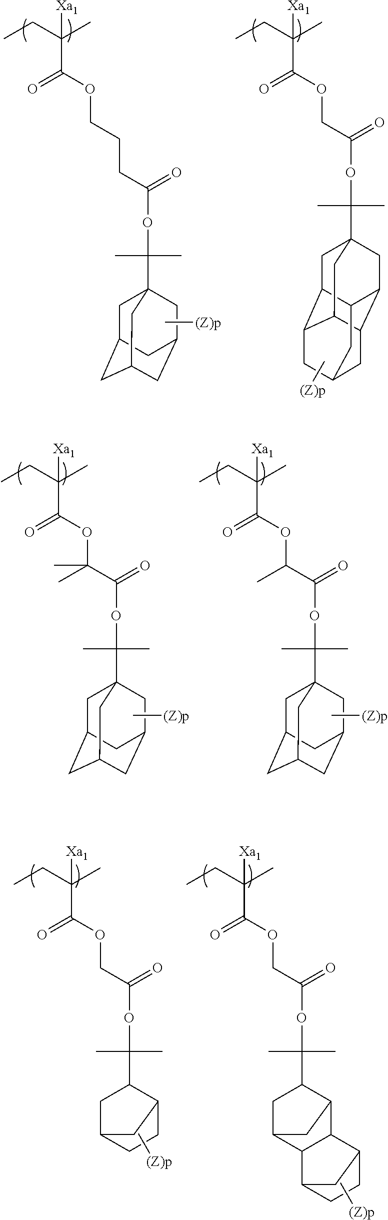

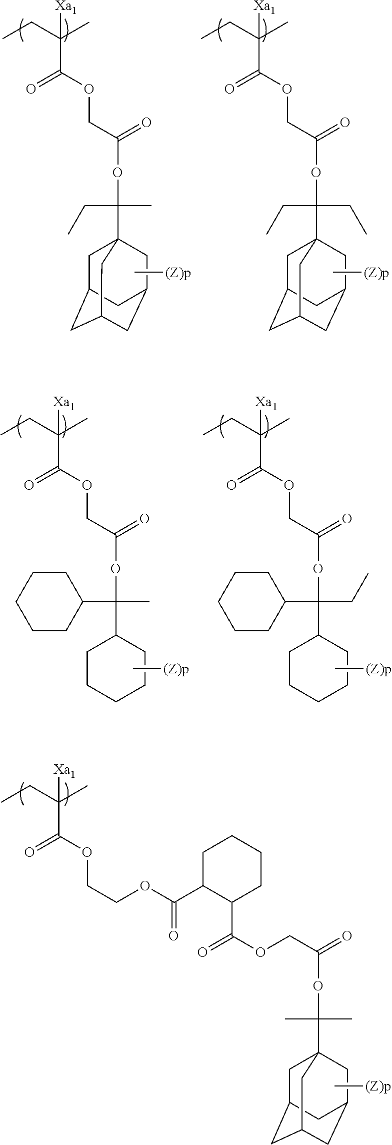

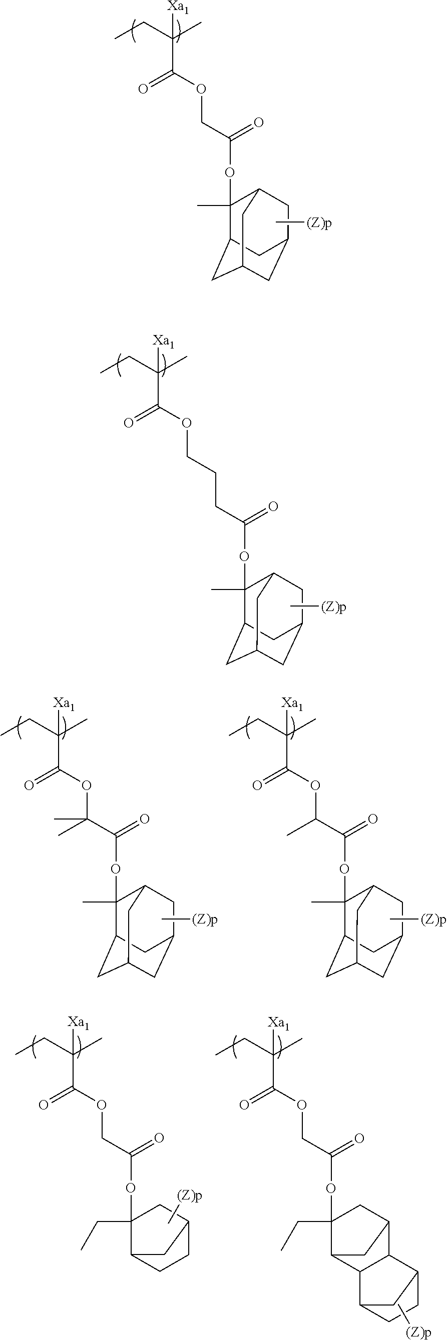

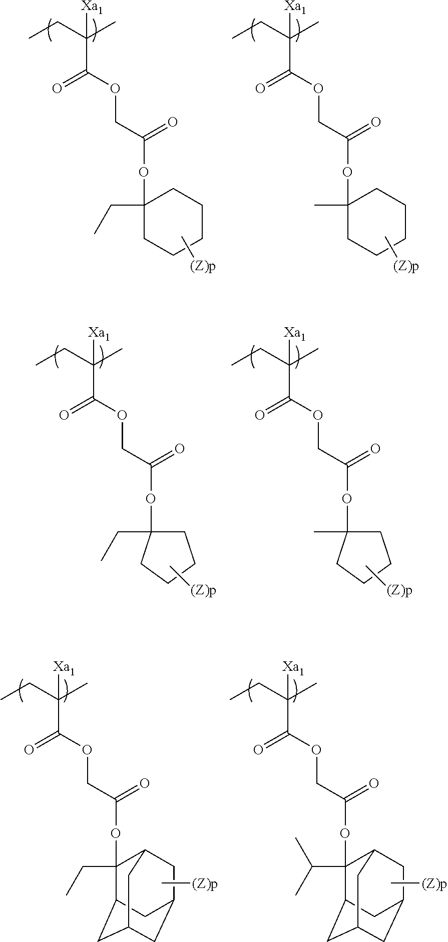

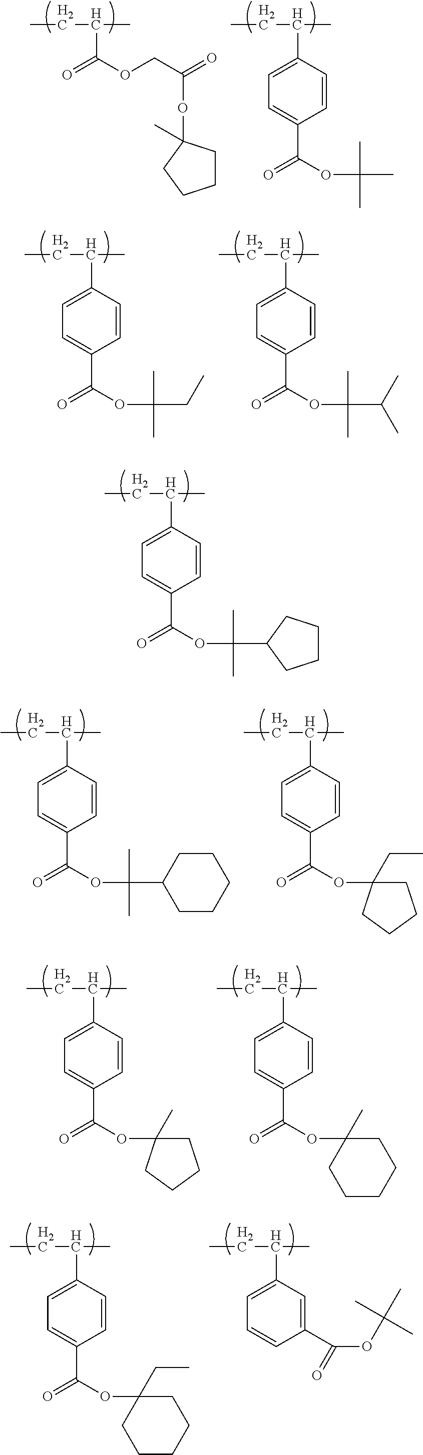

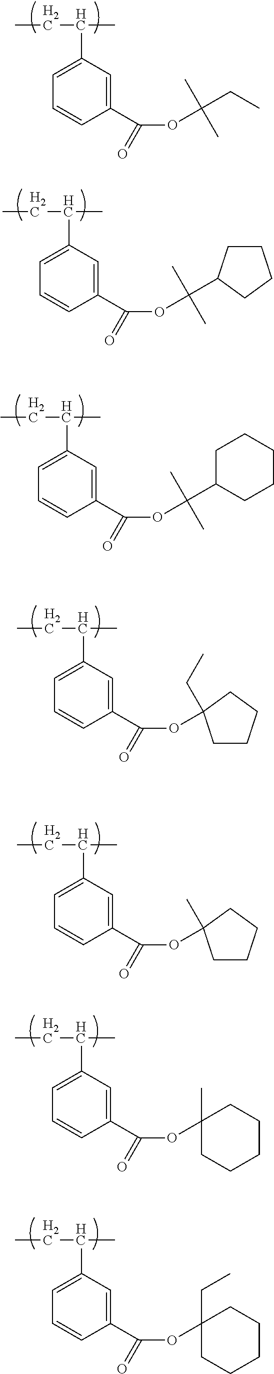

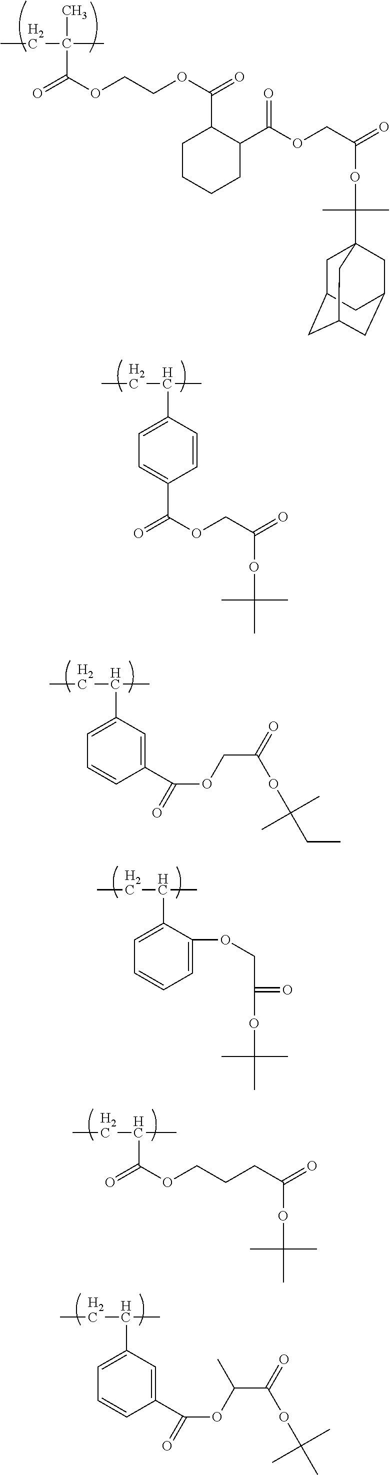

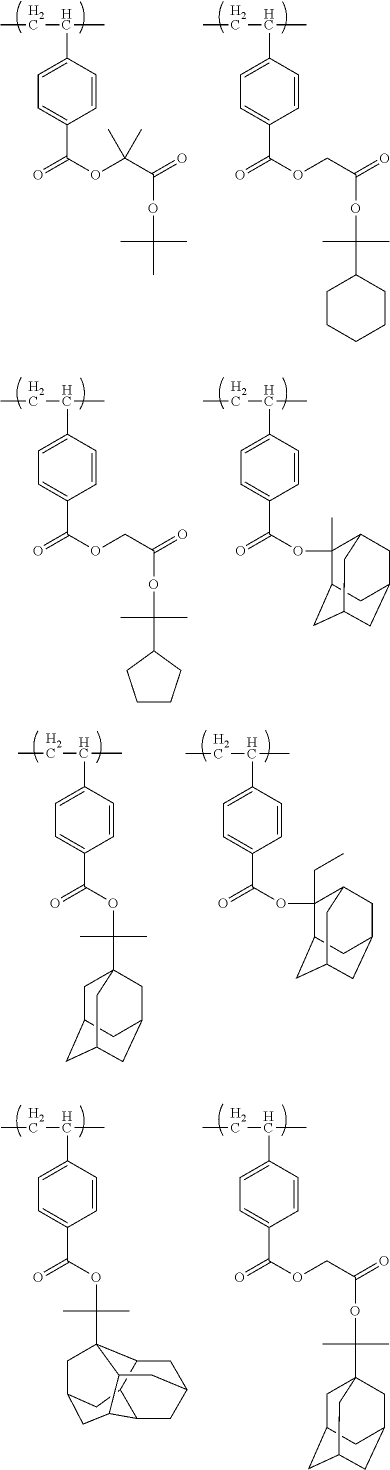

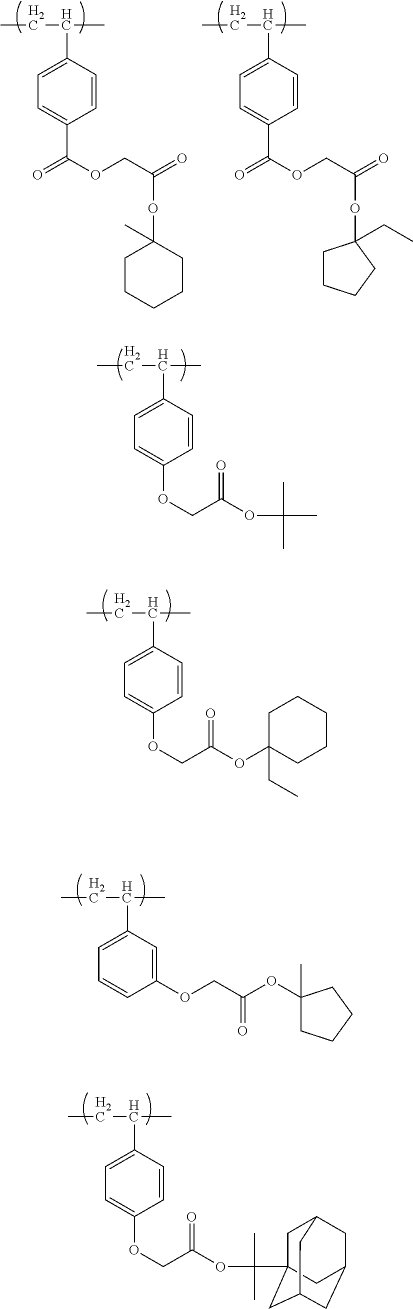

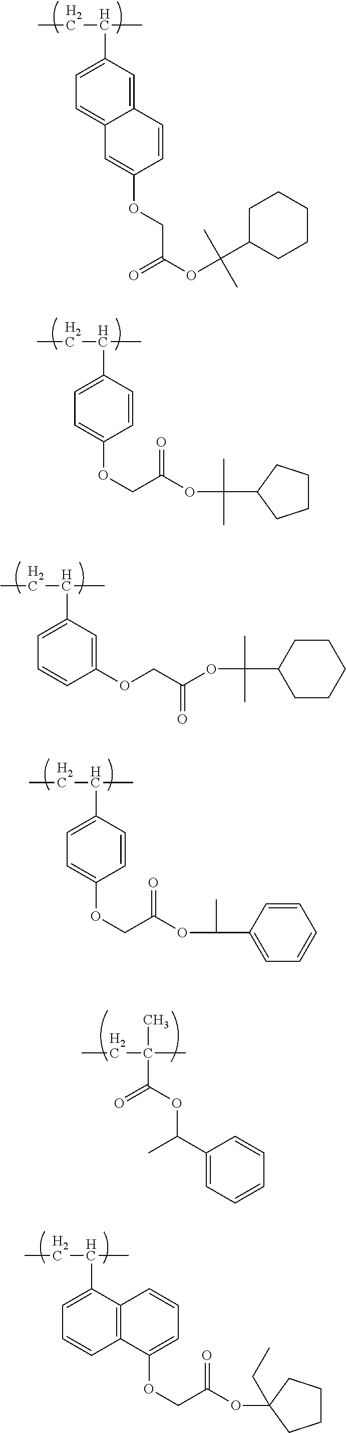

Moreover, the resin (P) may contain any of the repeating units of general formula (6) below as the repeating unit (B). This is especially preferred when the exposure is performed using electron beams or EUV light.

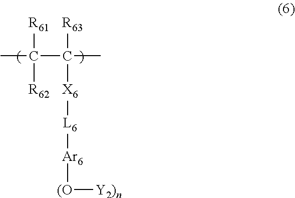

In general formula (6), each of R₆₁, R₆₂ and R₆₃ independently represents a hydrogen atom, an alkyl group, a cycloalkyl group, a halogen atom, a cyano group or an alkoxycarbonyl group. R₆₂ may be bonded to Ar₆ to thereby form a ring. If so, R₆₂ represents a single bond or a bivalent connecting group.

X₆ represents a single bond, —COO— or —CONR₆₄— in which R₆₄ represents a hydrogen atom or an alkyl group, provided that R₆₄ may be bonded to R₆₂ to thereby form a ring, which R₆₄ is a single bond or a bivalent connecting group.

L₆ represents a single bond or an alkylene group.

Ar₆ represents a (n+1)-valent aromatic ring group, provided that Ar₆ may be bonded to R₆₂ to thereby form a ring, which Ar₆ is a single bond or a (n+2)-valent aromatic ring group.

Y₂, when n 2 each independently, represents a hydrogen atom or a group that when acted on by an acid, is cleaved, provided that at least one of Y₂s is a group that when acted on by an acid, is cleaved, and

n is an integer of 1 to 4.

General formula (6) will be described in greater detail below.

As a preferred alkyl group represented by each of R₆₁ to R₆₃ in general formula (6), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred.

The alkyl group contained in the alkoxycarbonyl group is preferably the same as that represented by each of R₆₁ to R₆₃ above.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is preferred.

When R₆₂ is a bivalent connecting group, the connecting group is preferably an alkylene group. The alkylene group is preferably an optionally substituted alkylene group having 1 to 8 carbon atoms, such as a methylene group, an ethylene group, a propylene group, a butylene group, a hexylene group or an octylene group.

The alkyl group represented by R₆₄ of the —CONR₆₄—(R₆₄ represents a hydrogen atom or an alkyl group) represented by X₆ is the same as set forth above as the alkyl group represented by each of R₆₁ to R₆₃.

X₆ is preferably a single bond, —COO— or —CONH—, more preferably a single bond or —COO—.

When R₆₄ is a bivalent connecting group, the connecting group is preferably an alkylene group. The alkylene group is preferably an optionally substituted alkylene group having 1 to 8 carbon atoms, such as a methylene group, an ethylene group, a propylene group, a butylene group, a hexylene group or an octylene group.

The alkylene group represented by L₆ is preferably an optionally substituted alkylene group having 1 to 8 carbon atoms, such as a methylene group, an ethylene group, a propylene group, a butylene group, a hexylene group or an octylene group. The ring formed by the mutual bonding of R₆₂ and L₆ is most preferably a 5- or 6-membered ring.

Ar₆ represents a (n+1)-valent aromatic ring group, provided that Ar₆ may be bonded to R₆₂ to thereby form a ring, which Ar₆ is a (n+2)-valent aromatic ring group. A substituent may be introduced in the aromatic ring group. As preferred examples thereof, there can be mentioned an arylene group having 6 to 18 carbon atoms, such as a phenylene group, a tolylene group or a naphthylene group, and an aromatic ring group containing a heteroring, such as thiophene, furan, pyrrole, benzothiophene, benzofuran, benzopyrrole, triazine, imidazole, benzimidazole, triazole, thiadiazole or thiazole.

Particular examples of the substituents that can be introduced in the above alkyl group, cycloalkyl group, alkoxycarbonyl group, alkylene group and bivalent aromatic ring group are the same as those which can be introduced in the above groups represented by R₅₁ to R₅₃ in general formula (5).

In the formula, n is preferably 1 or 2, more preferably 1.

Each of n Y₂s independently represents a hydrogen atom or a group that is cleaved by the action of an acid, provided that at least one of n Y₂s represents a group that is cleaved by the action of an acid.

As the group that is cleaved by the action of an acid, Y₂, there can be mentioned, for example, —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), —CH(R₃₆)(Ar) or the like.

In the formulae, each of R₃₆ to R₃₉ independently represents an alkyl group, a cycloalkyl group, a monovalent aromatic ring group, a group composed of a combination of an alkylene group and a monovalent aromatic ring group, or an alkenyl group. R₃₆ and R₃₇ may be bonded to each other to thereby form a ring.

Each of R₀₁ and R₀₂ independently represents a hydrogen atom, an alkyl group, a cycloalkyl group, a monovalent aromatic ring group, a group composed of a combination of an alkylene group and a monovalent aromatic ring group, or an alkenyl group.

Ar represents a monovalent aromatic ring group.

Each of the alkyl groups represented by R₃₆ to R₃₉, R₀₁ and R₀₂ preferably has 1 to 8 carbon atoms. For example, there can be mentioned a methyl group, an ethyl group, a propyl group, an n-butyl group, a sec-butyl group, a hexyl group, an octyl group or the like.

The cycloalkyl groups represented by R₃₆ to R₃₉, R₀₁ and R₀₂ may be monocyclic or polycyclic. When the cycloalkyl group is monocyclic, it is preferably a cycloalkyl group having 3 to 8 carbon atoms. As such, there can be mentioned, for example, a cyclopropyl group, a cyclobutyl group, a cyclopentyl group, a cyclohexyl group, a cyclooctyl group or the like. When the cycloalkyl group is polycyclic, it is preferably a cycloalkyl group having 6 to 20 carbon atoms. As such, there can be mentioned, for example, an adamantyl group, a norbornyl group, an isobornyl group, a camphonyl group, a dicyclopentyl group, an α-pinanyl group, a tricyclodecanyl group, a tetracyclododecyl group, an androstanyl group or the like. With respect to these, the carbon atoms of each of the cycloalkyl groups may be partially substituted with a heteroatom, such as an oxygen atom.

Each of the monovalent aromatic ring groups represented by R₃₆ to R₃₉, R₀₁, R₀₂ and Ar is preferably one having 6 to 10 carbon atoms. For example, there can be mentioned an aryl group, such as a phenyl group, a naphthyl group or an anthryl group, or a monovalent aromatic ring group containing a heteroring, such as thiophene, furan, pyrrole, benzothiophene, benzofuran, benzopyrrole, triazine, imidazole, benzimidazole, triazole, thiadiazole or thiazole.

Each of the groups comprised of an alkylene group combined with a monovalent aromatic ring group, represented by R₃₆ to R₃₉, R₀₁ and R₀₂ is preferably an aralkyl group having 7 to 12 carbon atoms. For example, there can be mentioned a benzyl group, a phenethyl group, a naphthylmethyl group or the like.

Each of the alkenyl groups represented by R₃₆ to R₃₉, R₀₁ and R₀₂ preferably has 2 to 8 carbon atoms. For example, there can be mentioned a vinyl group, an allyl group, a butenyl group, a cyclohexenyl group or the like.

The ring formed by the mutual bonding of R₃₆ and R₃₇ may be monocyclic or polycyclic. The monocyclic structure is preferably a cycloalkyl structure having 3 to 8 carbon atoms. As such, there can be mentioned, for example, a cyclopropane structure, a cyclobutane structure, a cyclopentane structure, a cyclohexane structure, a cycloheptane structure, a cyclooctane structure or the like. The polycyclic structure is preferably a cycloalkyl structure having 6 to 20 carbon atoms. As such, there can be mentioned, for example, an adamantane structure, a norbornane structure, a dicyclopentane structure, a tricyclodecane structure, a tetracyclododecane structure or the like. With respect to these, the carbon atoms of each of the cycloalkyl structures may be partially substituted with a heteroatom, such as an oxygen atom.

Substituents may be introduced in the above groups represented by R₃₆ to R₃₉, R₀₁, R₀₂ and Ar. As the substituents, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

The group that is cleaved by the action of an acid, Y₂, more preferably has any of the structures of general formula (6-A) below.

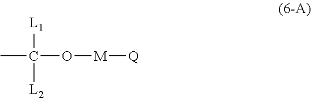

In the formula, each of L₁ and L₂ independently represents a hydrogen atom, an alkyl group, a cycloalkyl group, a monovalent aromatic ring group or a group comprised of an alkylene group combined with a monovalent aromatic ring group.

M represents a single bond or a bivalent connecting group.

Q represents an alkyl group, a cycloalkyl group optionally containing a heteroatom, a monovalent aromatic ring group optionally containing a heteroatom, an amino group, an ammonium group, a mercapto group, a cyano group or an aldehyde group.

At least two of Q, M and L₁ may be bonded to each other to thereby form a ring (preferably, a 5-membered or 6-membered ring).

The alkyl groups represented by L₁ and L₂ are, for example, alkyl groups each having 1 to 8 carbon atoms. As preferred examples thereof, there can be mentioned a methyl group, an ethyl group, a propyl group, an n-butyl group, a sec-butyl group, a hexyl group and an octyl group.

The cycloalkyl groups represented by L₁ and L₂ are, for example, cycloalkyl groups each having 3 to 15 carbon atoms. As preferred examples thereof, there can be mentioned a cyclopentyl group, a cyclohexyl group, a norbornyl group, an adamantyl group and the like.

The monovalent aromatic ring groups represented by L₁ and L₂ are, for example, aryl groups each having 6 to 15 carbon atoms. As preferred examples thereof, there can be mentioned a phenyl group, a tolyl group, a naphthyl group, an anthryl group and the like.

The groups each comprised of an alkylene group combined with a monovalent aromatic ring group, represented by L₁ and L₂ are, for example, those each having 6 to 20 carbon atoms. There can be mentioned aralkyl groups, such as a benzyl group and a phenethyl group.

The bivalent connecting group represented by M is, for example, an alkylene group (e.g., a methylene group, an ethylene group, a propylene group, a butylene group, a hexylene group, an octylene group, etc.), a cycloalkylene group (e.g., a cyclopentylene group, a cyclohexylene group, an adamantylene group, etc.), an alkenylene group (e.g., an ethylene group, a propenylene group, a butenylene group, etc.), a bivalent aromatic ring group (e.g., a phenylene group, a tolylene group, a naphthylene group, etc.), —S—, —O—, —CO—, —SO₂—, —N(R₀)— or a bivalent connecting group resulting from combination of these groups. R₀ represents a hydrogen atom or an alkyl group (for example, an alkyl group having 1 to 8 carbon atoms; in particular, a methyl group, an ethyl group, a propyl group, an n-butyl group, a sec-butyl group, a hexyl group, an octyl group or the like).

The alkyl group represented by Q is the same as mentioned above as being represented by each of L₁ and L₂.

As the aliphatic hydrocarbon ring group containing no heteroatom and monovalent aromatic ring group containing no heteroatom respectively contained in the cycloalkyl group optionally containing a heteroatom and monovalent aromatic ring group optionally containing a heteroatom, both represented by Q, there can be mentioned, for example, the cycloalkyl group and monovalent aromatic ring group mentioned above as being represented by each of L₁ and L₂. Preferably, each thereof has 3 to 15 carbon atoms.

As the cycloalkyl group containing a heteroatom and monovalent aromatic ring group containing a heteroatom, there can be mentioned, for example, groups having a heterocyclic structure, such as thiirane, cyclothiorane, thiophene, furan, pyrrole, benzothiophene, benzofuran, benzopyrrole, triazine, imidazole, benzimidazole, triazole, thiadiazole, thiazole and pyrrolidone. However, the above cycloalkyl groups and monovalent aromatic ring groups are not limited to these as long as a structure generally known as a heteroring (ring formed by carbon and a heteroatom, or ring formed by heteroatoms) is included.

As the ring that may be formed by the mutual bonding of at least two of Q, M and L₁, there can be mentioned one resulting from the mutual bonding of at least two of Q, M and L₁ so as to form, for example, a propylene group or a butylene group and subsequent formation of a 5-membered or 6-membered ring containing an oxygen atom.

Substituents may be introduced in the groups represented by L₁, L₂, M and Q in general formula (6-A). As the substituents, there can be mentioned, for example, those mentioned above as being optionally introduced in R₃₆ to R₃₉, R₀₁, R₀₂ and Ar. Preferably, the number of carbon atoms of each of the substituents is up to 8.

The groups of the formula -M-Q are preferably groups each composed of 1 to 30 carbon atoms, more preferably 5 to 20 carbon atoms.

Particular examples of the repeating units of general formula (6) are shown below as preferred particular examples of the repeating units (B), which however in no way limit the scope of the present invention.

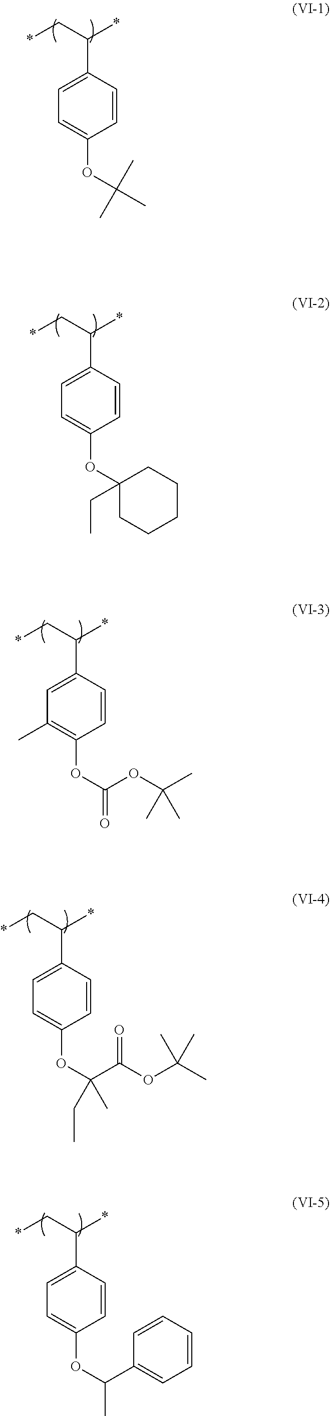

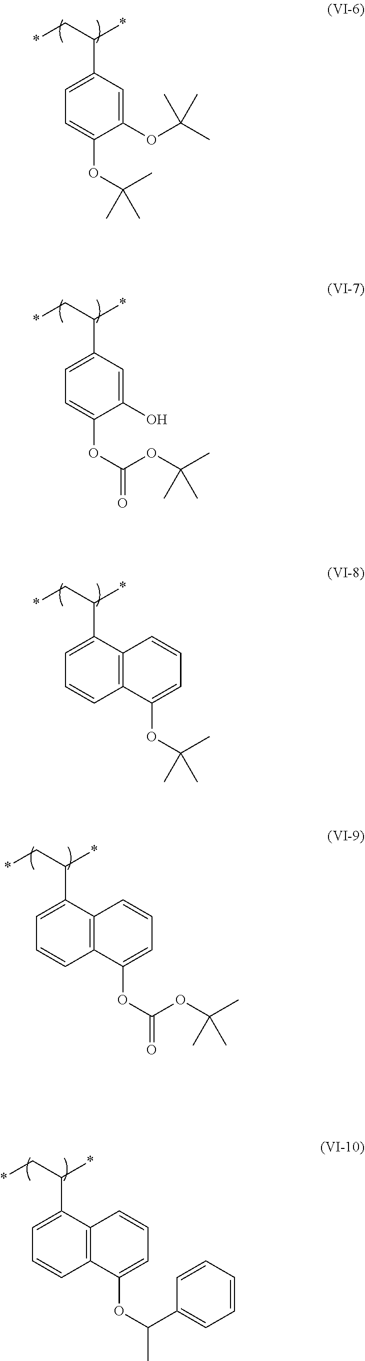

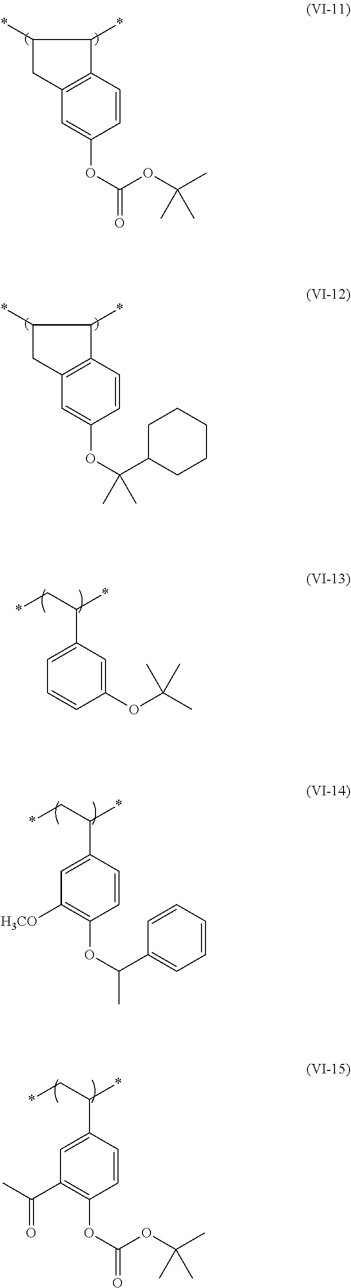

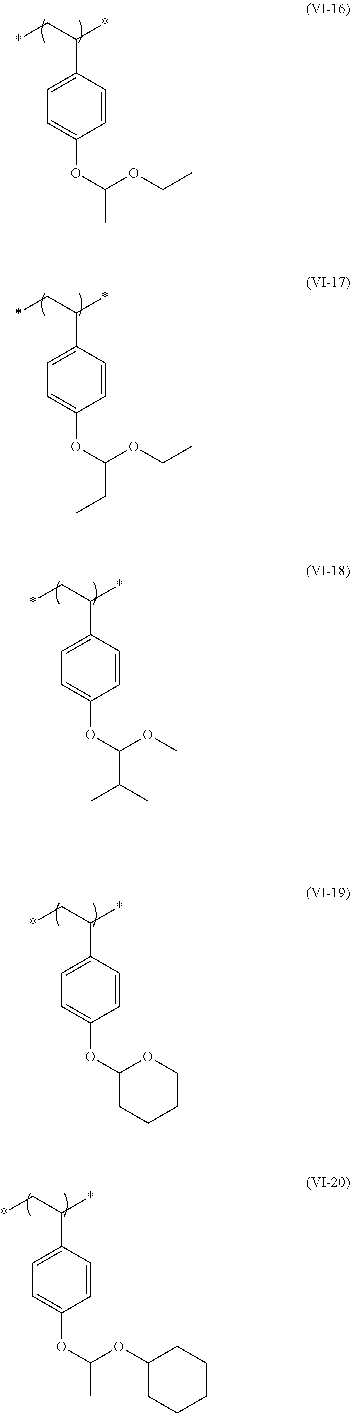

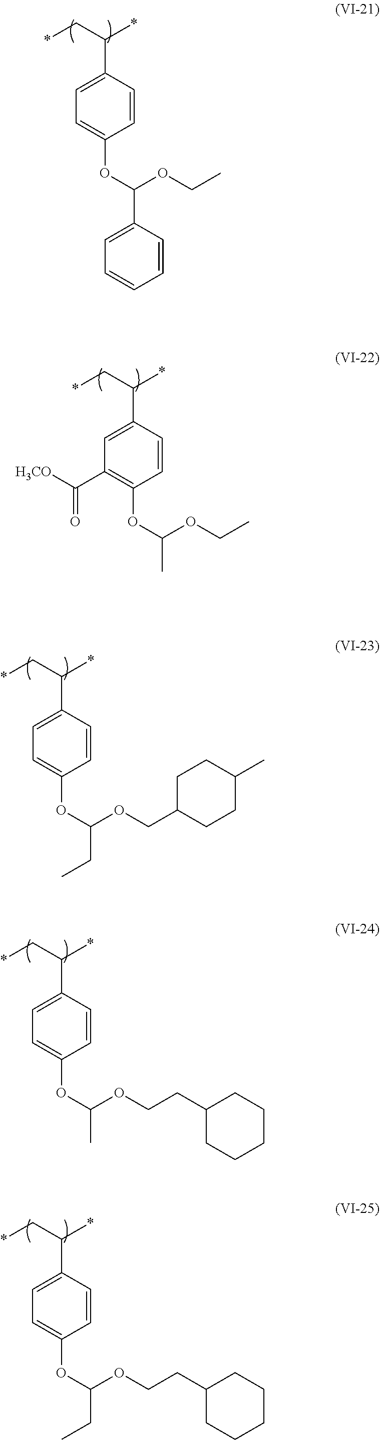

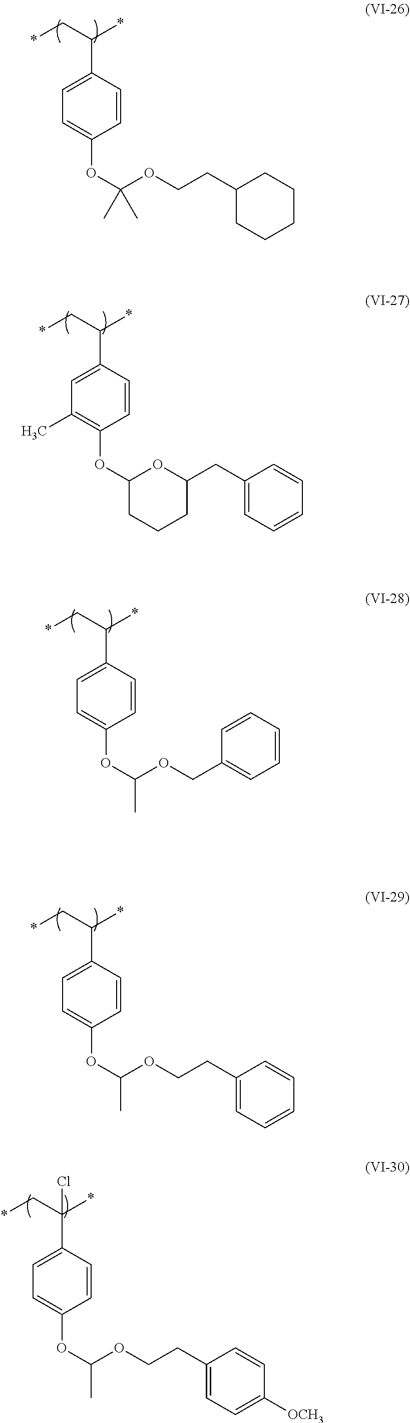

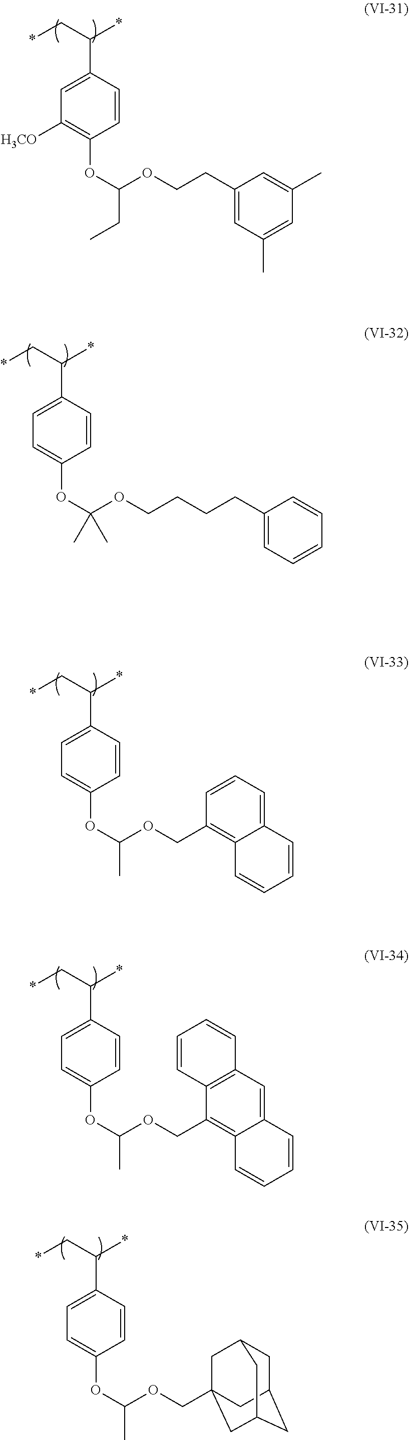

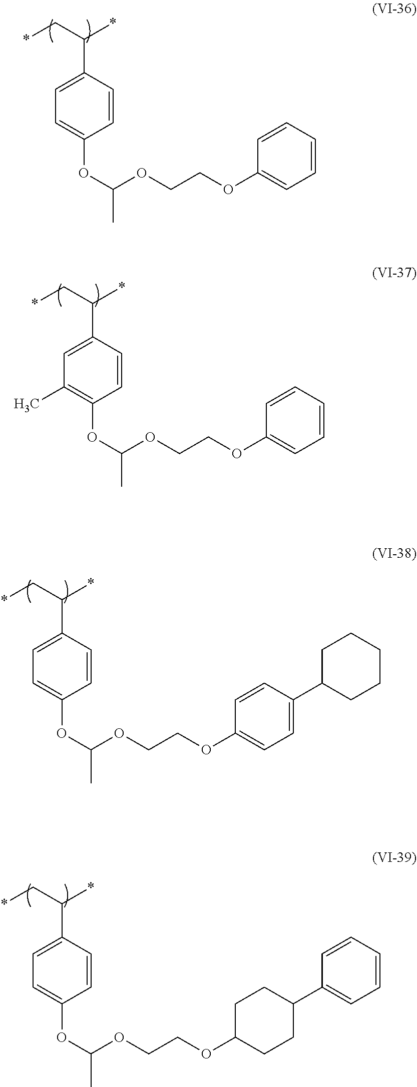

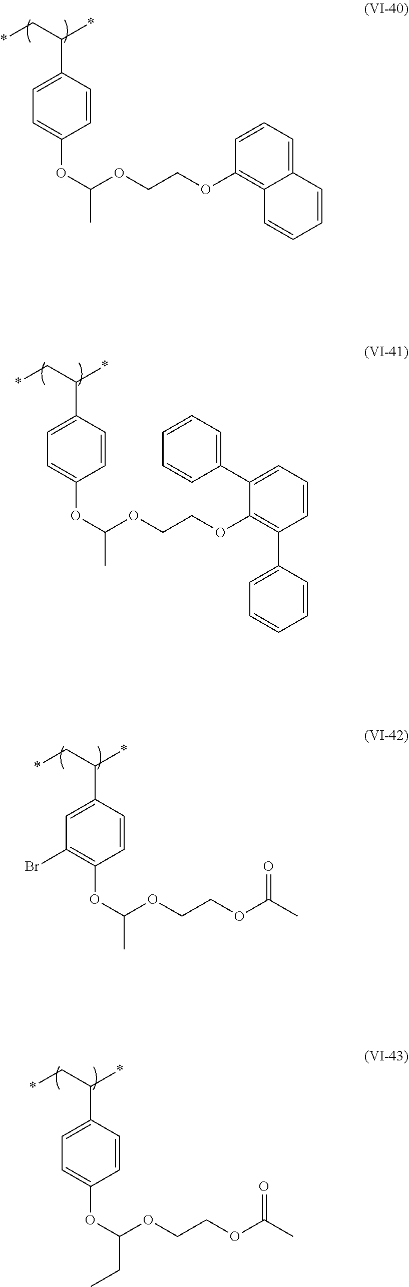

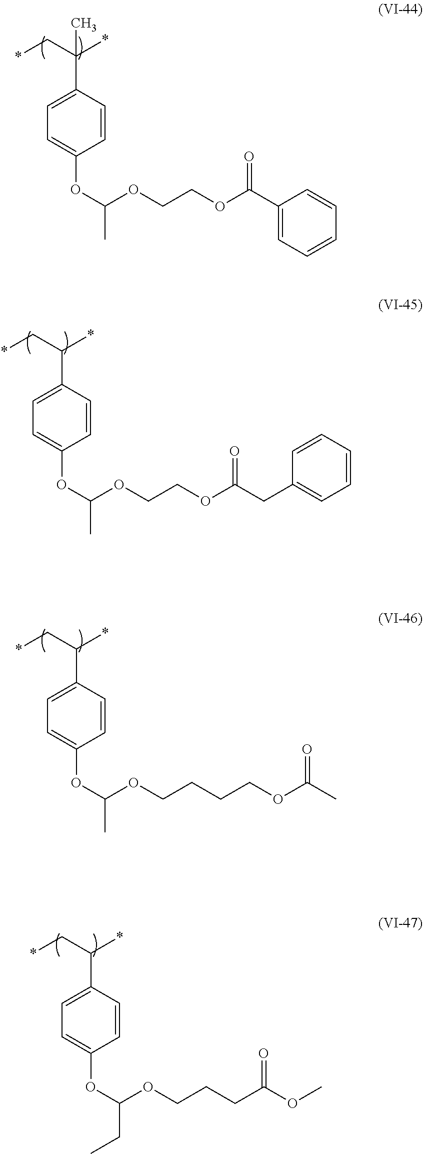

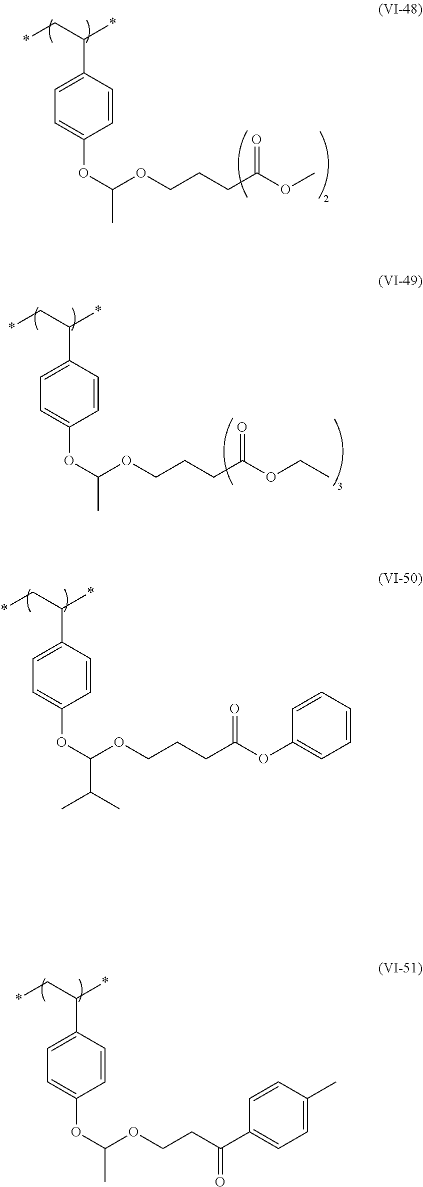

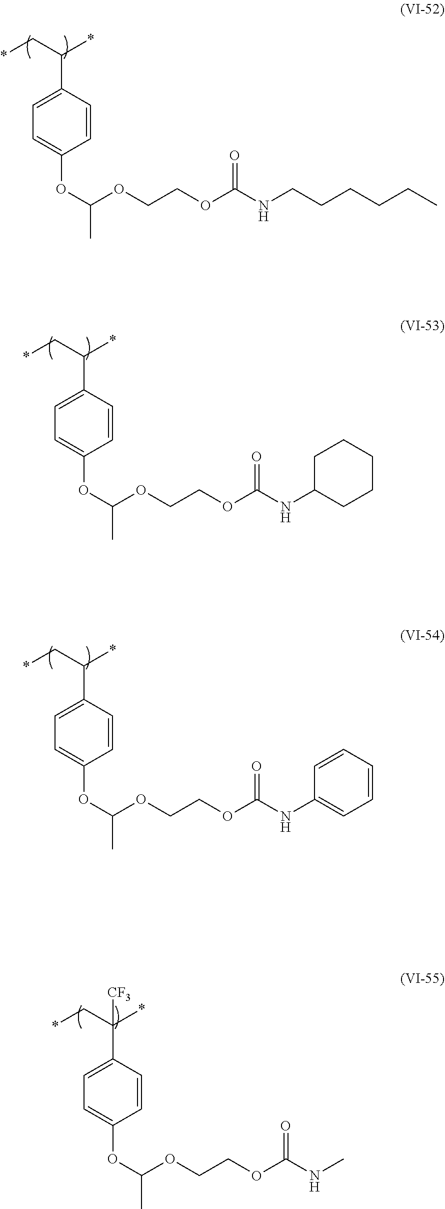

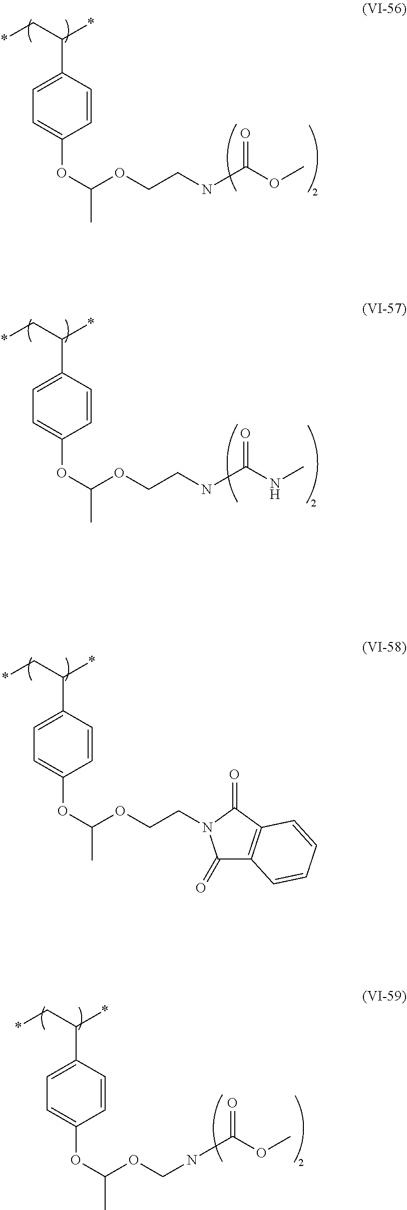

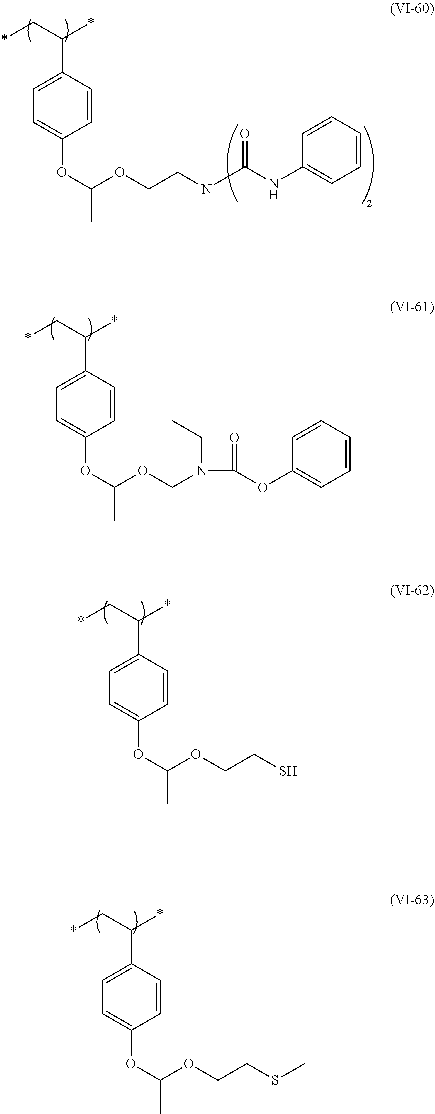

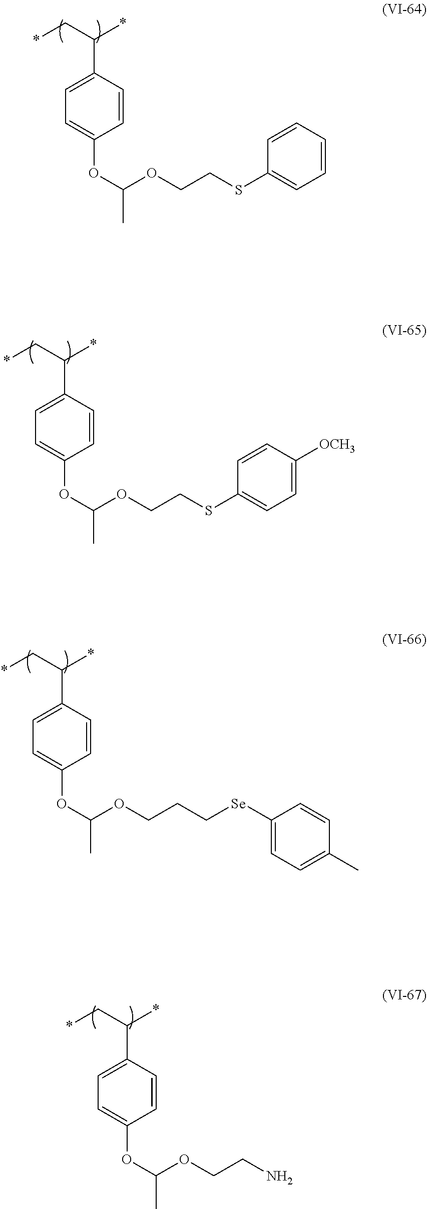

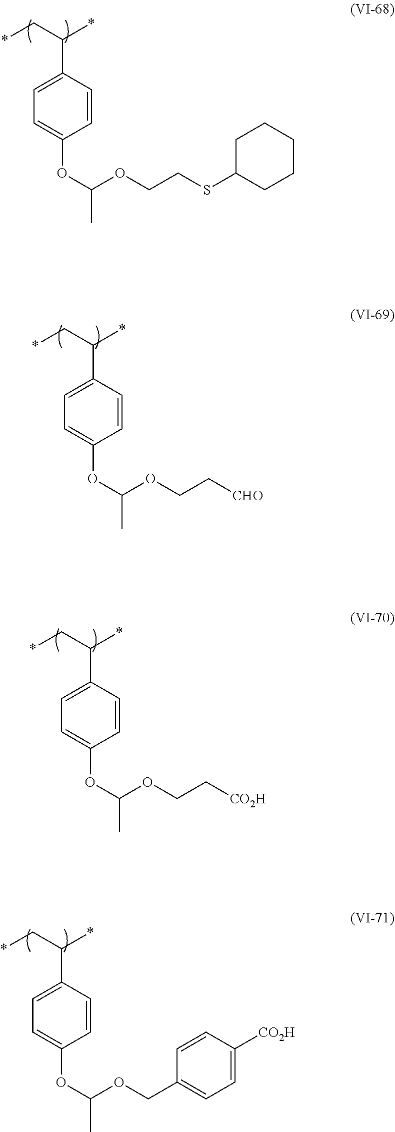

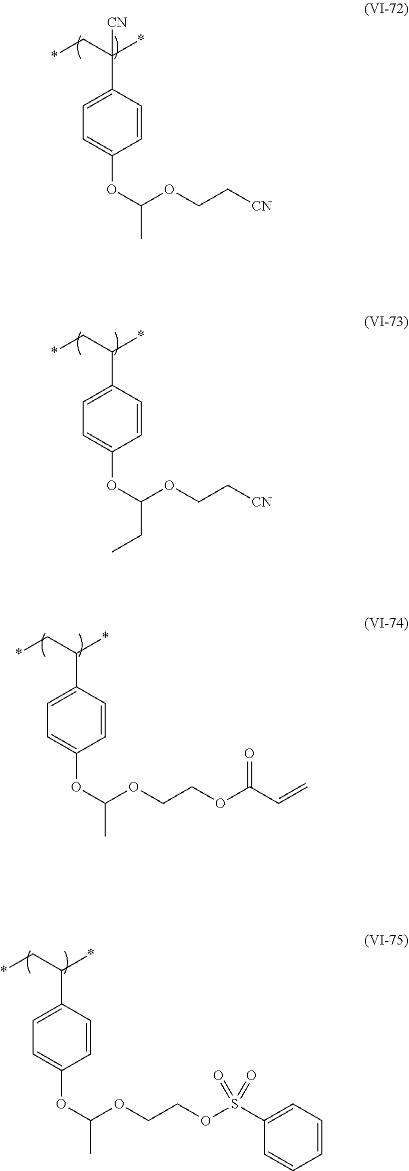

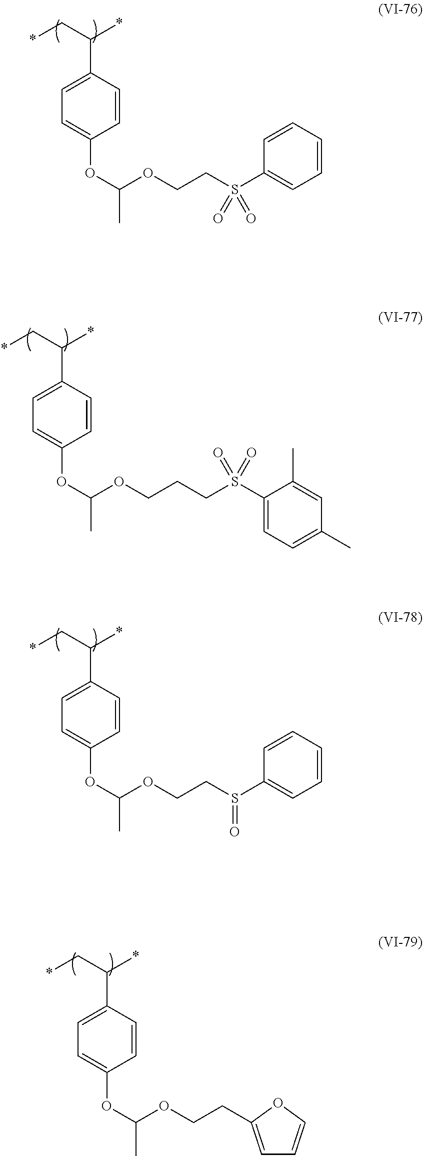

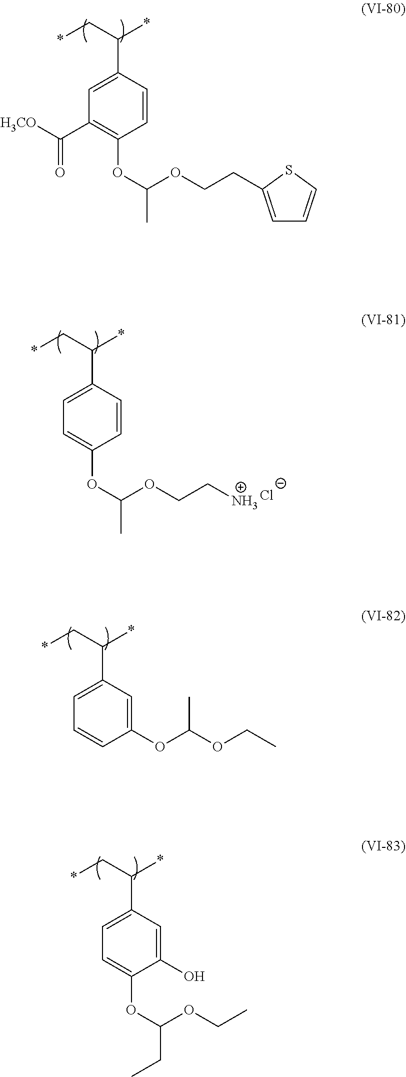

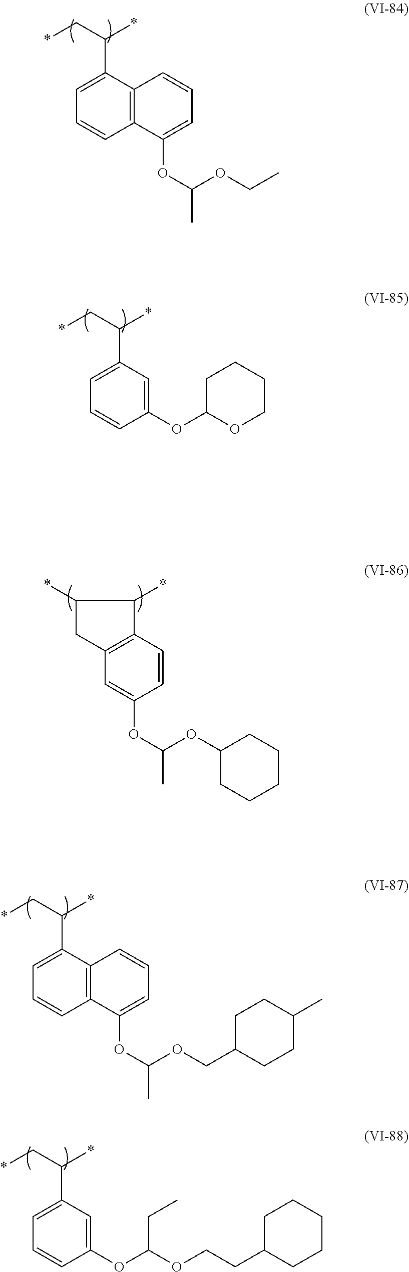

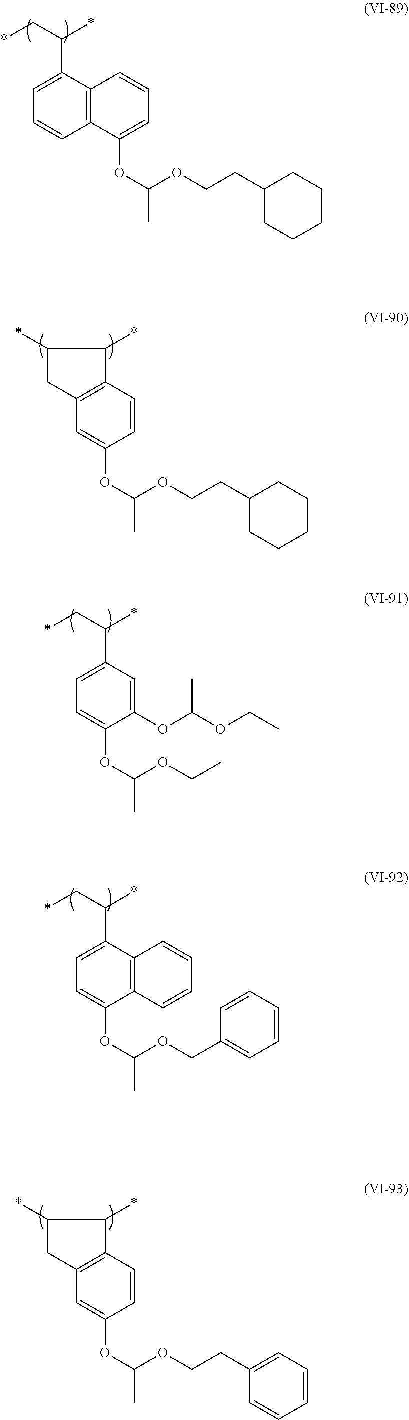

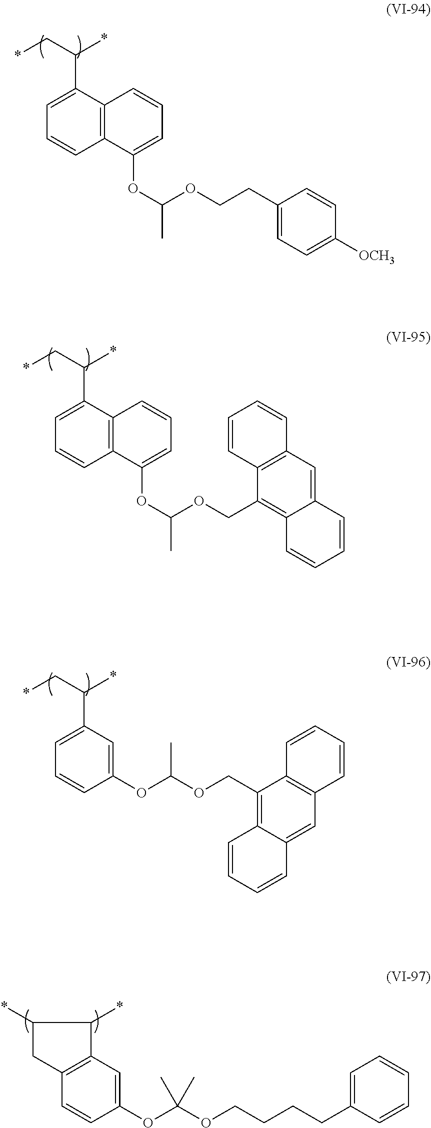

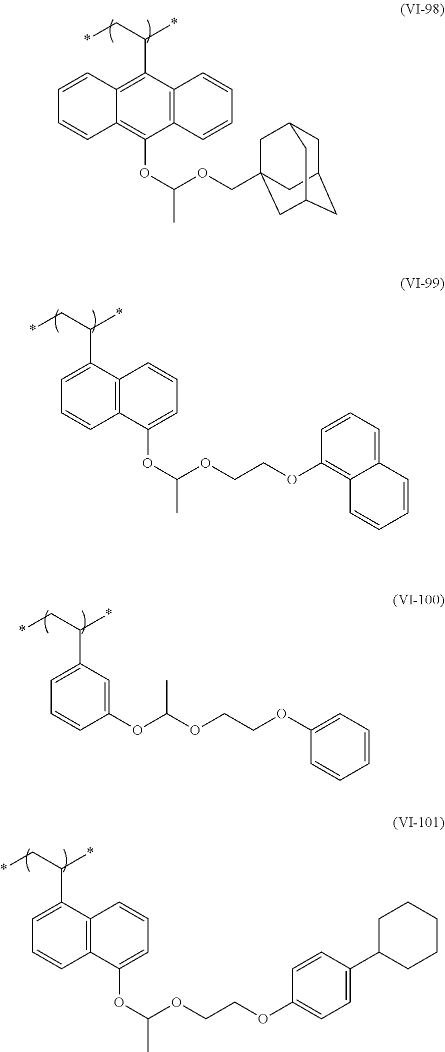

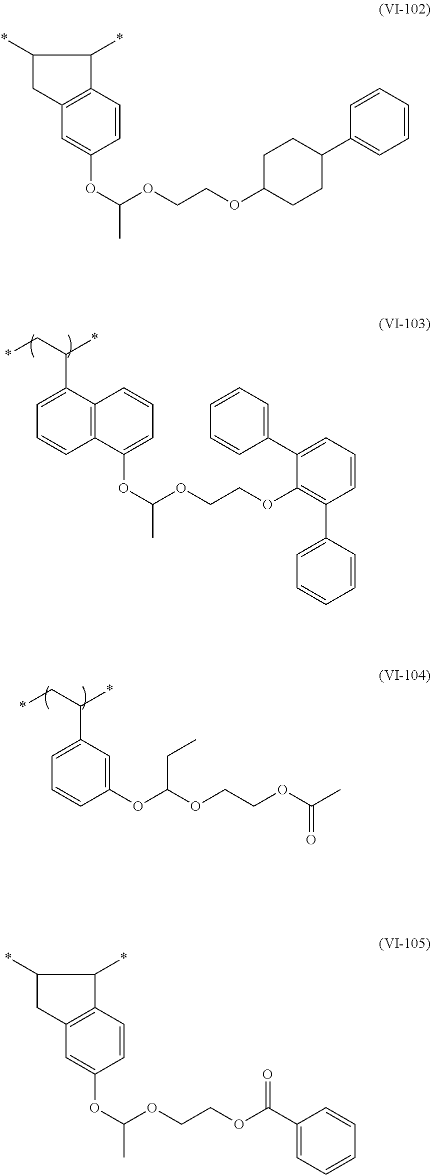

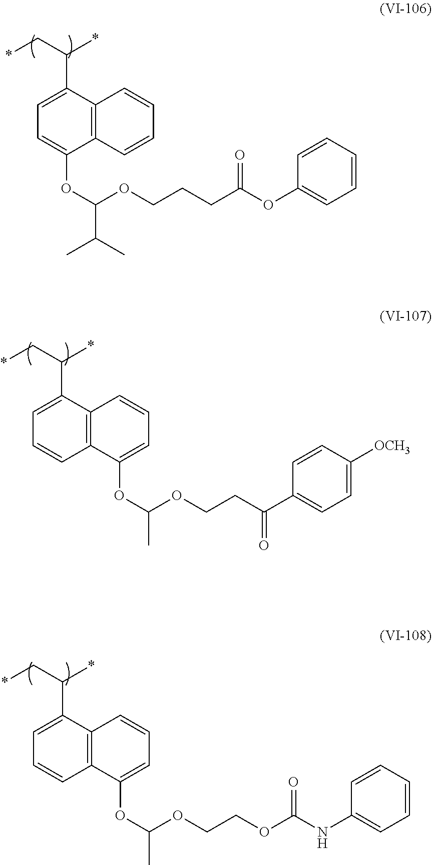

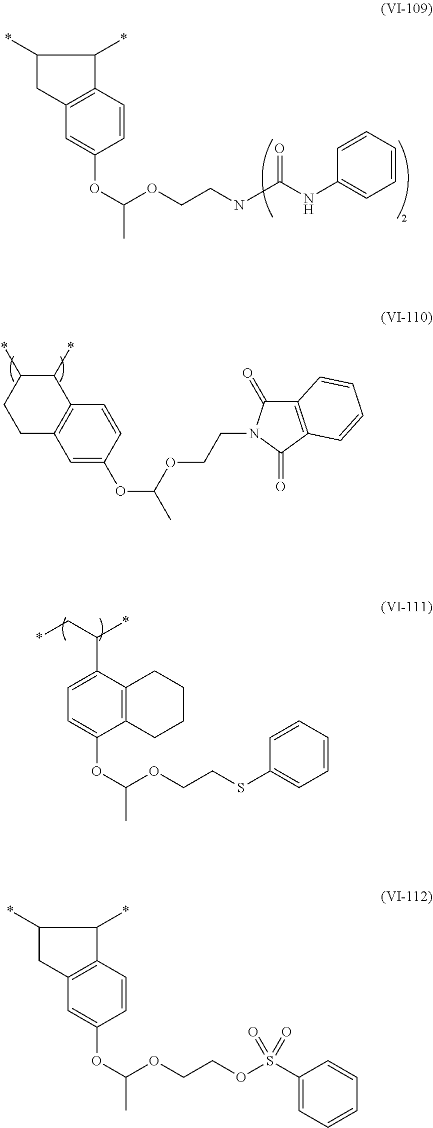

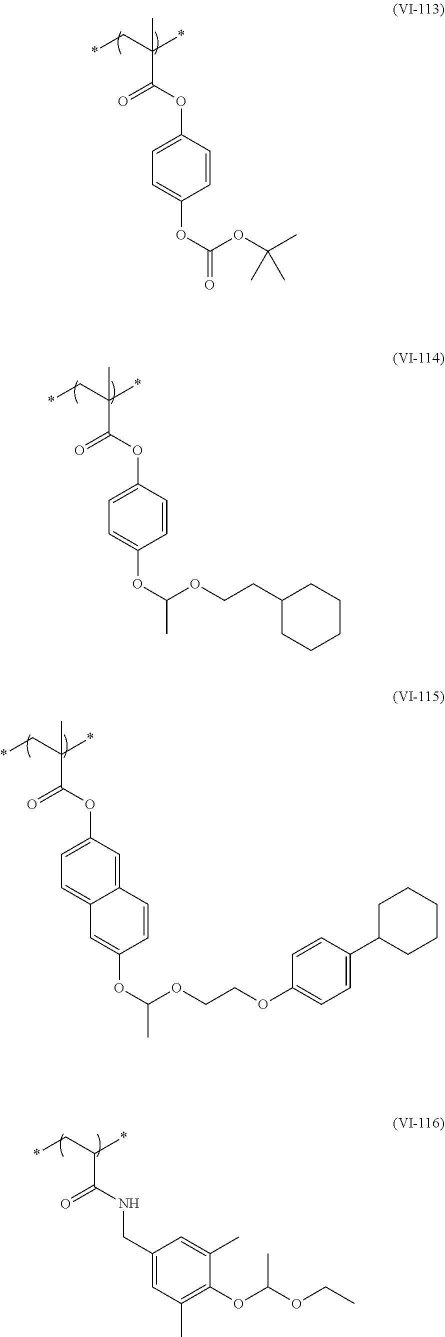

Furthermore, the resin (P) may contain any of the repeating units of general formula (BZ) below as the repeating unit (B). This is especially preferred when the exposure is performed using electron beams or EUV light.

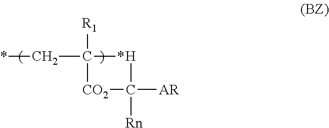

In general formula (BZ), AR represents an aryl group. Rn represents an alkyl group, a cycloalkyl group or an aryl group. Rn and AR may be bonded to each other to thereby form a nonaromatic ring.

R₁ represents a hydrogen atom, an alkyl group, a cycloalkyl group, a halogen atom, a cyano group or an alkyloxycarbonyl group.

The aryl group represented by AR is preferably one having 6 to 20 carbon atoms, such as a phenyl group, a naphthyl group, an anthryl group or a fluorene group. An aryl group having 6 to 15 carbon atoms is more preferred.

When AR is a naphthyl group, an anthryl group or a fluorene group, the position of bonding of AR to the carbon atom to which Rn is bonded is not particularly limited. For example, when AR is a naphthyl group, the carbon atom may be bonded to whichever position, α-position or R-position, of the naphthyl group. When AR is an anthryl group, the carbon atom may be bonded to any of the 1-position, 2-position and 9-position of the anthryl group.

One or more substituents may be introduced in each of the aryl groups represented by AR. As particular examples of such substituents, there can be mentioned a linear or branched alkyl group having 1 to 20 carbon atoms, such as a methyl group, an ethyl group, a propyl group, an isopropyl group, an n-butyl group, an isobutyl group, a t-butyl group, a pentyl group, a hexyl group, an octyl group or a dodecyl group; an alkoxy group containing any of these alkyl groups as its part; a cycloalkyl group, such as a cyclopentyl group or a cyclohexyl group; a cycloalkoxy group containing such a cycloalkyl group as its part; a hydroxyl group; a halogen atom; an aryl group; a cyano group; a nitro group; an acyl group; an acyloxy group; an acylamino group; a sulfonylamino group; an alkylthio group; an arylthio group; an aralkylthio group; a thiophenecarbonyloxy group; a thiophenemethylcarbonyloxy group; and a heterocyclic residue, such as a pyrrolidone residue. Among these substituents, a linear or branched alkyl group having 1 to 5 carbon atoms and an alkoxy group containing the alkyl group as its part are preferred. A paramethyl group and a paramethoxy group are more preferred.

When a plurality of substituents are introduced in the aryl group represented by AR, at least two members of the plurality of substituents may be bonded to each other to thereby form a ring. The ring is preferably a 5- to 8-membered one, more preferably a 5- or 6-membered one. Further, this ring may be a heteroring containing a heteroatom, such as an oxygen atom, a nitrogen atom or a sulfur atom, as a ring member.

A substituent may further be introduced in this ring. The substituent is the same as the further substituent mentioned below as being introducible in Rn.

From the viewpoint of roughness performance, it is preferred for each of the repeating units (B) of general formula (BZ) to contain two or more aromatic rings. Generally, the number of aromatic rings introduced in the repeating unit (B) is preferably up to 5, more preferably up to 3.

Also, from the viewpoint of roughness performance, it is preferred for AR of each of the repeating units (B) of general formula (BZ) to contain two or more aromatic rings. More preferably, AR is a naphthyl group or a biphenyl group. Generally, the number of aromatic rings introduced in AR is preferably up to 5, more preferably up to 3.

As mentioned above, Rn represents an alkyl group, a cycloalkyl group or an aryl group. It is preferred for Rn to be an alkyl group or a cycloalkyl group.

The alkyl group represented by Rn may be in the form of a linear or branched chain. As a preferred alkyl group, there can be mentioned an alkyl group having 1 to 20 carbon atoms, such as a methyl group, an ethyl group, a propyl group, an isopropyl group, an n-butyl group, an isobutyl group, a t-butyl group, a pentyl group, a hexyl group, an octyl group or a dodecyl group. The alkyl group represented by Rn more preferably has 1 to 5 carbon atoms, further more preferably 1 to 3 carbon atoms.

As the cycloalkyl group represented by Rn, there can be mentioned, for example, one having 3 to 15 carbon atoms, such as a cyclopentyl group or a cyclohexyl group.

The aryl group represented by Rn is preferably, for example, one having 6 to 14 carbon atoms, such as a phenyl group, a xylyl group, a tolyl group, a cumenyl group, a naphthyl group or an anthryl group.

Substituents may further be introduced in the alkyl group, cycloalkyl group and aryl group represented by Rn. As such substituents, there can be mentioned, for example, an alkoxy group, a hydroxyl group, a halogen atom, a nitro group, an acyl group, an acyloxy group, an acylamino group, a sulfonylamino group, a dialkylamino group, an alkylthio group, an arylthio group, an aralkylthio group, a thiophenecarbonyloxy group, a thiophenemethylcarbonyloxy group, and a heterocyclic residue, such as a pyrrolidone residue. Among these substituents, an alkoxy group, a hydroxyl group, a halogen atom, a nitro group, an acyl group, an acyloxy group, an acylamino group and a sulfonylamino group are especially preferred.

As mentioned above, R₁ represents a hydrogen atom, an alkyl group, a cycloalkyl group, a halogen atom, a cyano group or an alkyloxycarbonyl group.

The alkyl group and cycloalkyl group represented by R₁ are, for example, the same as mentioned above in connection with Rn. Substituents may be introduced in the alkyl group and cycloalkyl group. The substituents are, for example, the same as set forth above in connection with Rn.

When R₁ is a substituted alkyl group or cycloalkyl group, it is especially preferred for R₁ to be, for example, a trifluoromethyl group, an alkyloxycarbonylmethyl group, an alkylcarbonyloxymethyl group, a hydroxymethyl group or an alkoxymethyl group.

As the halogen atom represented by R₁, there can be mentioned a fluorine atom, a chlorine atom, a bromine atom or an iodine atom. A fluorine atom is most preferred.

As the part of alkyl group contained in the alkyloxycarbonyl group represented by R₁, there can be employed, for example, any of the structures mentioned above as the alkyl group represented by R₁.

Preferably, Rn and AR are bonded to each other to thereby form a nonaromatic ring. In particular, this can enhance the roughness performance.

The nonaromatic ring that may be formed by the mutual bonding of Rn and AR is preferably a 5- to 8-membered ring, more preferably a 5- or 6-membered ring.

The nonaromatic ring may be an aliphatic ring or a heteroring containing a heteroatom, such as an oxygen atom, a nitrogen atom or a sulfur atom, as a ring member.

A substituent may be introduced in the nonaromatic ring. The substituent is, for example, the same as the further substituent mentioned above as being introducible in Rn.

Non-limiting specific examples of the repeating units (B) of general formula (BZ) are shown below.

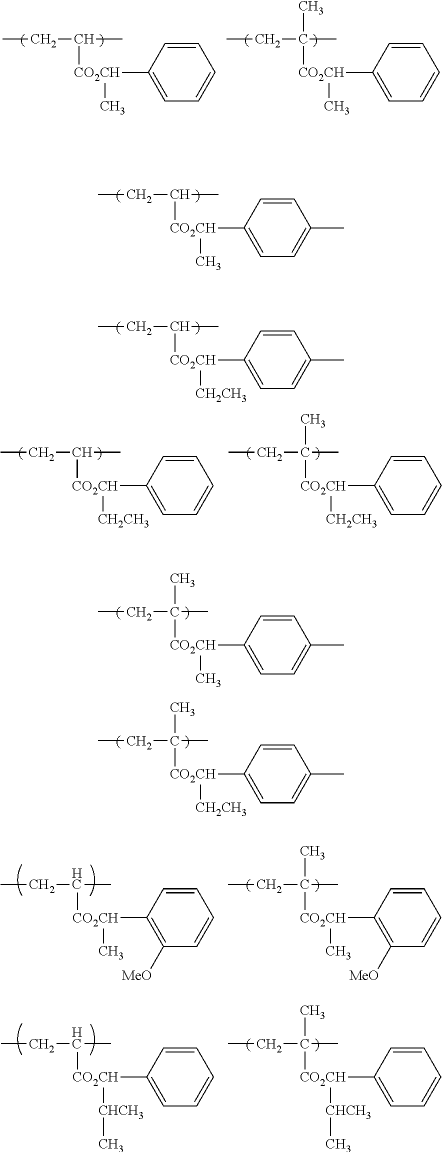

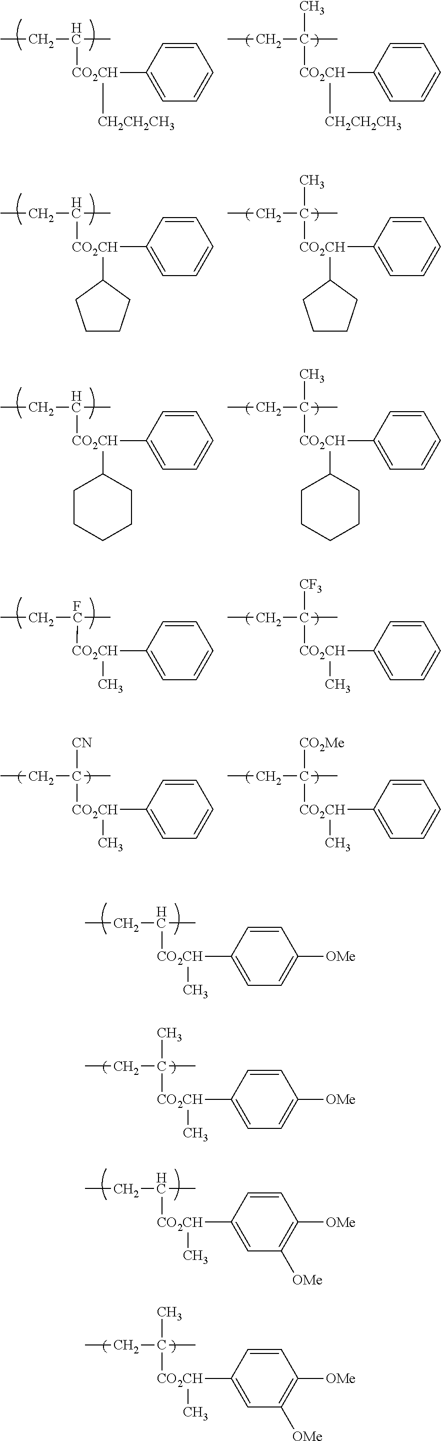

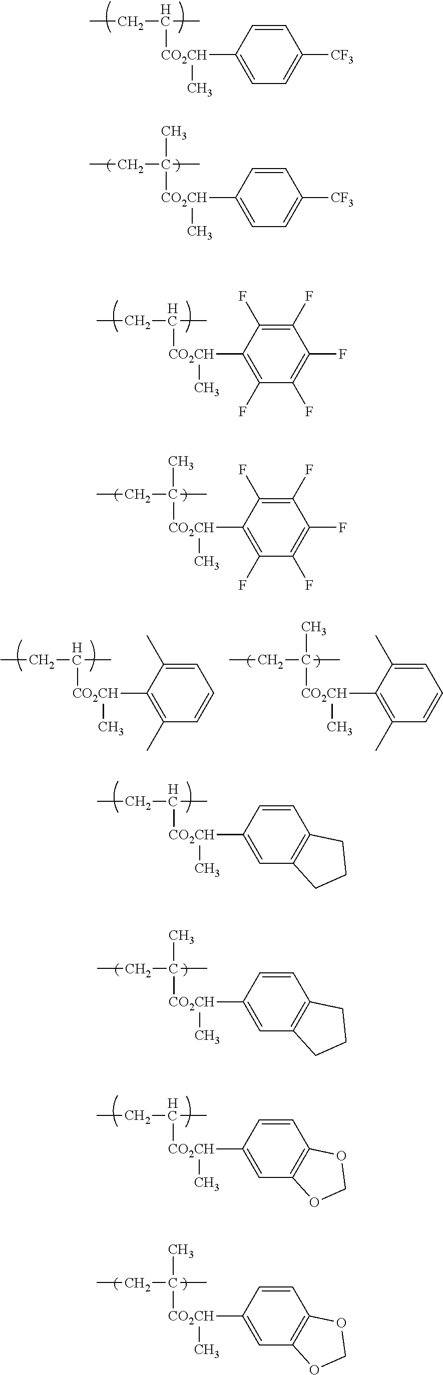

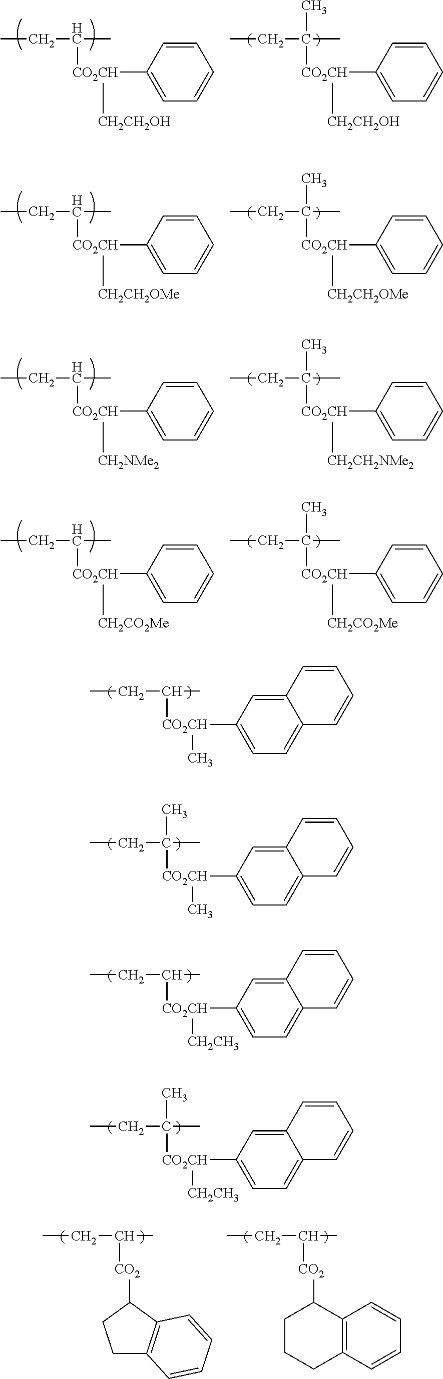

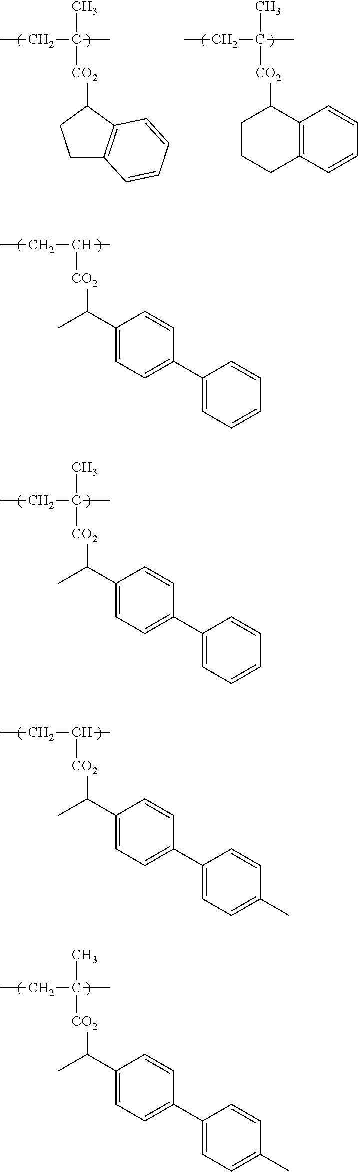

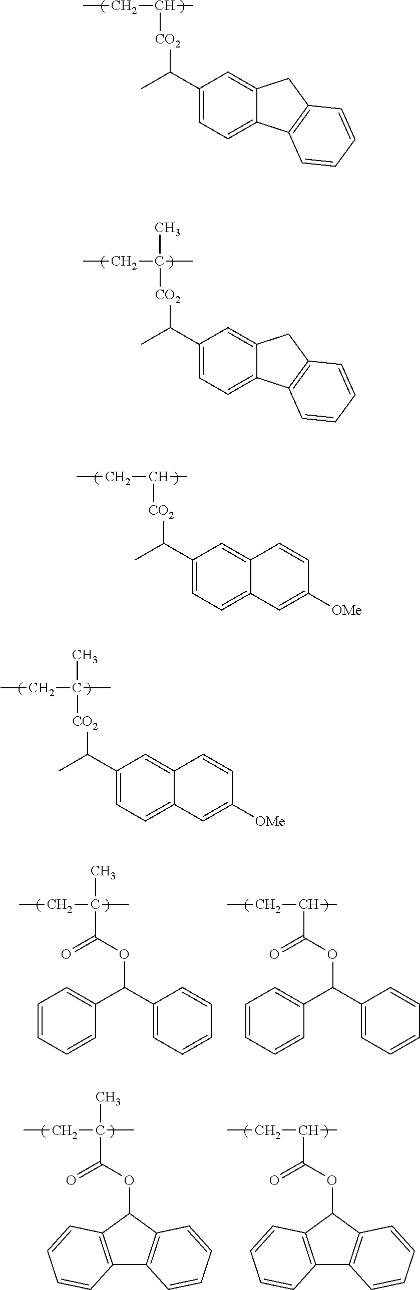

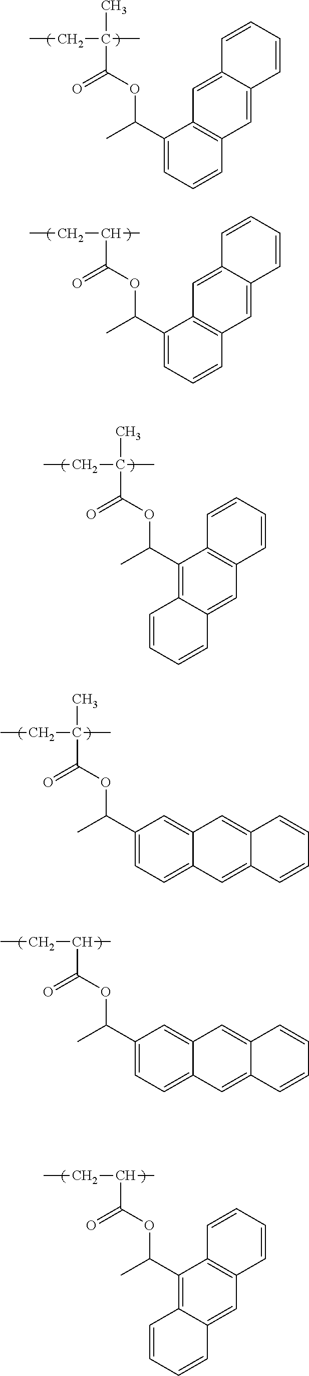

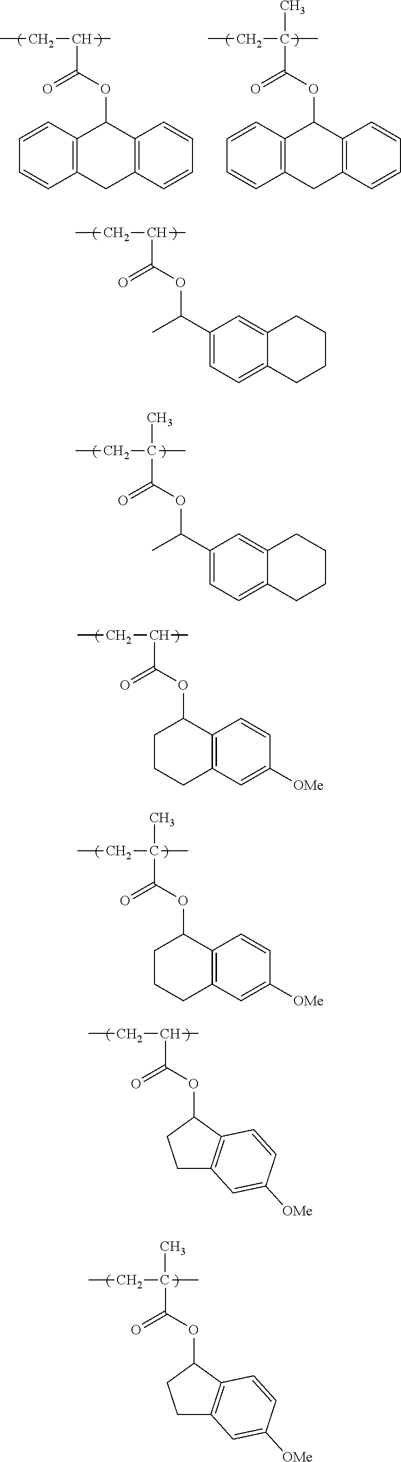

Two or more types of acid-decomposable repeating units (B) may be contained in the resin (P).

The content of repeating unit (B) in the resin (P), based on all the repeating units of the resin, is preferably in the range of 3 to 90 mol %, more preferably 5 to 80 mol % and most preferably 7 to 70 mol %.

Repeating Unit (C)>

The resin (P) may further contain a repeating unit (C) containing an alkali-soluble group. The alkali-soluble group is preferably one comprising an aromatic ring group.

The repeating unit (C) preferably has the structure of general formula (7) below.

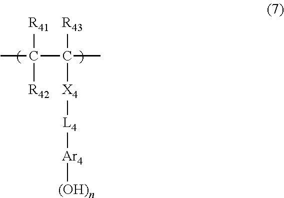

In the formula,

each of R₄₁, R₄₂ and R₄₃ independently represents a hydrogen atom, an alkyl group, a halogen atom, a cyano group or an alkoxycarbonyl group.

X₄ represents a single bond, —COO— or —CONR₆₄— in which R₆₄ represents a hydrogen atom or an alkyl group.

L₄ represents a single bond or an alkylene group.

Ar₄ represents a (n+1)-valent aromatic ring group, provided that Ar₄ may be bonded to R₄₂ to thereby form a ring, which Ar₄ is a (n+2)-valent aromatic ring group, and

n is an integer of 1 to 4.

Particular examples of the alkyl groups, cycloalkyl groups, halogen atoms and alkoxycarbonyl groups represented by R₄₁, R₄₂ and R₄₃ in formula (7) and substituents introducible therein are the same as set forth above in connection with general formula (5).

A substituent may be introduced in the aromatic ring group represented by Ar₄. As preferred examples of the aromatic ring groups, there can be mentioned an arylene group having 6 to 18 carbon atoms, such as a phenylene group, a tolylene group, a naphthylene group or an anthracenylene group, and an aromatic ring group containing a heteroring, such as thiophene, furan, pyrrole, benzothiophene, benzofuran, benzopyrrole, triazine, imidazole, benzimidazole, triazole, thiadiazole or thiazole.

Preferred substituents that can be introduced in these groups include an alkyl group, an alkoxy group such as a methoxy group, an ethoxy group, a hydroxyethoxy group, a propoxy group, a hydroxypropoxy group or a butoxy group and an aryl group such as a phenyl group, as mentioned above in connection with R₅₁ to R₅₃ of general formula (5).

The alkyl group represented by R₆₄ of the —CONR₆₄—(R₆₄ represents a hydrogen atom or an alkyl group) represented by X₄ is the same as set forth above as the alkyl group represented by each of R₆₁ to R₆₃.

X₄ is preferably a single bond, —COO— or —CONH—, more preferably a single bond or —COO—.

The alkylene group represented by L₄ is preferably an optionally substituted alkylene group having 1 to 8 carbon atoms, such as a methylene group, an ethylene group, a propylene group, a butylene group, a hexylene group or an octylene group.

Ar₄ is more preferably an optionally substituted arylene group having 6 to 18 carbon atoms. A phenylene group, a naphthylene group and a biphenylene group are most preferred.

It is preferred for the repeating unit (C) to contain a hydroxystyrene structure. Namely, it is preferred for Ar₄ to be a phenylene group.

Particular examples of the repeating units (C) of general formula (7) are shown below, which in no way limit the scope of the present invention. In the following formulae, a is an integer of 0 to 2.

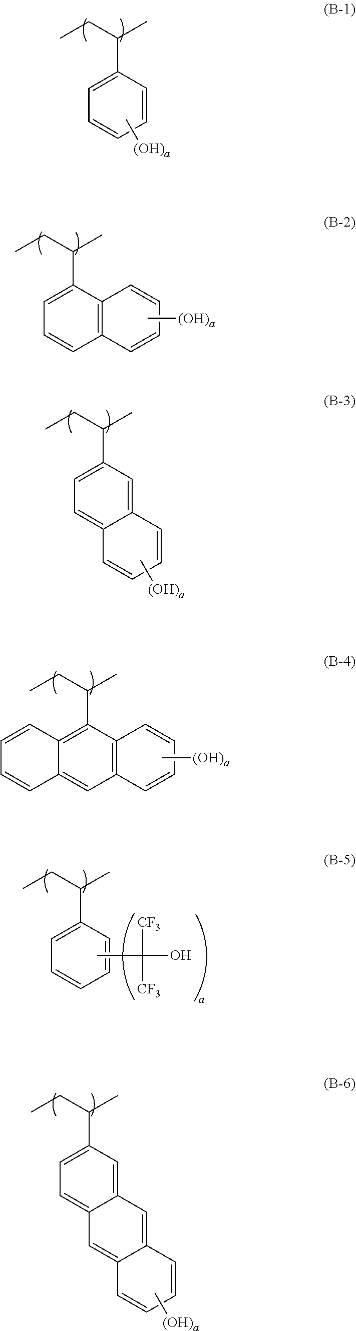

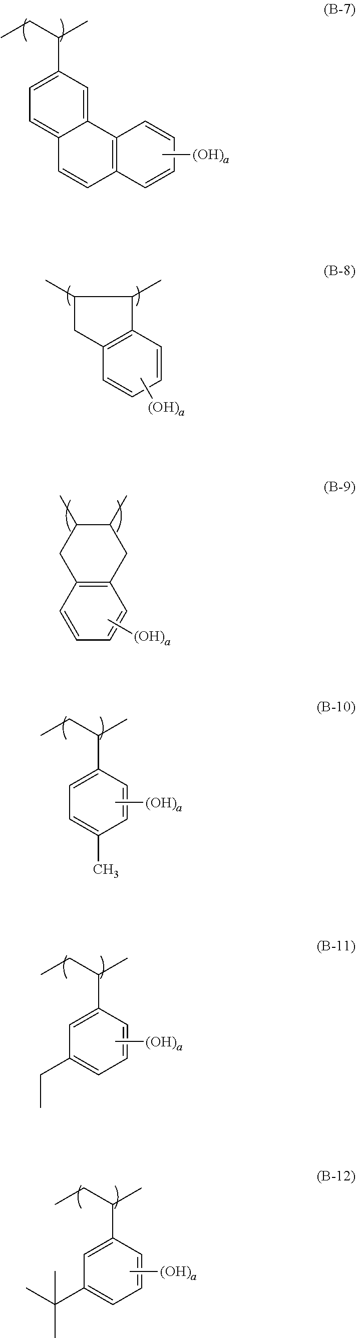

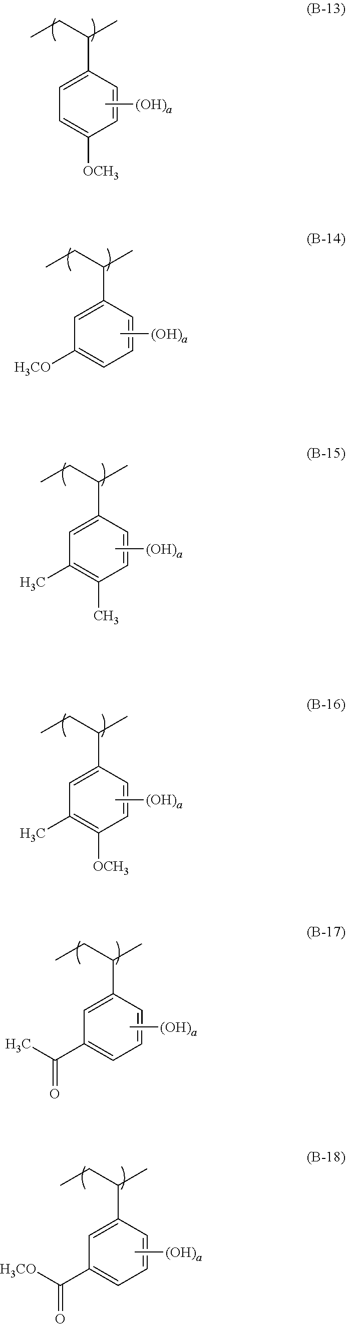

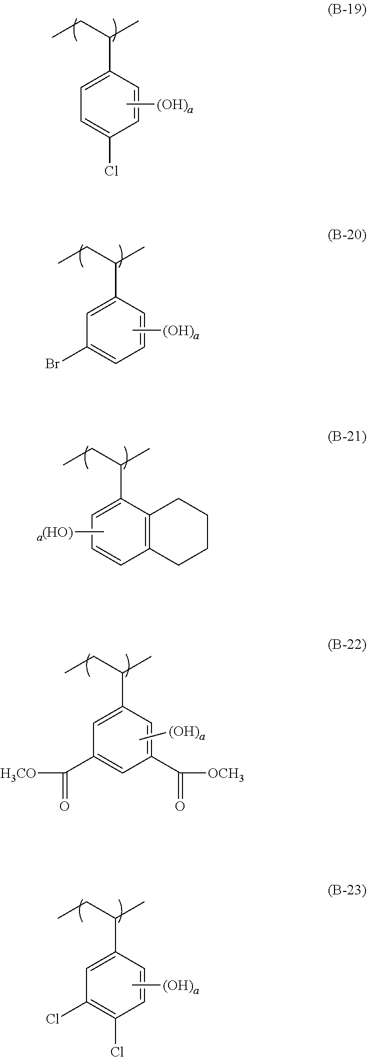

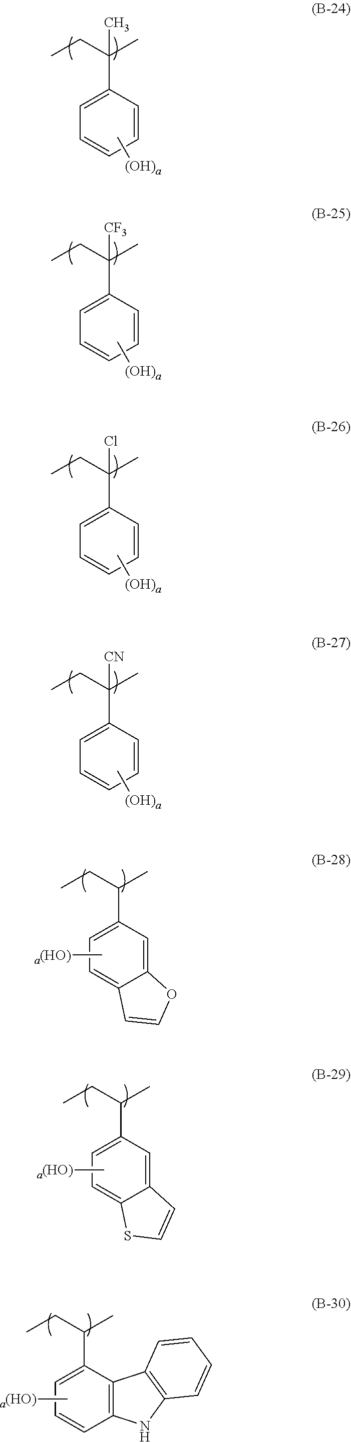

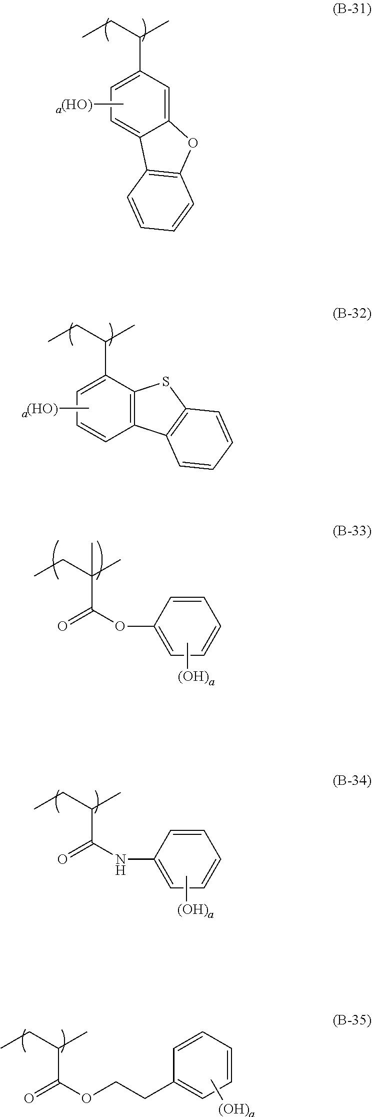

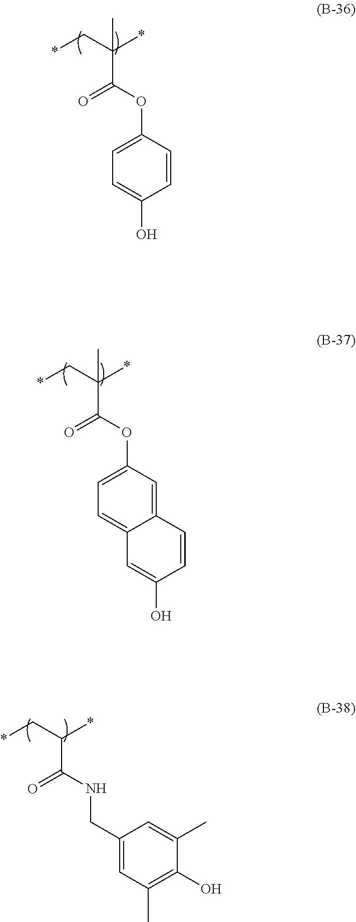

The resin (P) may comprise two or more types of repeating units (C).

The content of repeating unit (C) containing an alkali-soluble group, expressed by general formula (7) is preferably in the range of 5 to 90 mol %, more preferably 10 to 80 mol % and further more preferably 20 to 70 mol %, based on all the repeating units of the resin (P).

<Repeating Unit (D)>

The resin (P) may further contain a repeating unit (D) that contains a group that when acted on by an alkali developer, is decomposed to thereby increase its rate of dissolution in the alkali developer.

As the group that when acted on by an alkali developer, is decomposed to thereby increase its rate of dissolution in the alkali developer, there can be mentioned, for example, a lactone structure, phenylester structure or the like.

The repeating unit (D) is more preferably any of those of general formula (AII), below.

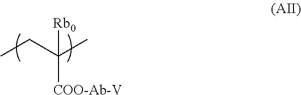

In general formula (AII),

V represents a group that when acted on by an alkali developer, is decomposed to thereby increase its rate of dissolution in the alkali developer.

Ab represents a single bond, an alkylene group, a bivalent connecting group with a cycloalkyl structure of a single ring or multiple rings, an ether group, an ester group, a carbonyl group, or a bivalent connecting group resulting from combination thereof.

Rb₀ represents a hydrogen atom, a halogen atom or an alkyl group.

The alkyl group represented by Rb₀ is preferably one having 1 to 4 carbon atoms. A substituent may be introduced in the alkyl group. As preferred substituents, there can be mentioned a hydroxyl group and a halogen atom. As the halogen atom represented by Rb₀, there can be mentioned a fluorine atom, a chlorine atom, a bromine atom or an iodine atom. Rb₀ is more preferably a hydrogen atom, a methyl group, a hydroxymethyl group or a trifluoromethyl group. A hydrogen atom and a methyl group are most preferred.

Ab preferably represents a single bond and a bivalent connecting group of the formula -Ab₁-CO₂— in which Ab₁ is an alkylene group or a cyclohexylene group, being preferably a methylene group, an ethylene group, a cyclohexylene group, an adamantylene group or a norbornylene group.

V represents a group that when acted on by an alkali developer, is decomposed to thereby increase its rate of dissolution in the alkali developer. The group is preferably a group having an ester bond, more preferably a group having a lactone structure.

Lactone structures of a 5 to 7-membered ring are preferred, and in particular, those resulting from condensation of lactone structures of a 5 to 7-membered ring with other cyclic structures effected in a fashion to form a bicyclo structure or spiro structure are preferred. The possession of repeating units having a lactone structure represented by any of the following general formulae (LC1-1) to (LC1-17) is more preferred.

The lactone structures may be directly bonded to the principal chain of the resin. Preferred lactone structures are those of the formulae (LC1-1), (LC1-4), (LC1-5), (LC1-6), (LC1-13) and (LC1-14).

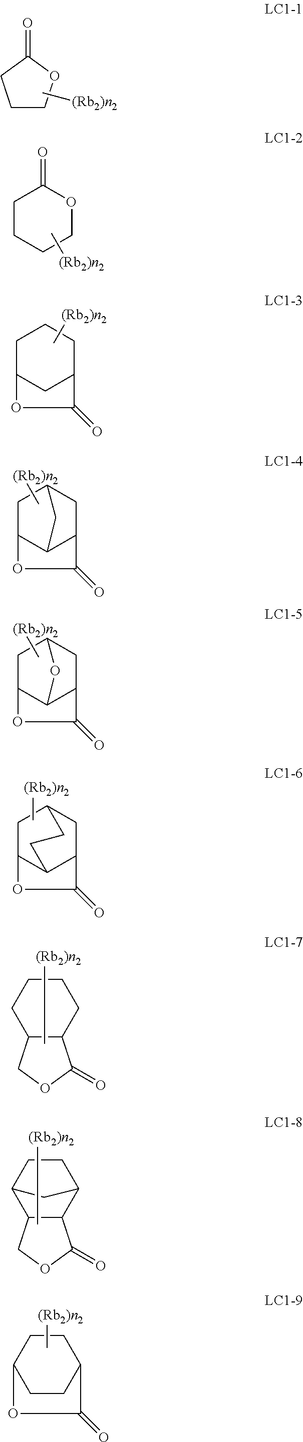

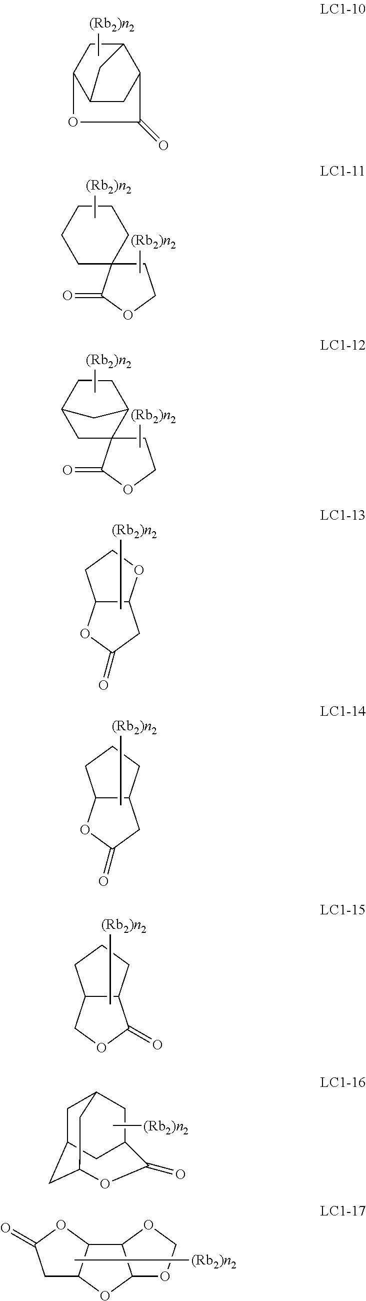

The presence of a substituent (Rb₂) on the portion of the lactone structure is optional. As a preferred substituent (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded with each other to thereby form a ring.

The repeating unit having a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or higher, more preferably 95% or higher.

When the resin (P) contains a repeating unit (D), the content ratio of the repeating unit (D) based on all the repeating units of the resin (P) is preferably in the range of 0.5 to 80 mol %, more preferably 1 to 60 mol % and still more preferably 2 to 40 mol %. The repeating unit (D) can be used either individually or in combination. The use of specified lactone structures would ensure improvement in the line edge roughness and development defect.

Specific examples of the repeating units (D) will be shown below. In the formulae, Rx represents H, CH₃, CH₂OH or CF₃.

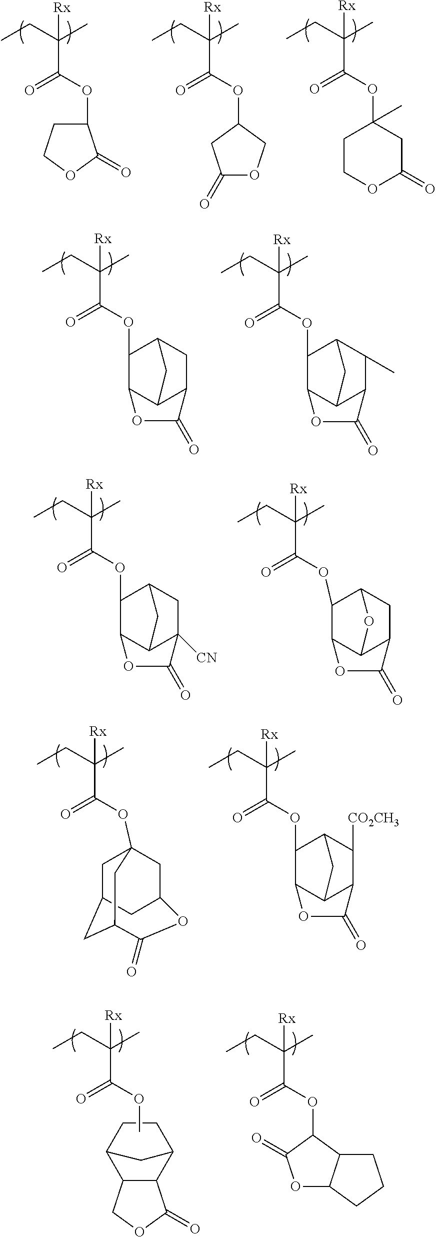

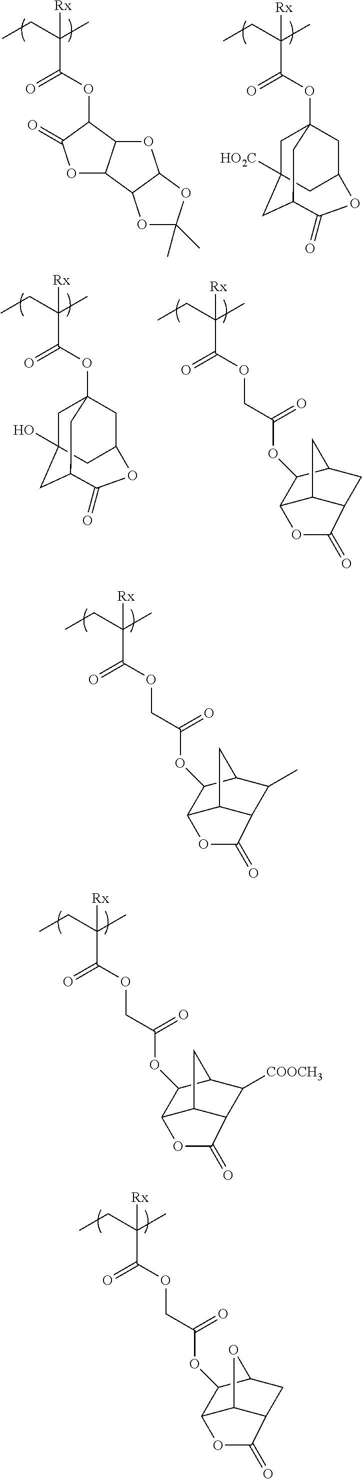

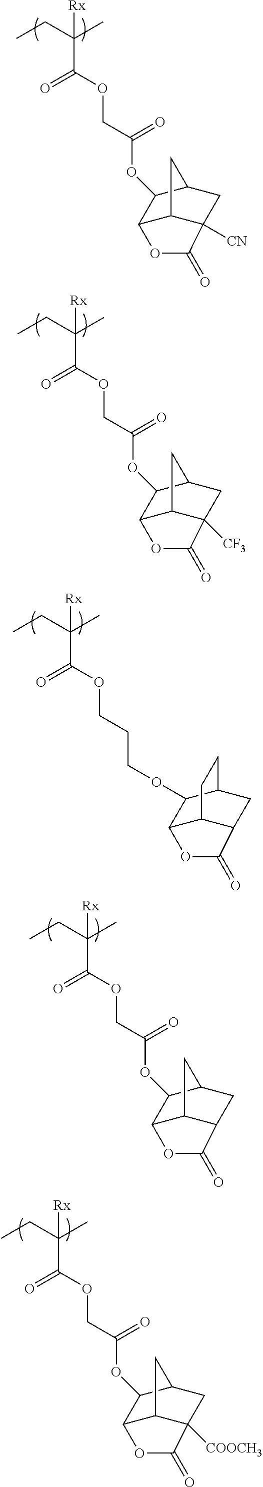

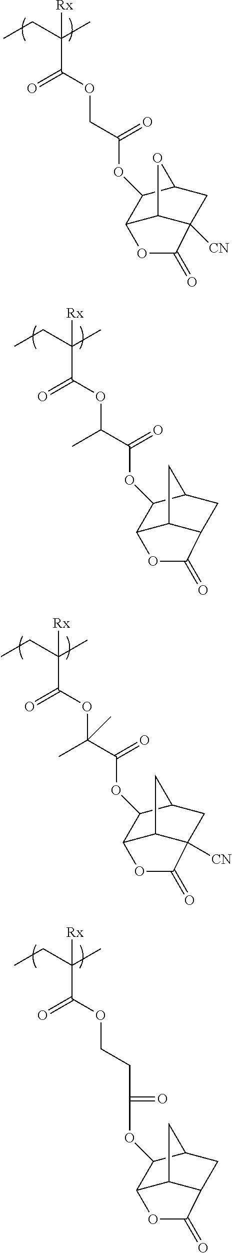

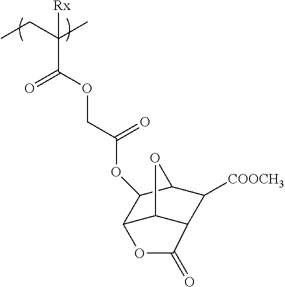

<Other Repeating Unit>

As a repeating unit other than the repeating units mentioned hereinbefore that may be introduced in the resin (P), there can be mentioned a repeating unit containing an alicyclic hydrocarbon in which a hydroxyl group or a cyano group is introduced, or a repeating unit containing an alicyclic hydrocarbon in which no polar group is introduced. It is preferred for such a repeating unit to contain substantially no acid-decomposable group.

In particular, the adherence to substrate and the developer affinity can be enhanced by the further introduction of the repeating unit containing an alicyclic hydrocarbon in which a hydroxyl group or a cyano group is introduced. The alicyclic hydrocarbon is preferably an adamantyl group, a diamantyl group or a norbornane group. As this repeating unit, there can be mentioned any of those of general formulae (AIIa) to (AIId) below.

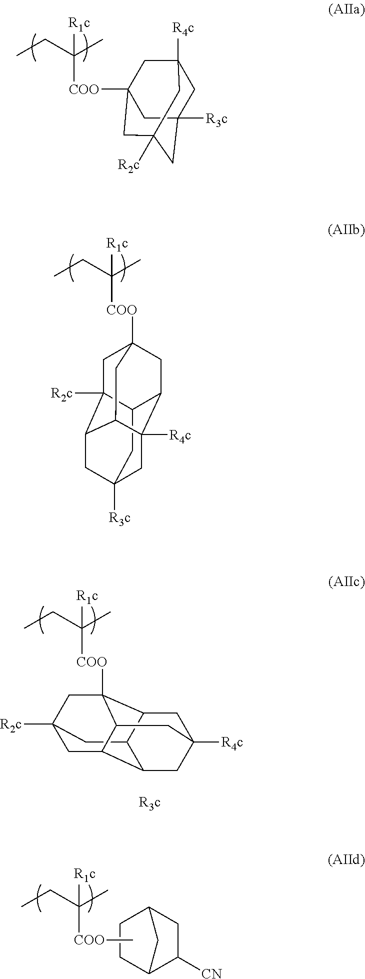

In general formulae (AIIa) to (AIId), at least one of R₂c to R₄c represents a hydroxyl group or a cyano group, and the remainder is a hydrogen atom. Preferably, one or two of R₂c to R₄c are hydroxyl groups, and the remainder is a hydrogen atom. Further more preferably, two of R₂c to R₄c are hydroxyl groups, and the remainder is a hydrogen atom. R₁c represents a hydrogen atom, a methyl group, a trifluoromethyl group or a hydroxymethyl group.

Specific examples of the repeating units each containing a hydroxyl group or a cyano group are shown below.

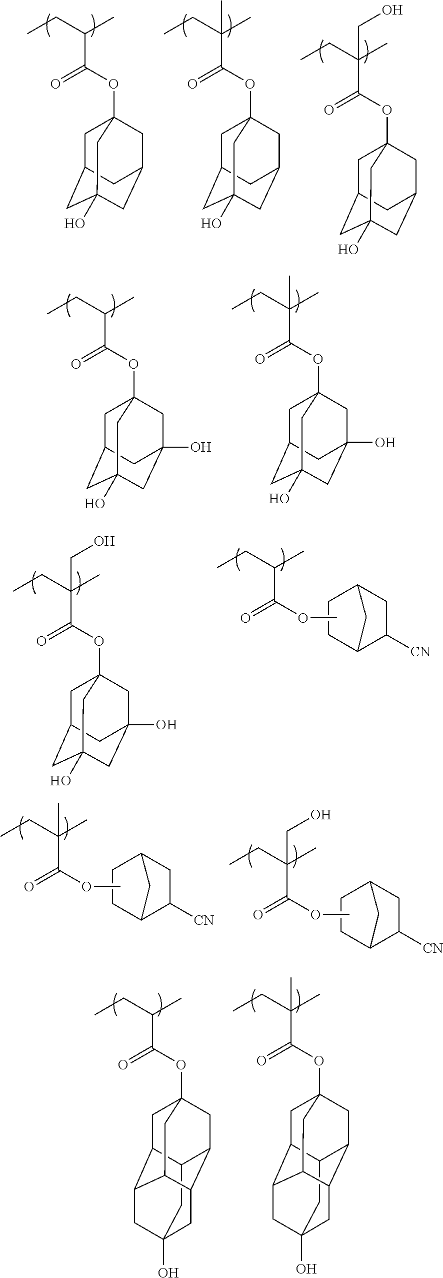

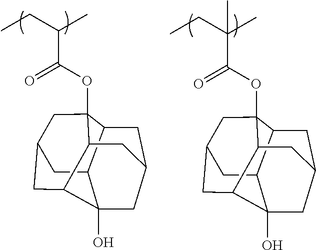

As the repeating unit having an alicyclic hydrocarbon structure in which no polar group is introduced, there can be mentioned, for example, any of the repeating units of general formula (VII) below.

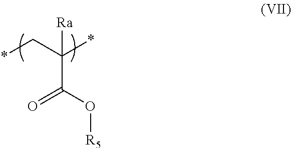

In general formula (VII), R₅ represents an alicyclic hydrocarbon, and Ra represents a hydrogen atom, an alkyl group, a hydroxymethyl group or a trifluoromethyl group.

Ra is preferably a hydrogen atom or an alkyl group, most preferably a hydrogen atom or a methyl group.

R₅ represents, for example, a cycloalkyl group having 3 to 12 carbon atoms, such as a cyclopentyl group, a cyclohexyl group, a cycloheptyl group or a cyclooctyl group; a cycloalkenyl group having 3 to 12-carbon atoms, such as a cyclohexenyl group; a ring-assembly hydrocarbon group, such as a bicyclohexyl group or a perhydronaphthalenyl group; or any of crosslinked-ring hydrocarbon rings, such as pinane, bornane, norpinane, norbornane and bicyclooctane rings (e.g., bicyclo[2.2.2]octane ring or bicyclo[3.2.1]octane ring), homobledane, adamantane, tricyclo[5.2.1.0^{2,6}]decane and tricyclo[4.3.1.1^{2,5}]undecane rings, tetracyclo[4.4.0.1^{2,5}.1^{7,10}]dodecane and perhydro-1,4-methano-5,8-methanonaphthalene rings, and perhydronaphthalene (decalin), perhydroanthracene, perhydrophenanthrene, perhydroacenaphthene, perhydrofluorene, perhydroindene and perhydrophenalene rings. R₅ is preferably a cyclopentyl group, a cyclohexyl group, a norbornyl group, an adamantyl group, a bicyclooctanyl group, a tricyclo[5,2,1,0^{2,6}]decanyl group or the like. As preferred crosslinked-ring hydrocarbon rings, there can be mentioned a norbornyl group and an adamantyl group.

Substituents may be introduced in these alicyclic hydrocarbon groups. As preferred substituents, there can be mentioned a halogen atom, an alkyl group, a hydroxyl group protected by a protective group, an amino group protected by a protective group and the like.

Particular examples of the repeating units each having an alicyclic hydrocarbon structure in which no polar group is introduced are shown below, which in no way limit the scope of the present invention. In the formulae, Ra represents H, CH₃, CH₂OH or CF₃.

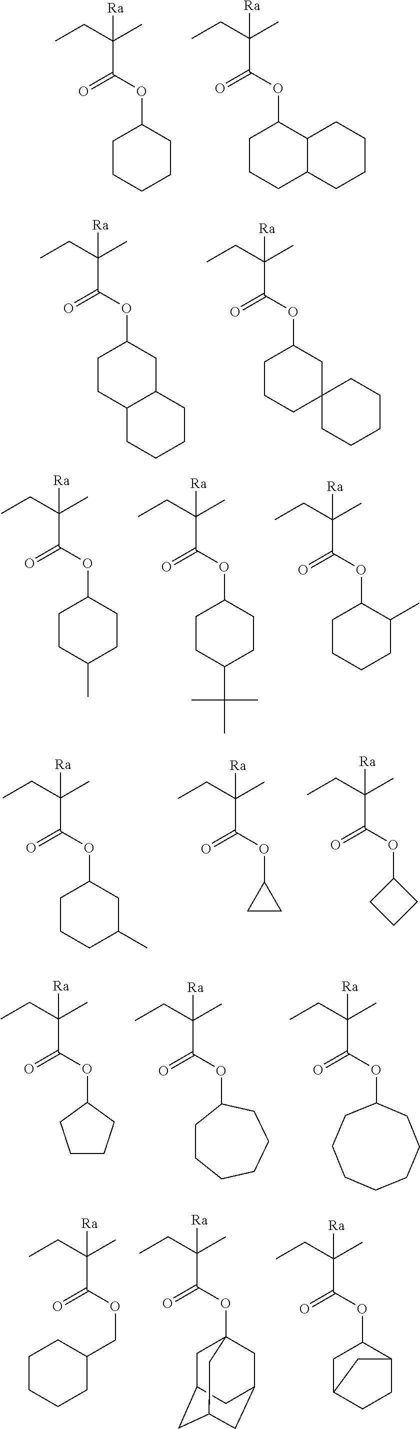

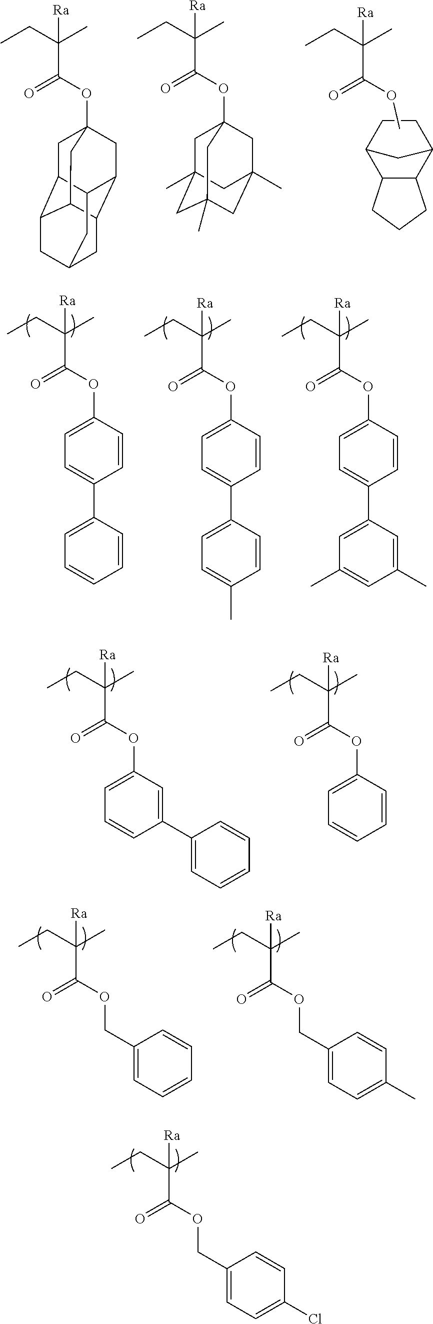

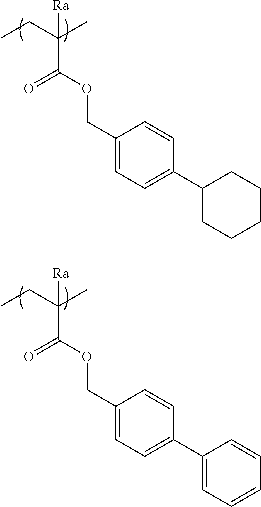

The content of repeating unit having an alicyclic hydrocarbon structure in which no polar group is introduced, based on all the repeating units of the resin (P), is preferably in the range of 1 to 40 mol %, more preferably 1 to 20 mol %.

The resin (P) according to the present invention can contain, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned, for example, a compound having an unsaturated bond capable of addition polymerization, selected from among acrylic esters, methacrylic esters, acrylamides, methacrylamides, allyl compounds, vinyl ethers, vinyl esters, styrenes, crotonic esters and the like.

The use of such repeating structural units would allow fine regulation of the required properties of the resin for use in the composition of the present invention, especially:

(1) solubility in application solvents,

(2) film forming easiness (glass transition point),

(3) alkali developability,

(4) film thinning (selections of hydrophilicity/hydrophobicity and alkali-soluble group),

(5) adhesion of unexposed area to substrate,

(6) dry etching resistance, etc.

In the resin (P) for use in the composition of the present invention, the molar ratios of individual repeating structural units contained are appropriately determined from the viewpoint of regulation of not only the dry etching resistance of the resist but also the standard developer adaptability, substrate adhesion, resist profile and generally required properties of the resist such as the resolving power, heat resistance and sensitivity.

The resin (P) according to the present invention may have any of the random, block, comb and star configurations.

The resin (P) can be synthesized by, for example, the radical, cation or anion polymerization of unsaturated monomers corresponding to given structures.

Further, the intended resin can be obtained by first polymerizing unsaturated monomers corresponding to the precursors of given structures and thereafter carrying out a polymer reaction.

The weight average molecular weight of the resin (P) is not particularly limited. Preferably, the weight average molecular weight thereof is in the range of 1000 to 100,000. It is more preferably in the range of 1500 to 20,000, most preferably 2000 to 10,000. Herein, the weight average molecular weight of the resin refers to the polystyrene-equivalent molecular weight measured by GPC (carrier: THF or N-methyl-2-pyrrolidone(NMP)).

The molecular weight dispersity (Mw/Mn) of the resin is preferably in the range of 1.00 to 5.00, more preferably 1.03 to 3.50 and further more preferably 1.05 to 2.50.

One type of rein (P) may be used alone, or two or more types thereof may be used in combination. The content of resin (P) is preferably in the range of 30 to 100 mass %, more preferably 50 to 100 mass % and most preferably 70 to 9100 mass %, based on the total solids of the actinic-ray- or radiation-sensitive resin composition of the present invention.

As particular examples of the resins (P), there can be mentioned, for example, resins each comprising at least one repeating unit, selected from among resins each comprising at least one repeating unit selected from among the particular examples of repeating units of general formulae (2) to (4) above, at least one repeating unit selected from among the particular examples of repeating units of general formulae (5), (6) and (BZ) above and at least one repeating unit selected from among the particular examples of repeating units of general formula (7) above.

In the resins (P), the content of repeating unit with a principal chain in which a cyclic structure is introduced is preferably 30 mol % or less, more preferably nil.

Preferred particular examples of the resins (P) are shown below, which in no way limit the scope of the present invention.

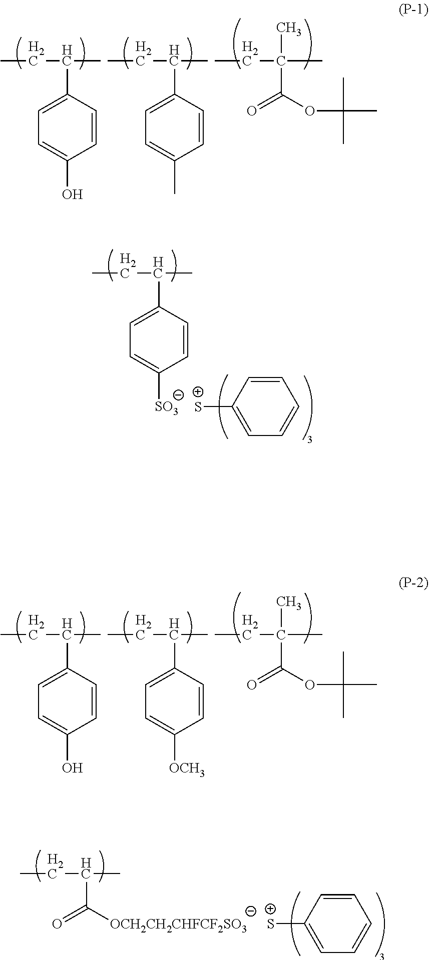

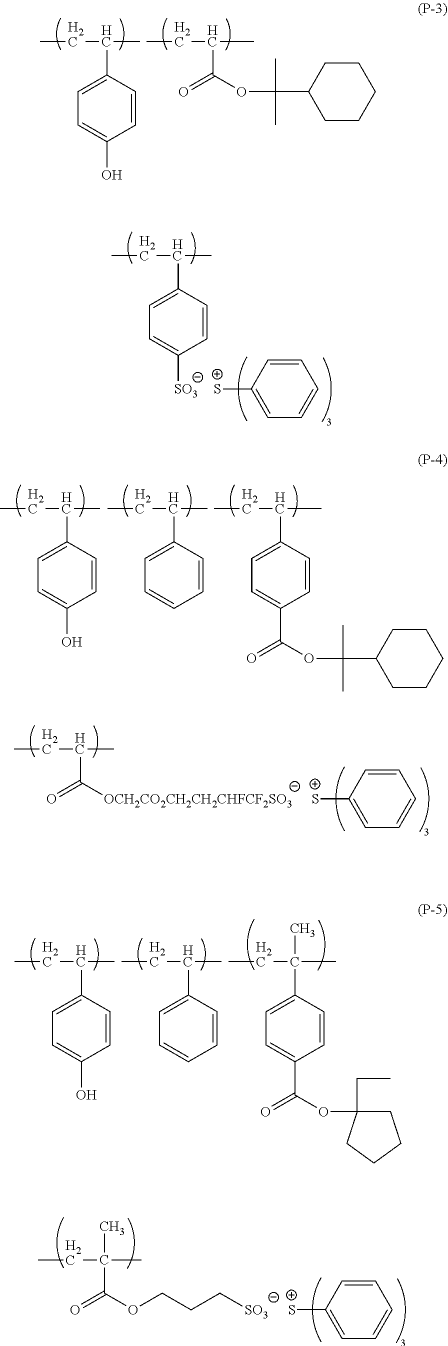

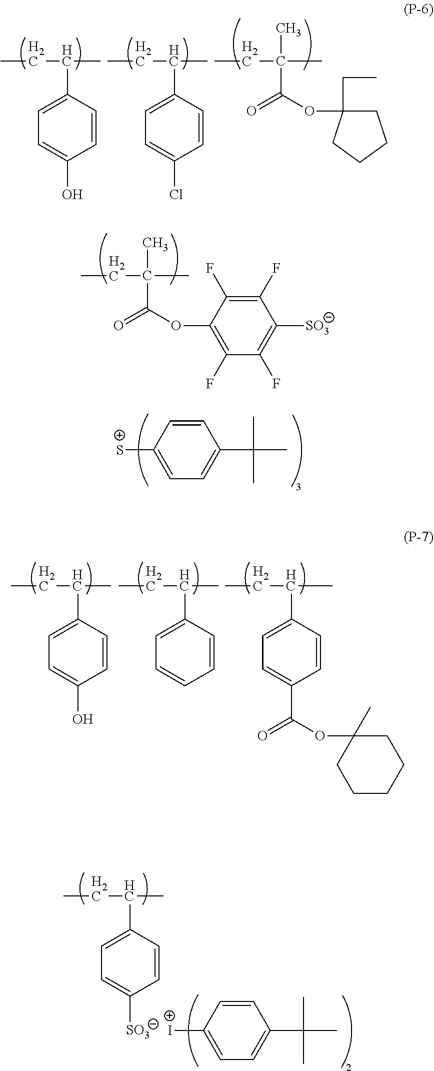

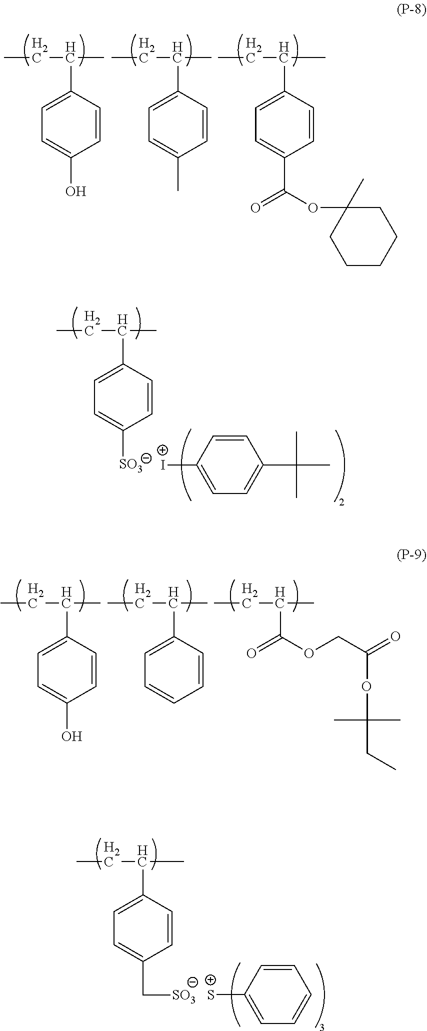

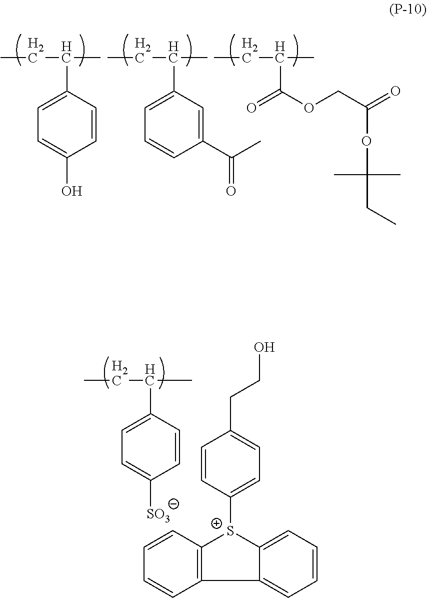

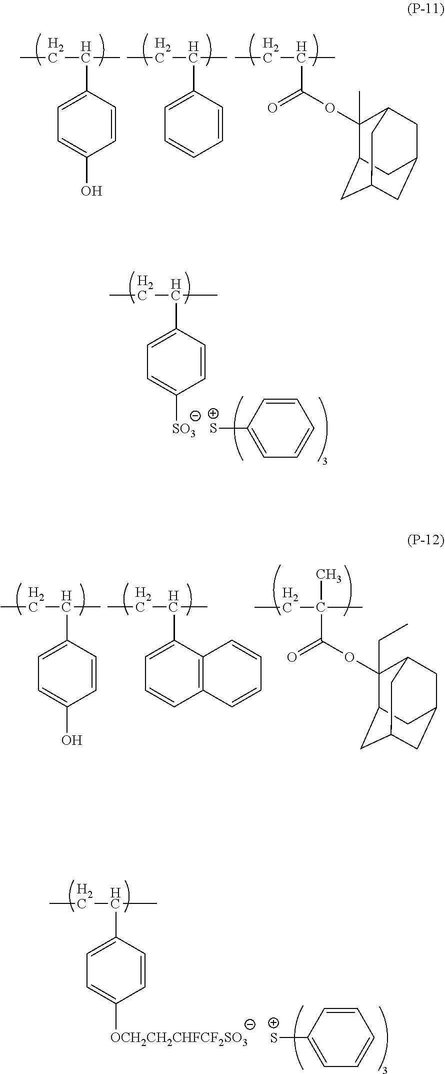

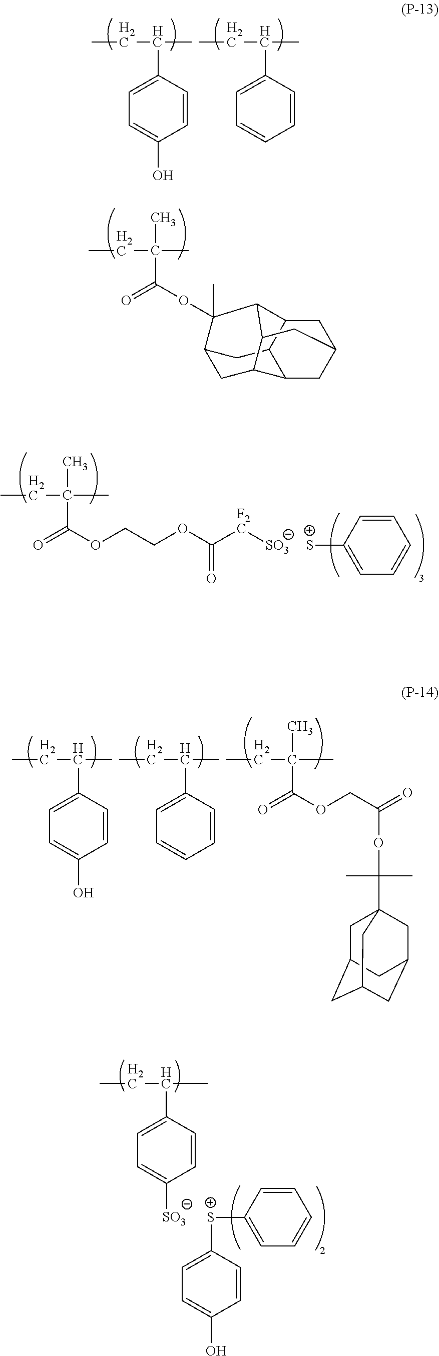

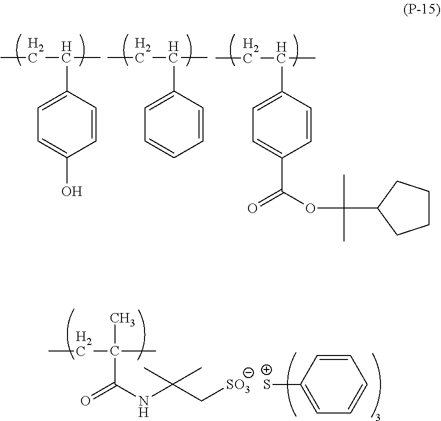

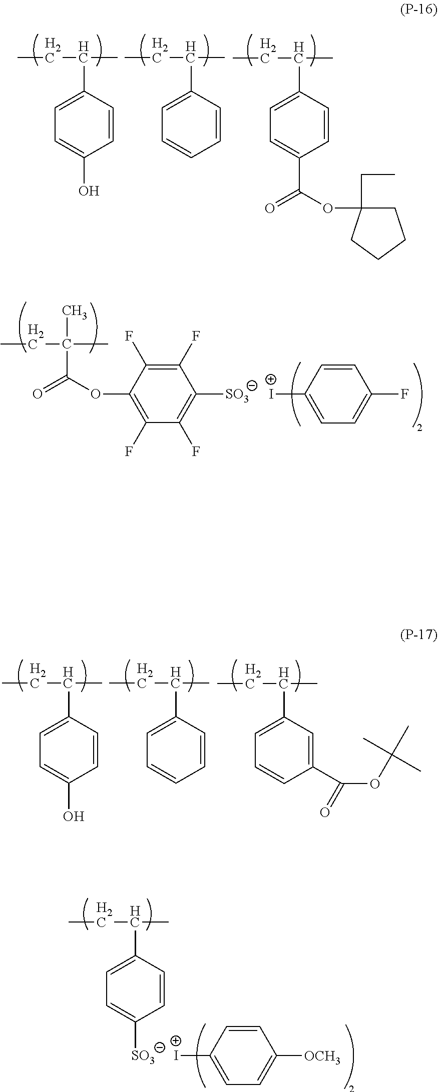

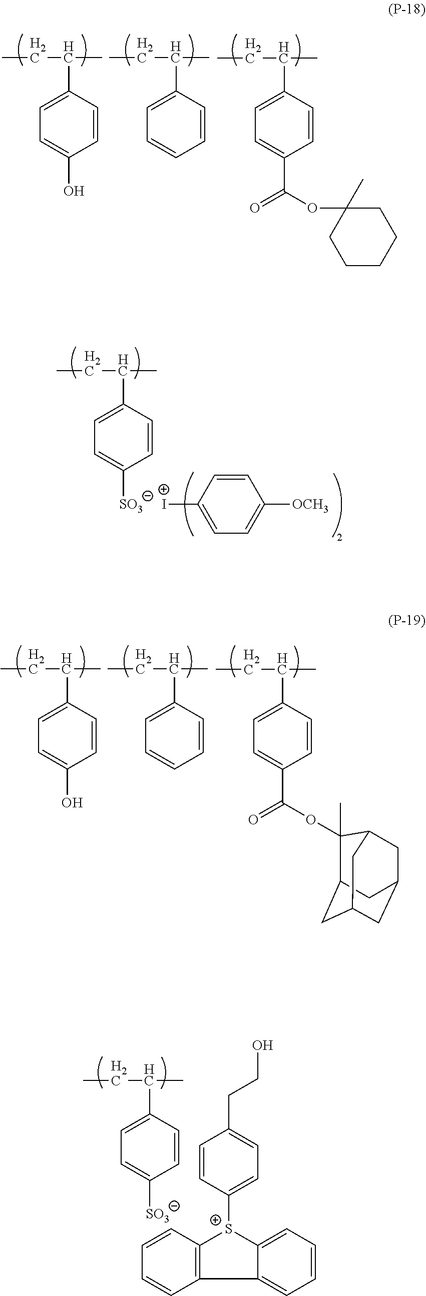

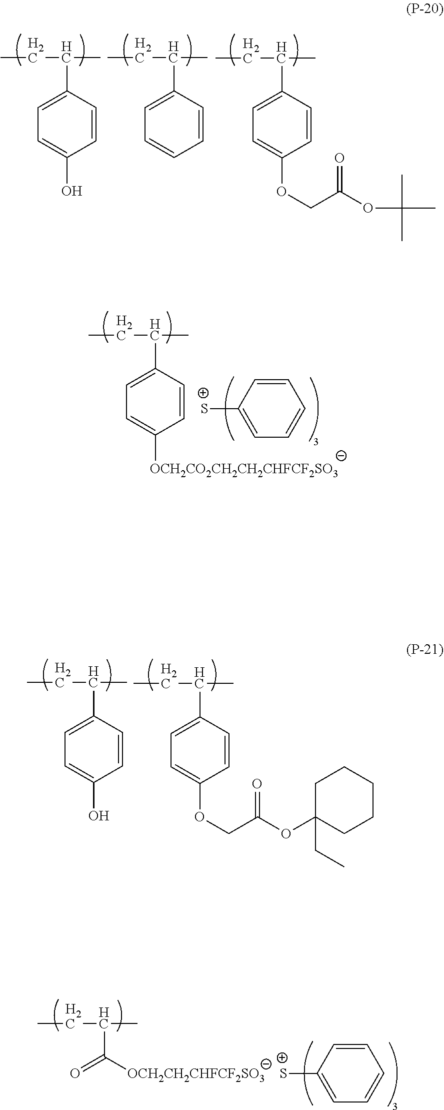

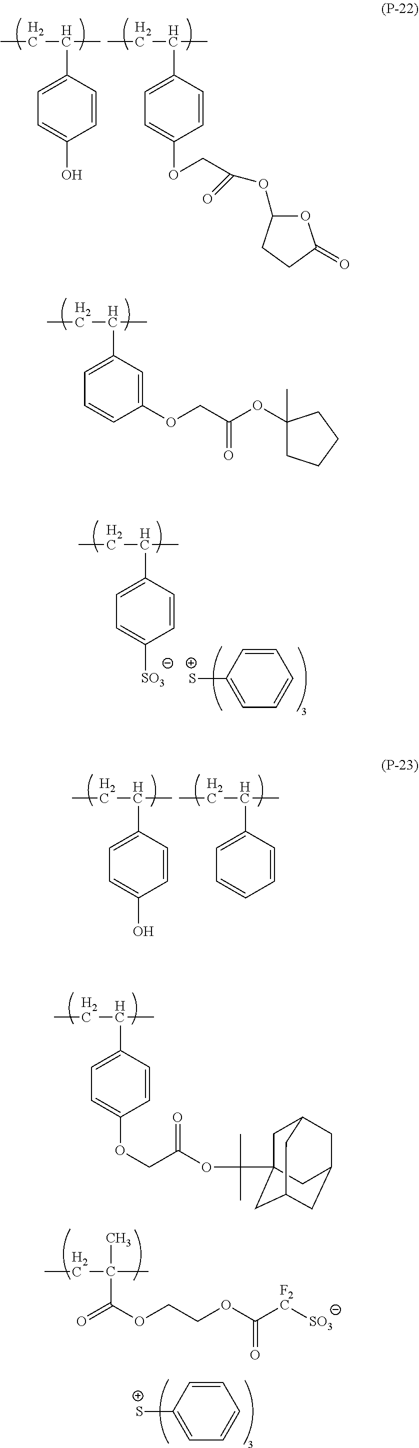

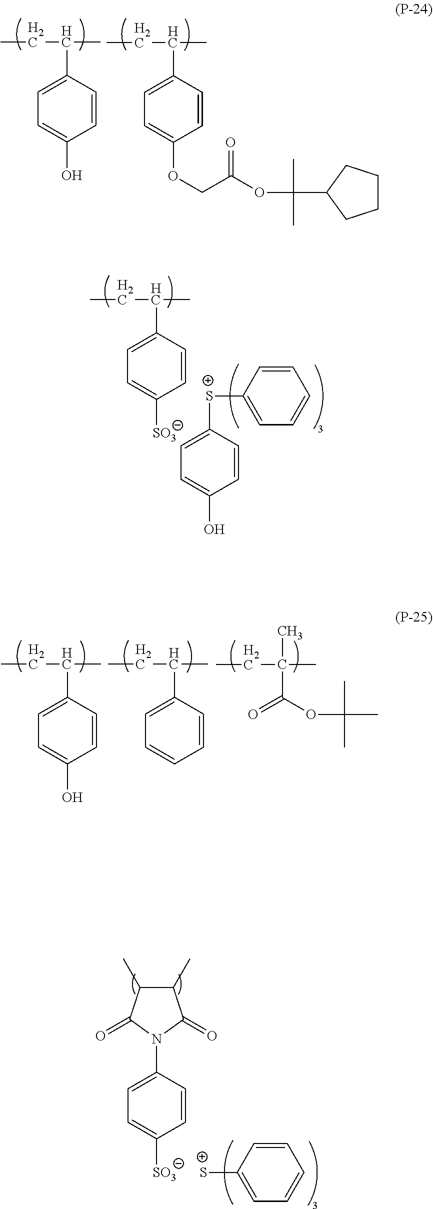

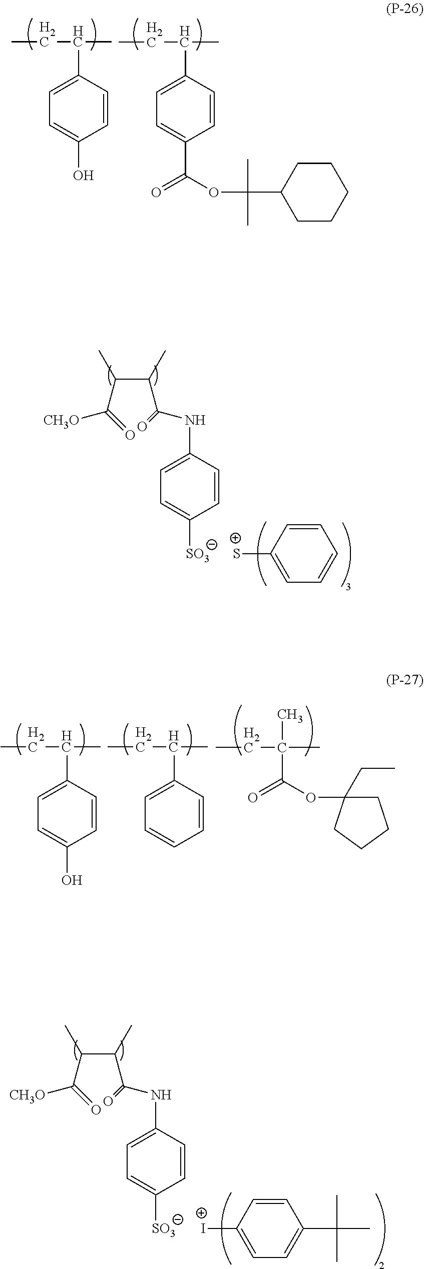

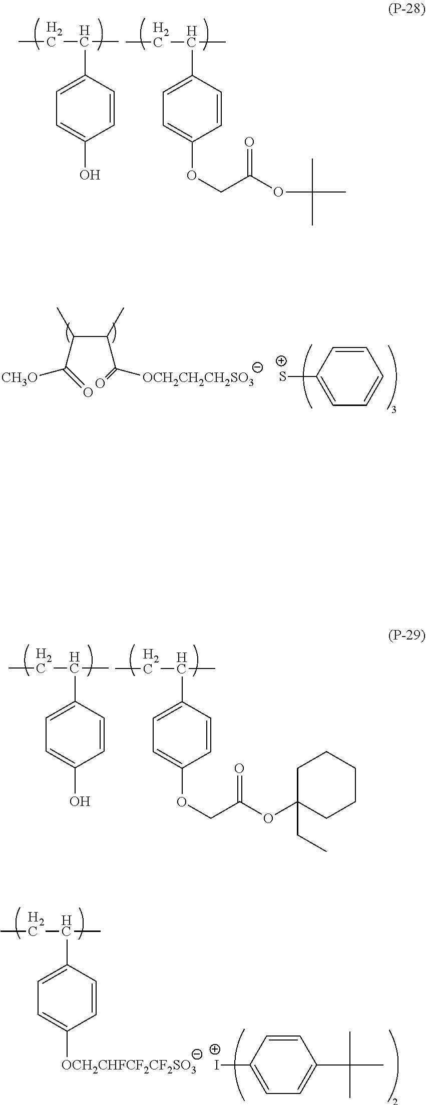

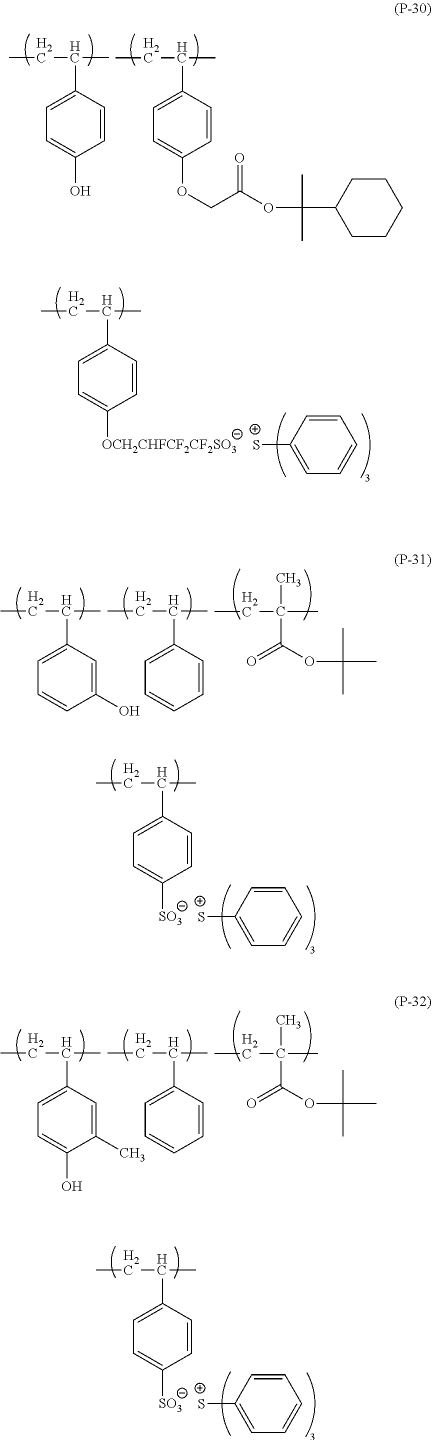

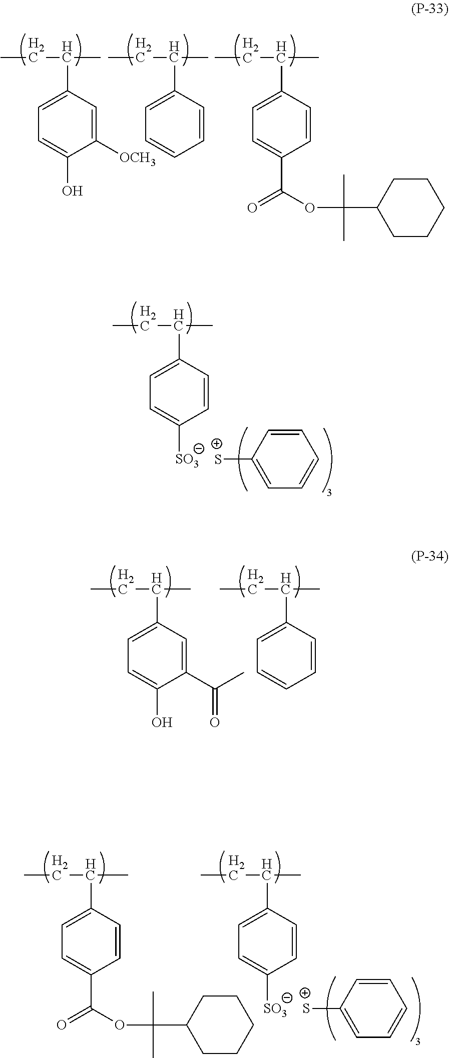

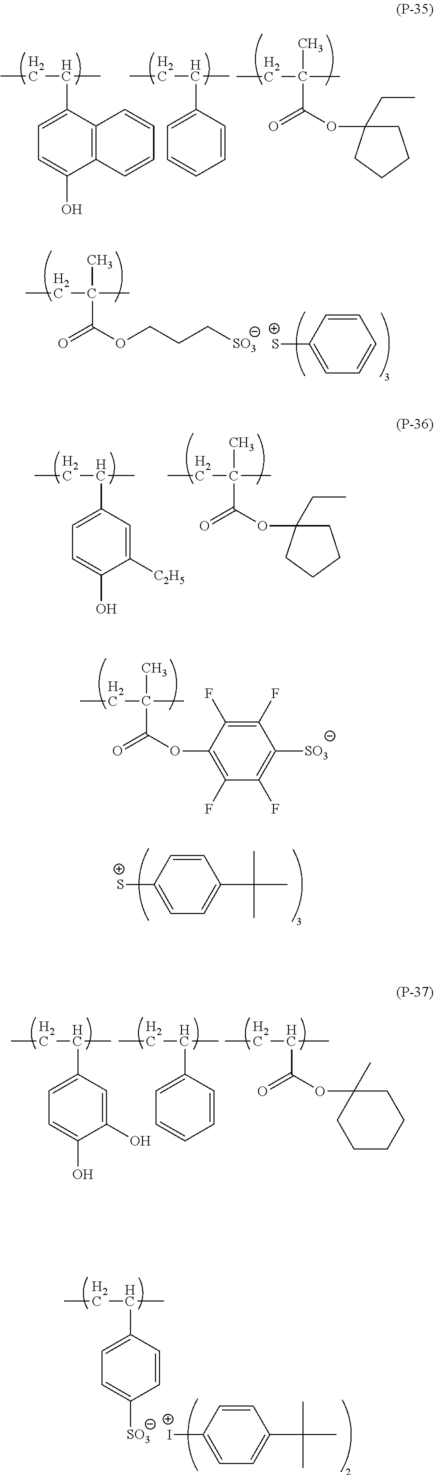

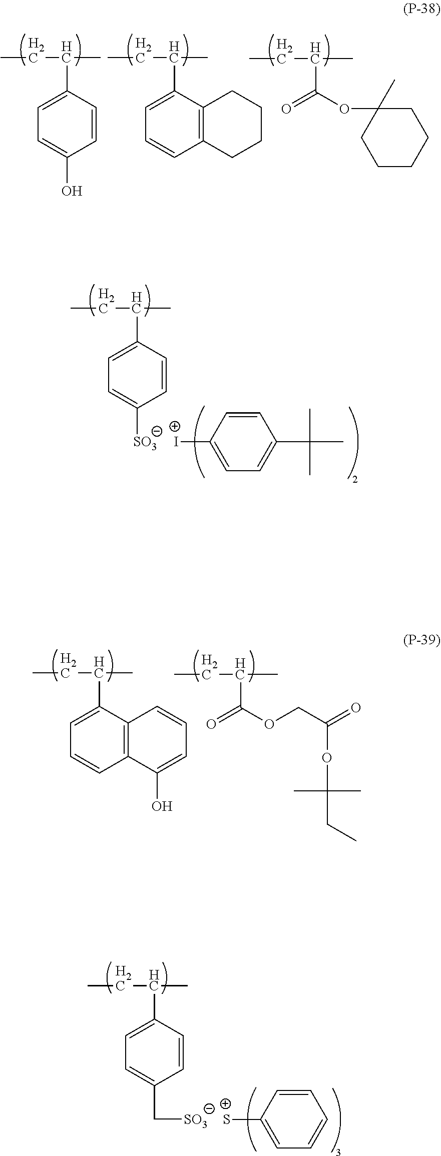

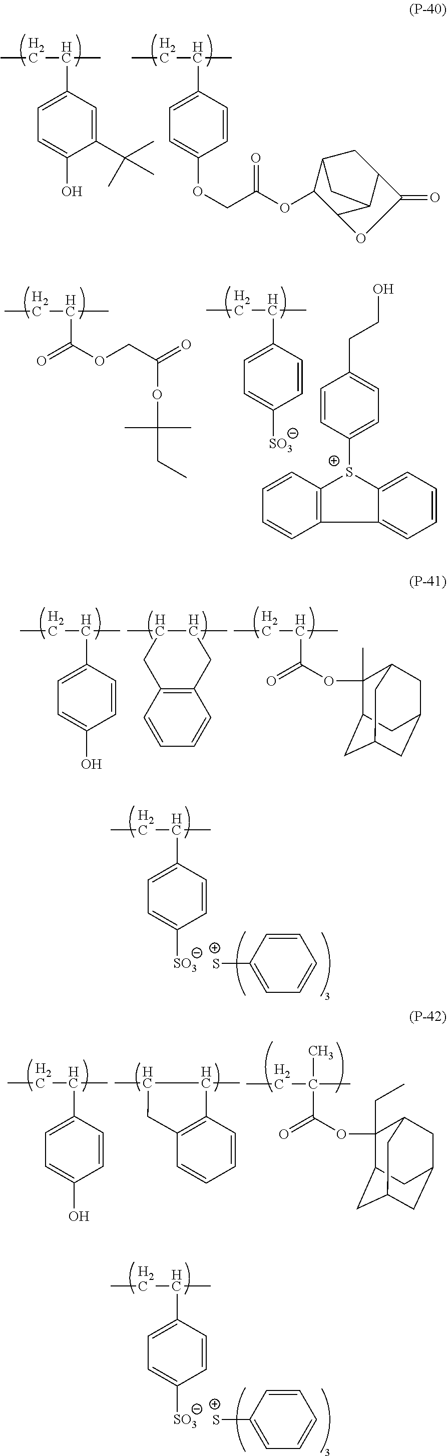

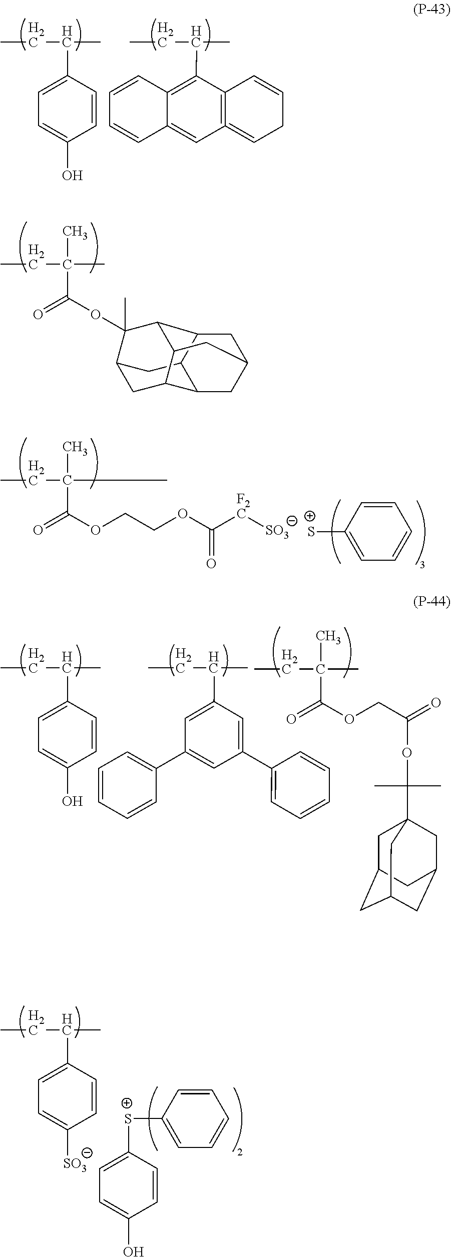

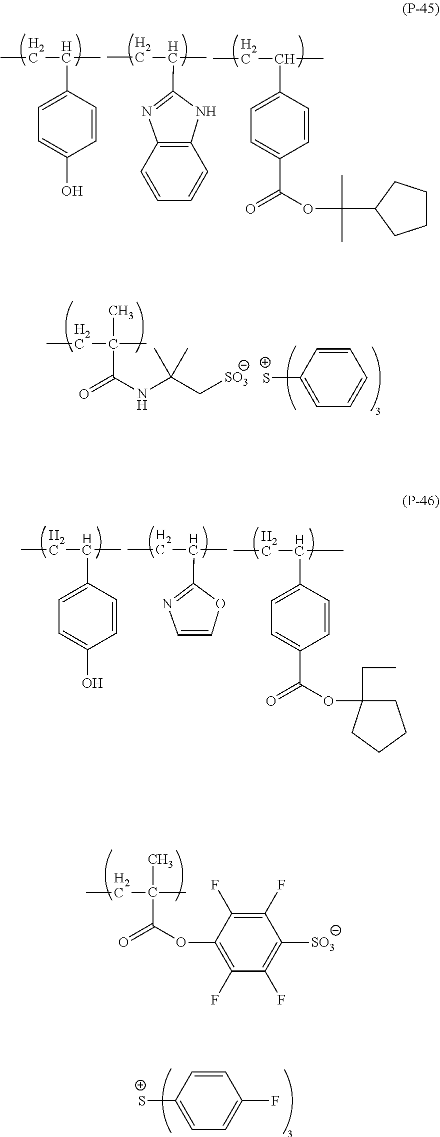

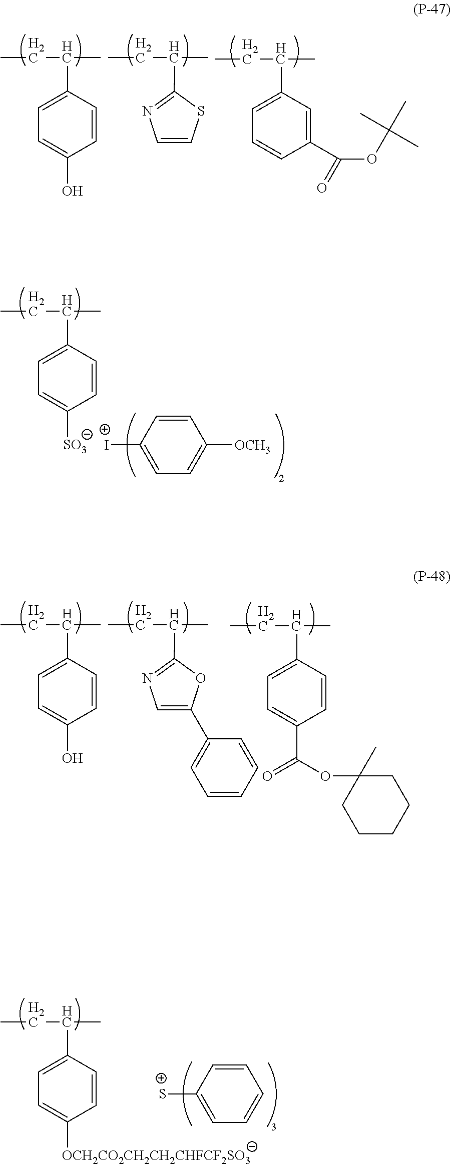

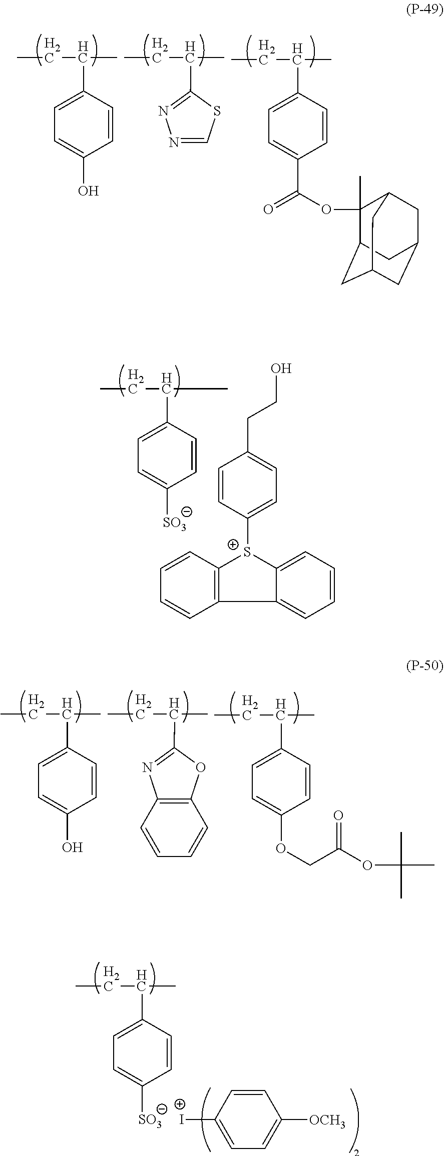

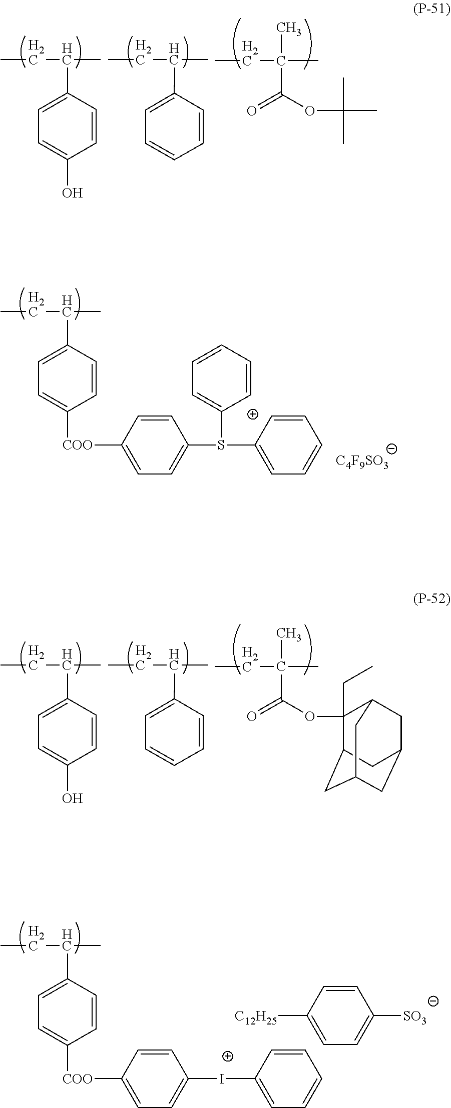

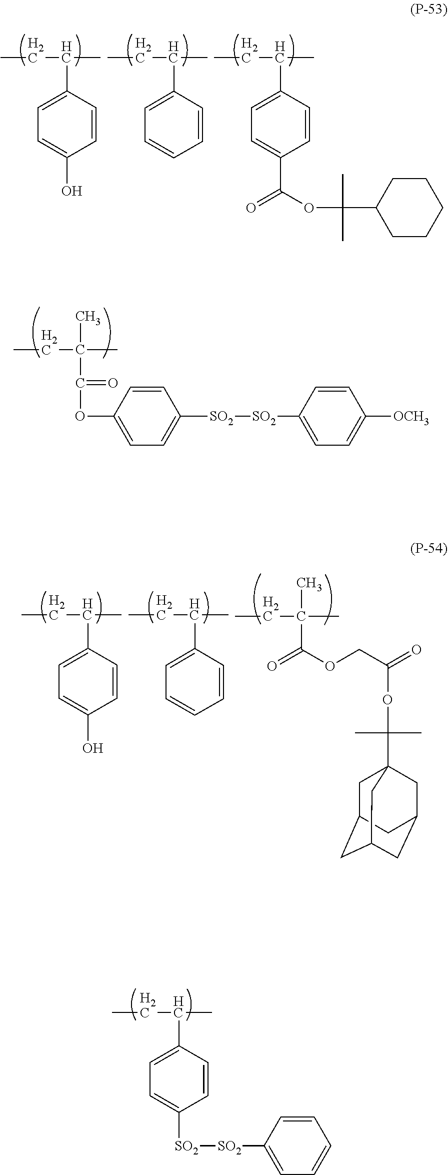

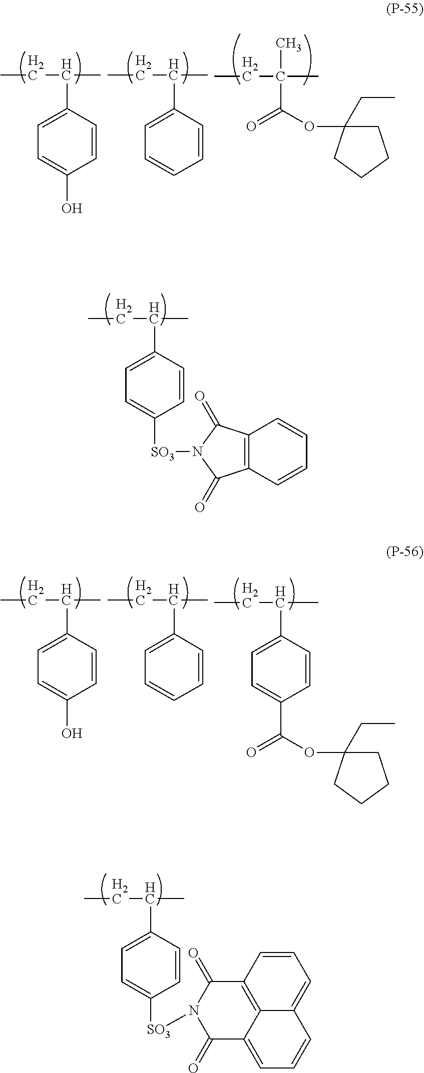

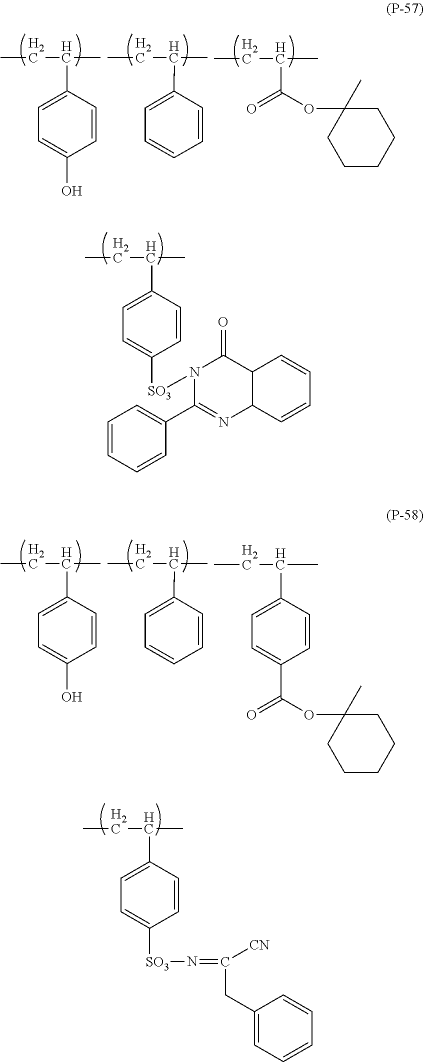

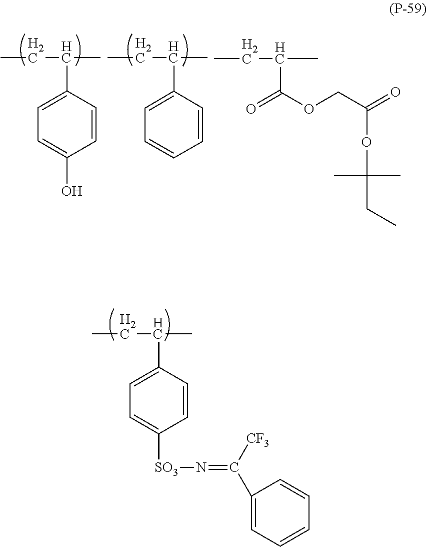

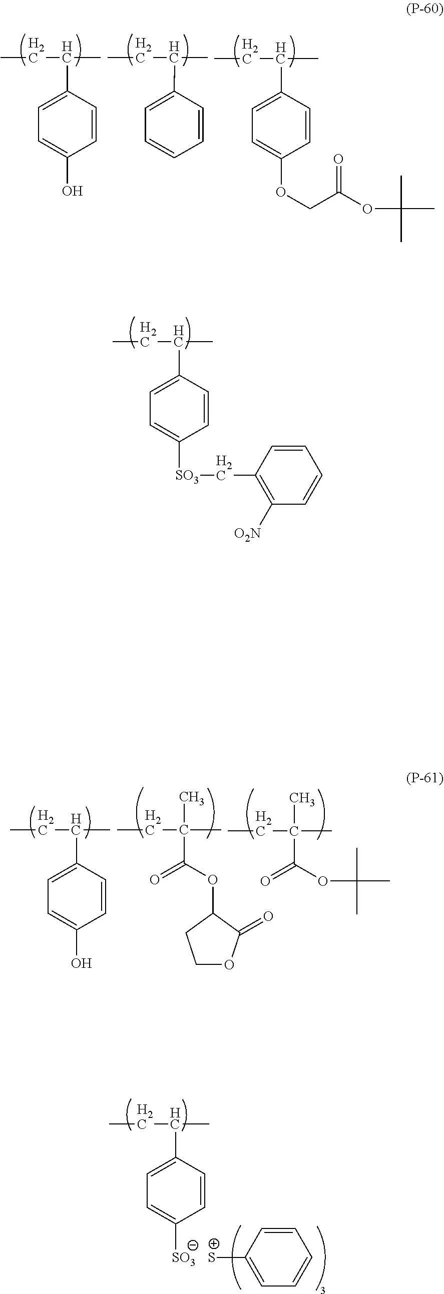

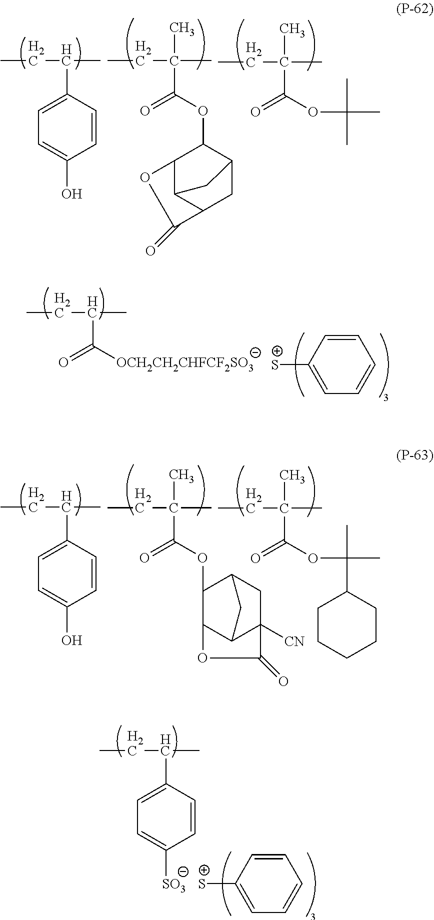

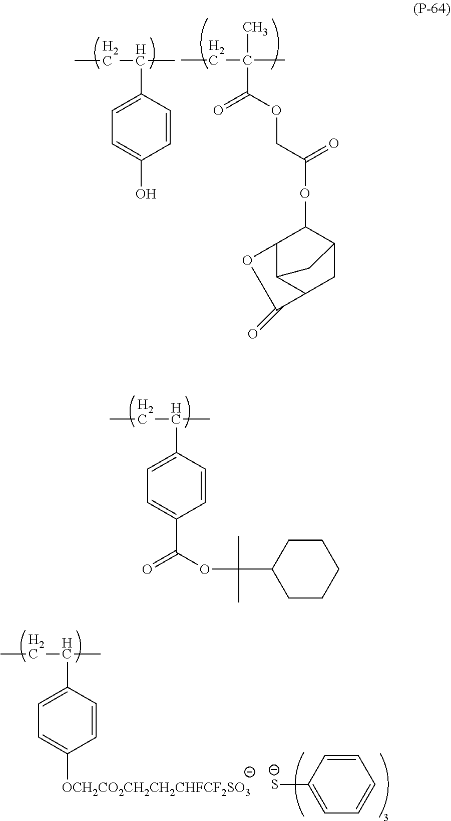

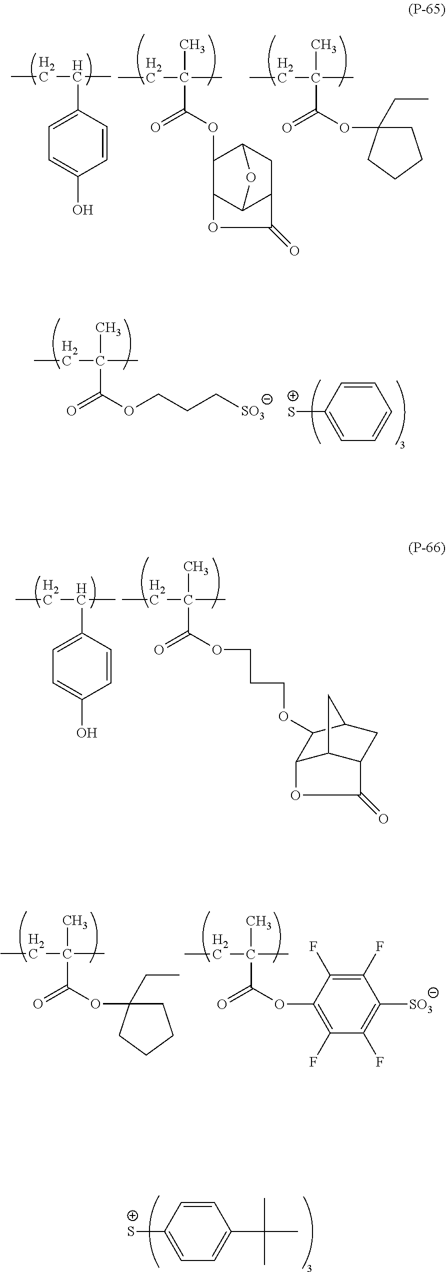

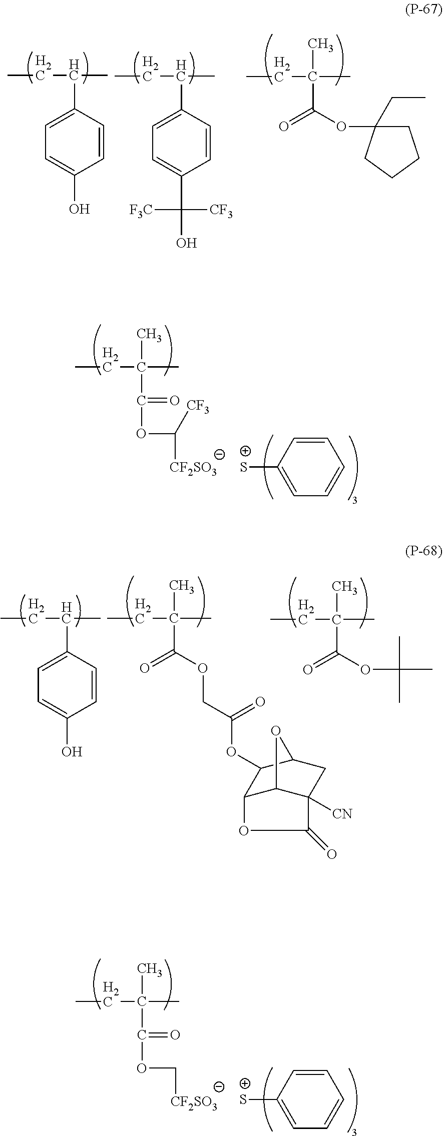

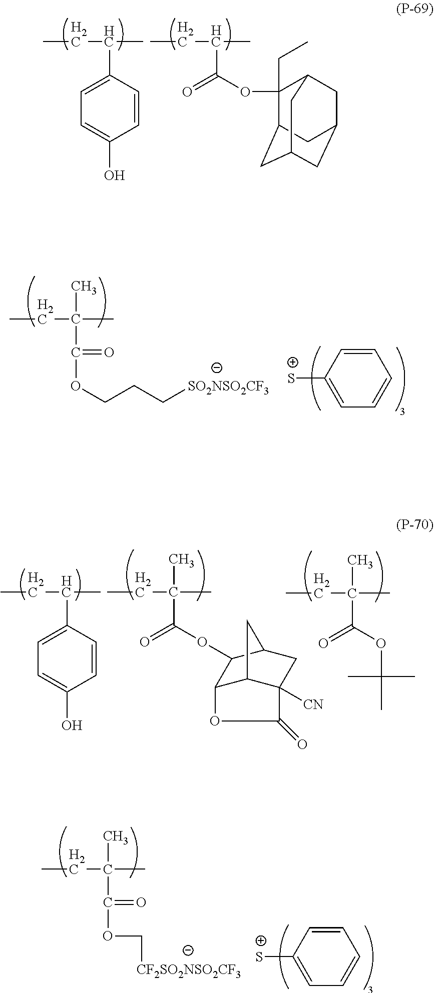

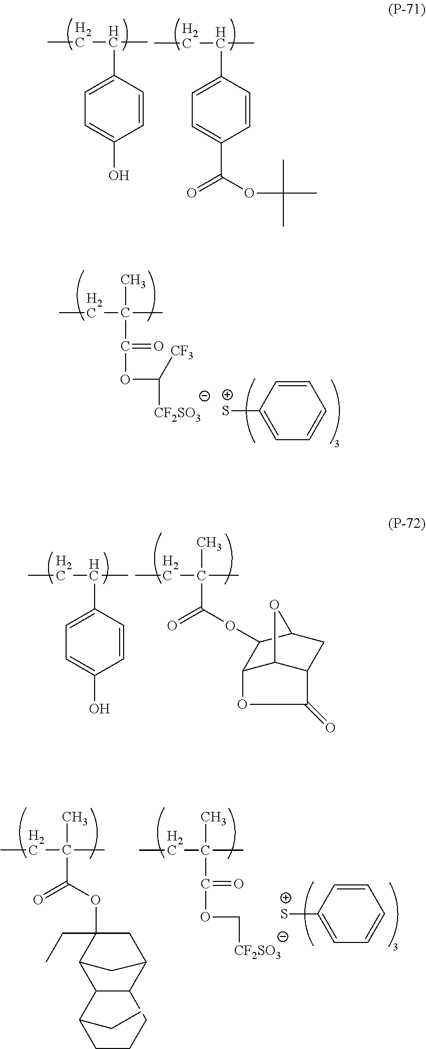

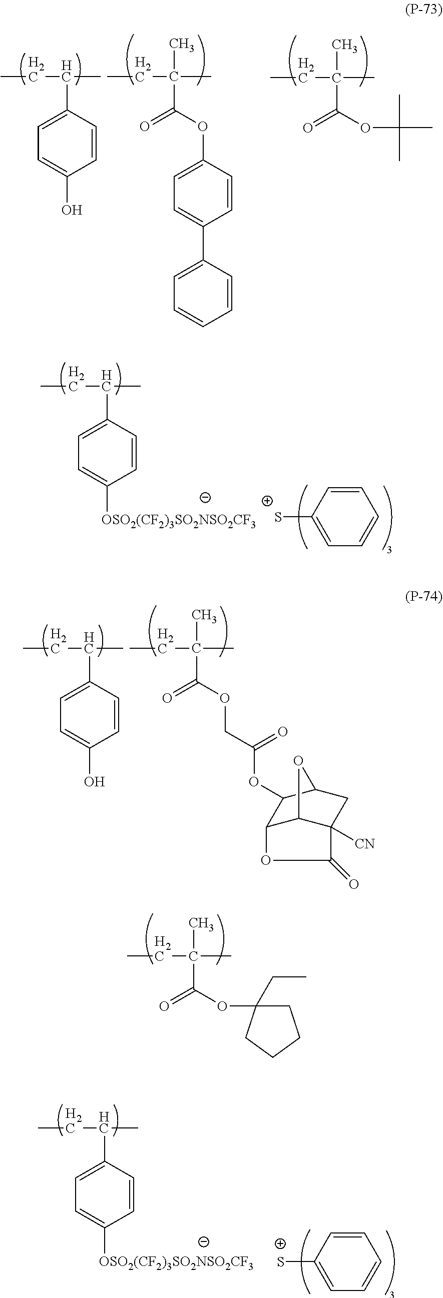

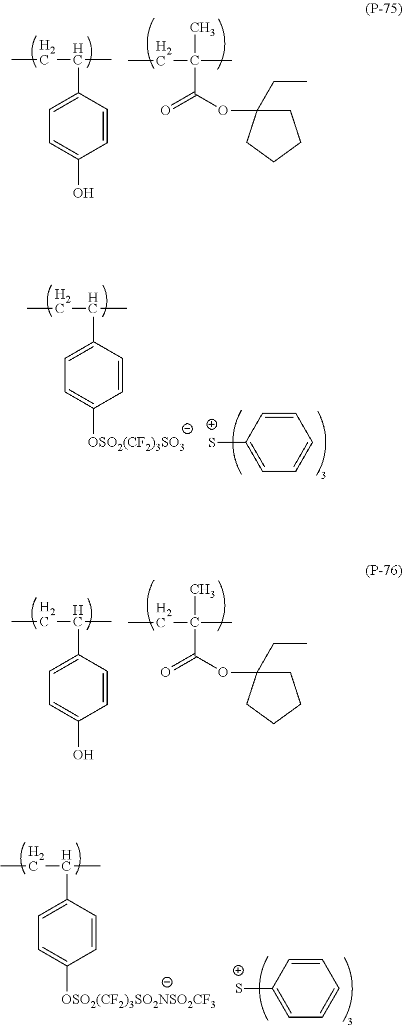

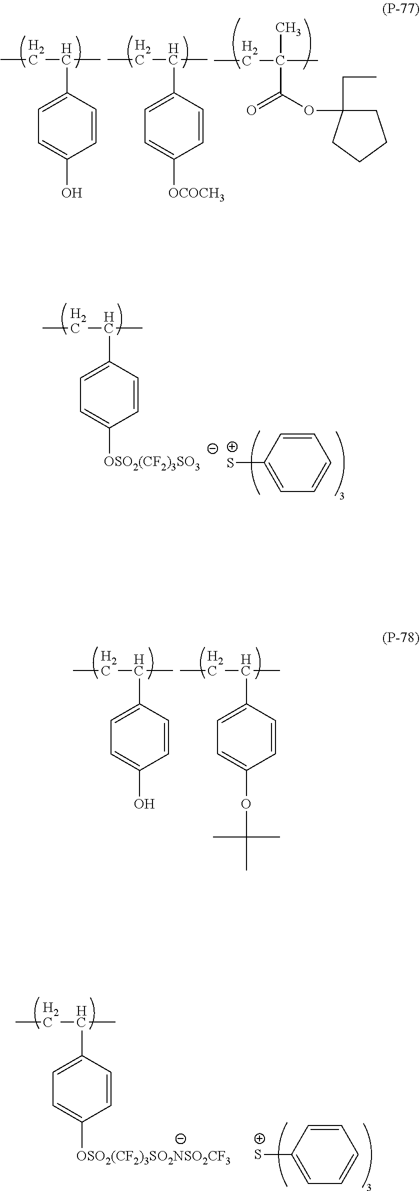

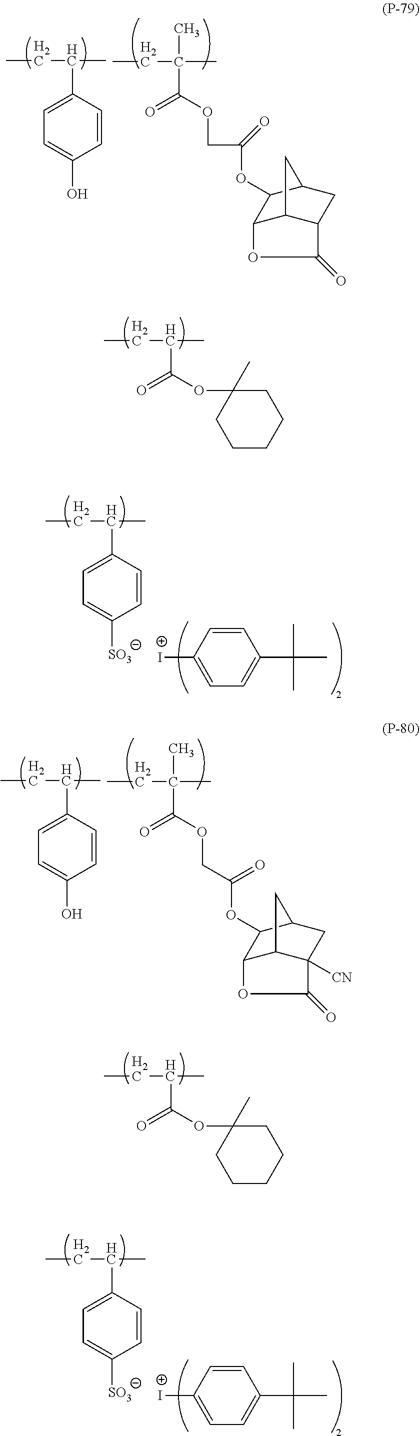

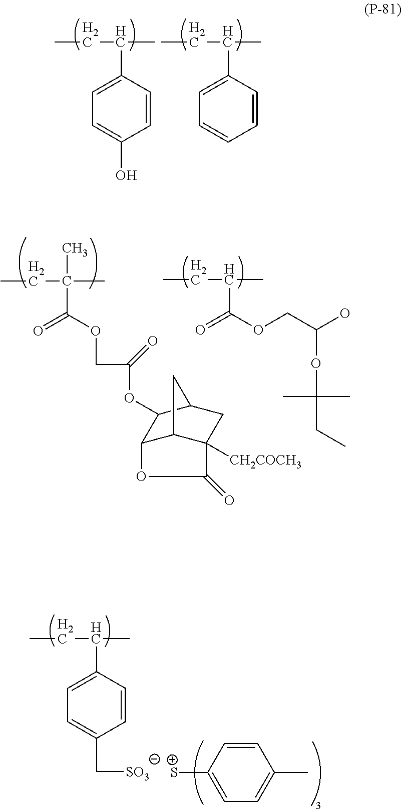

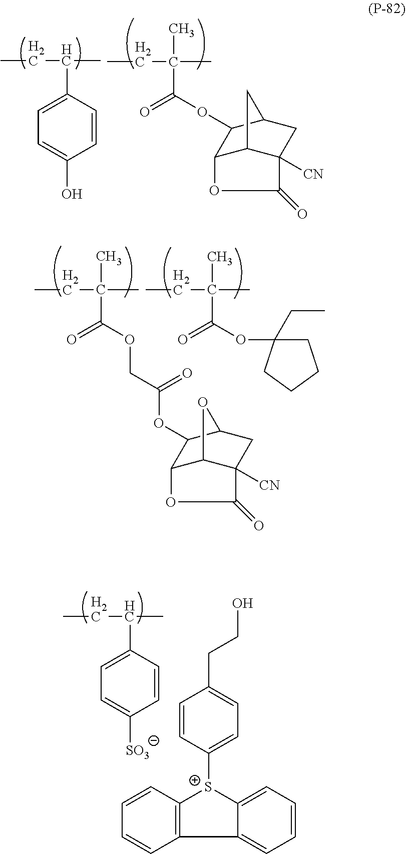

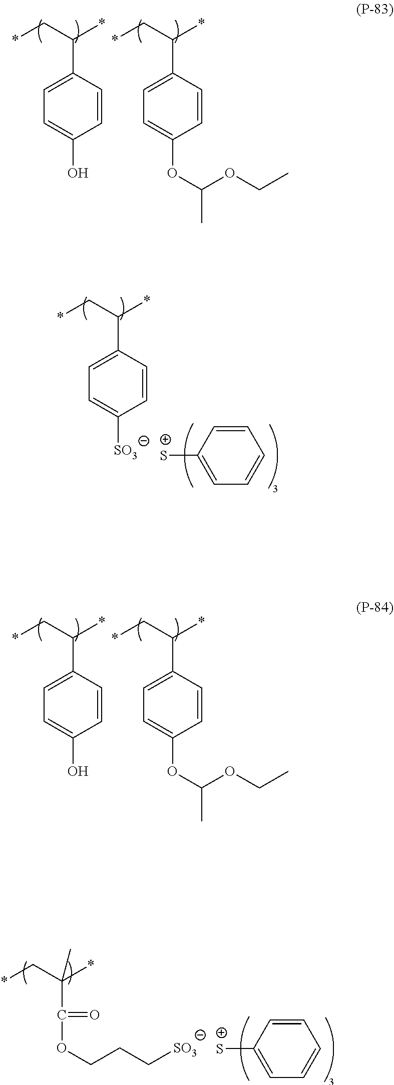

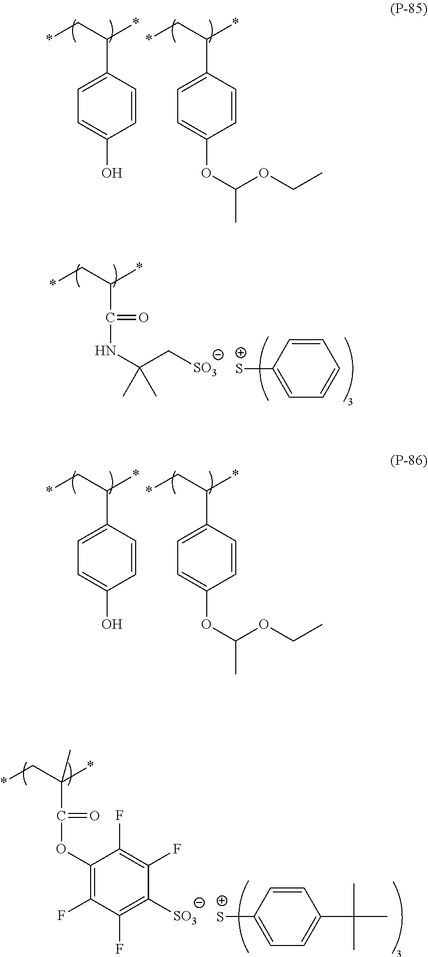

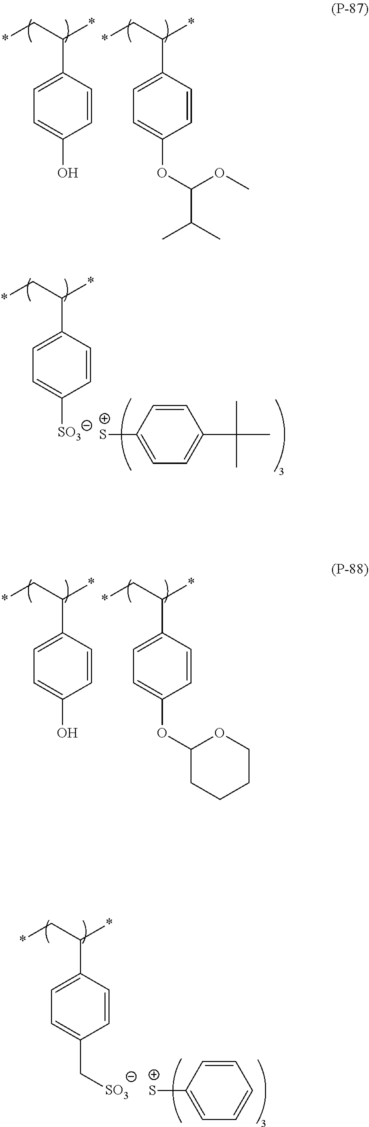

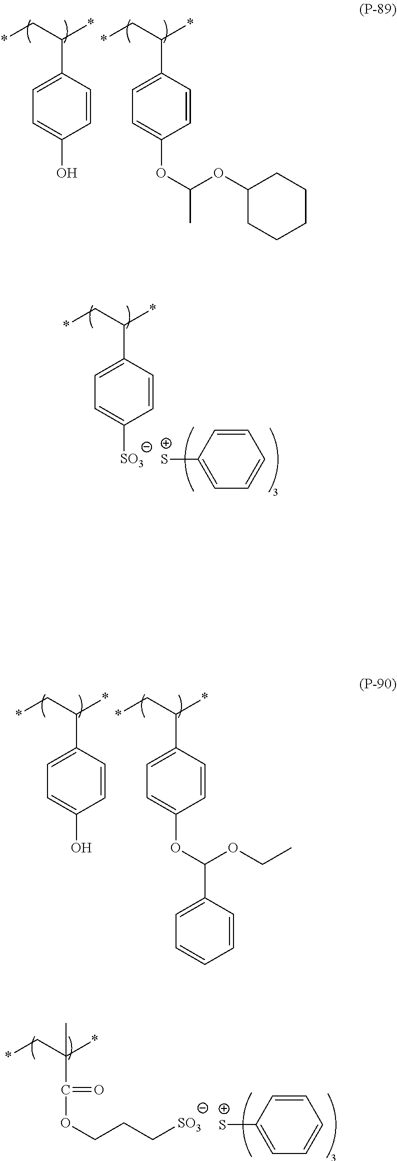

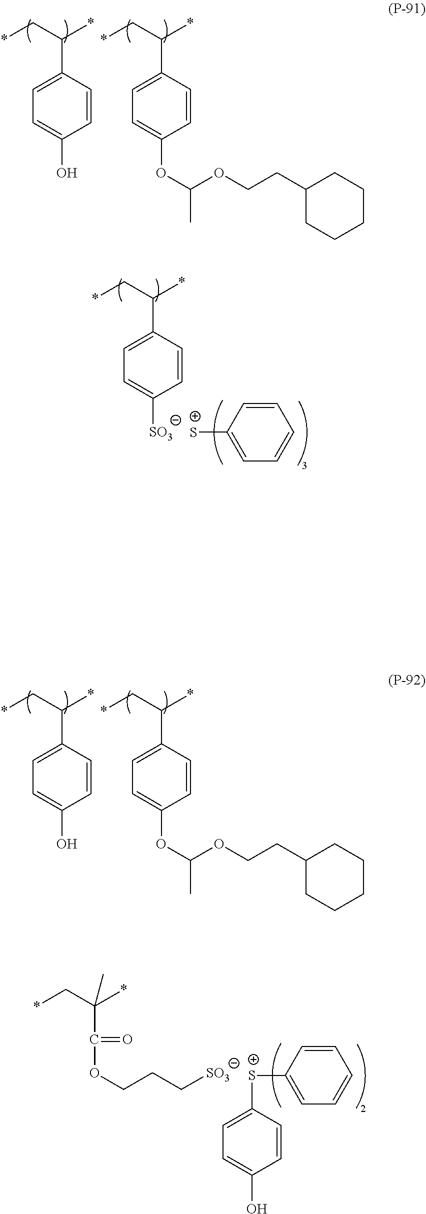

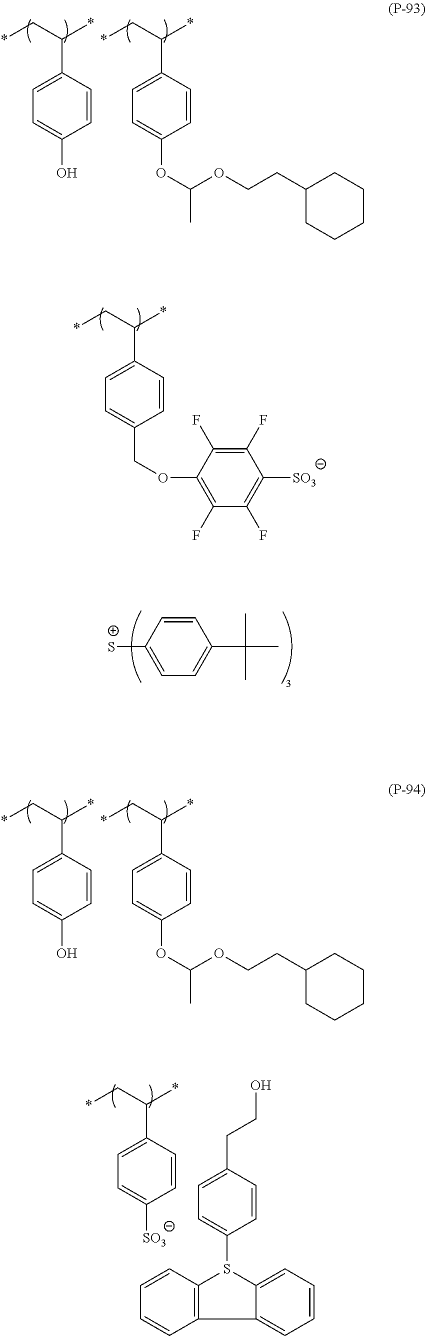

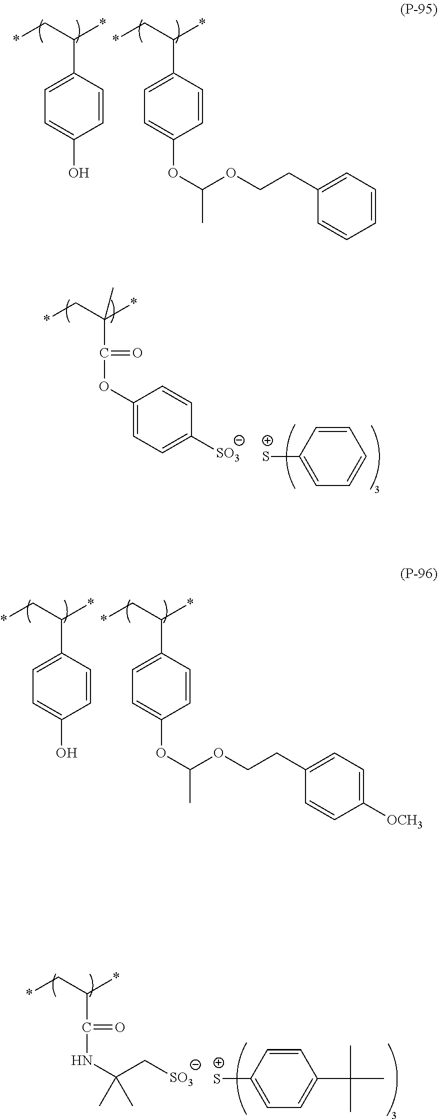

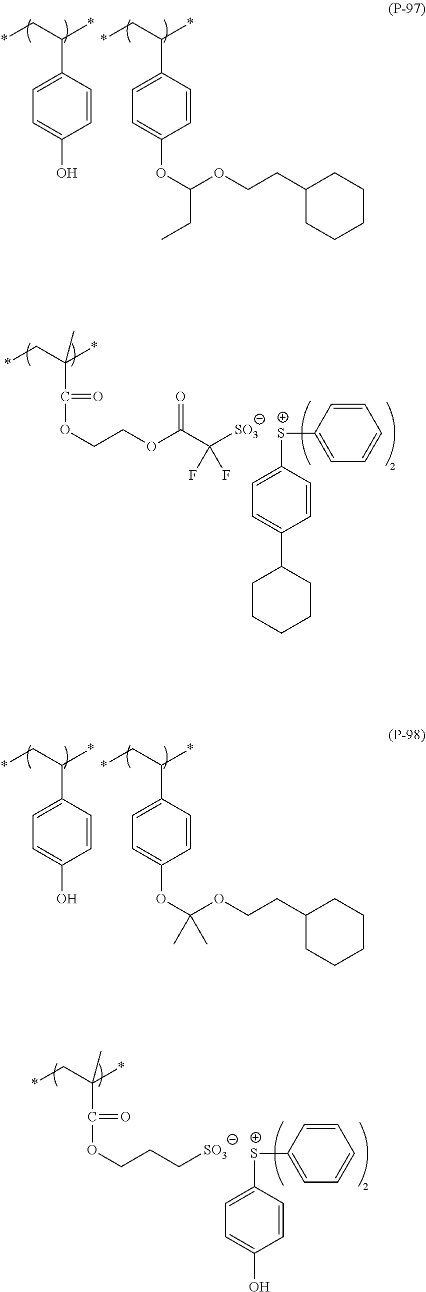

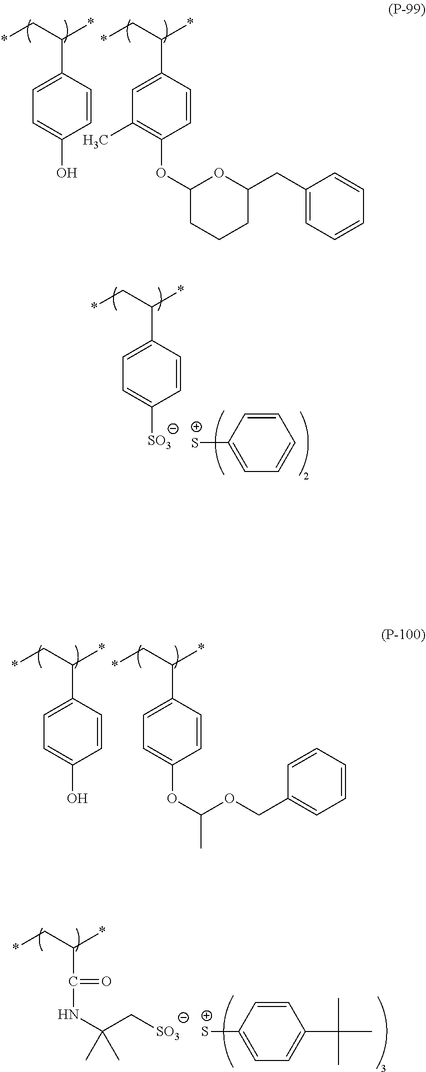

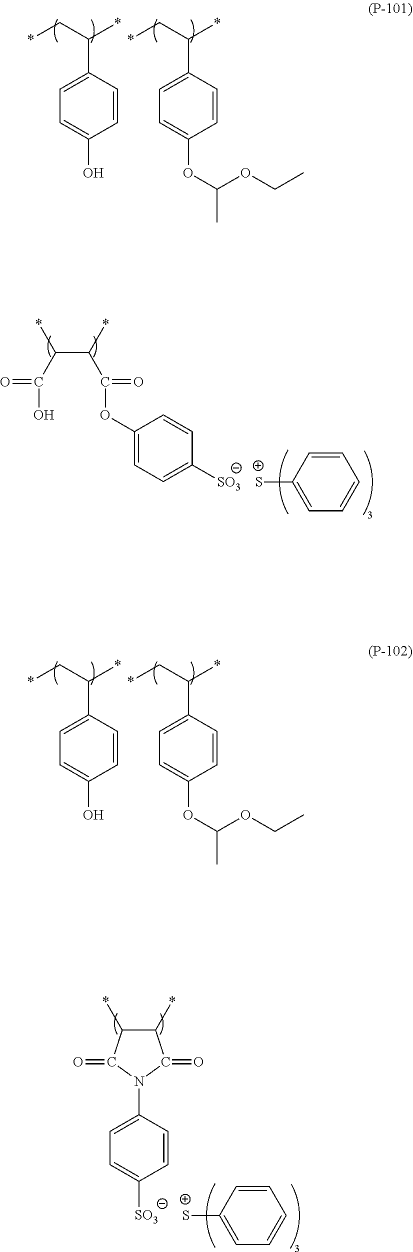

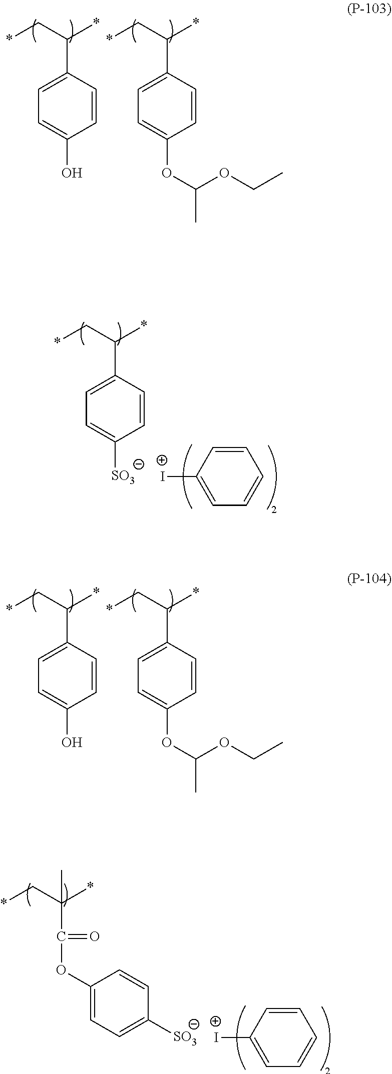

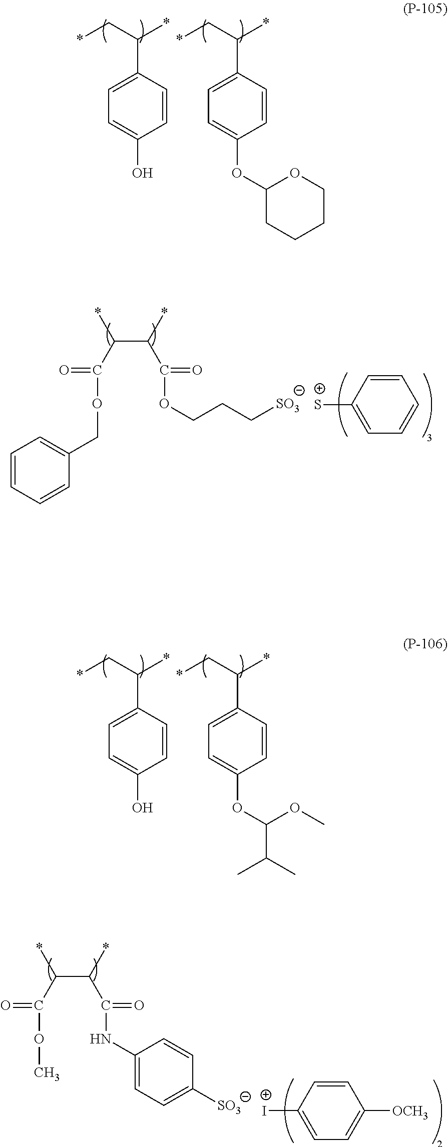

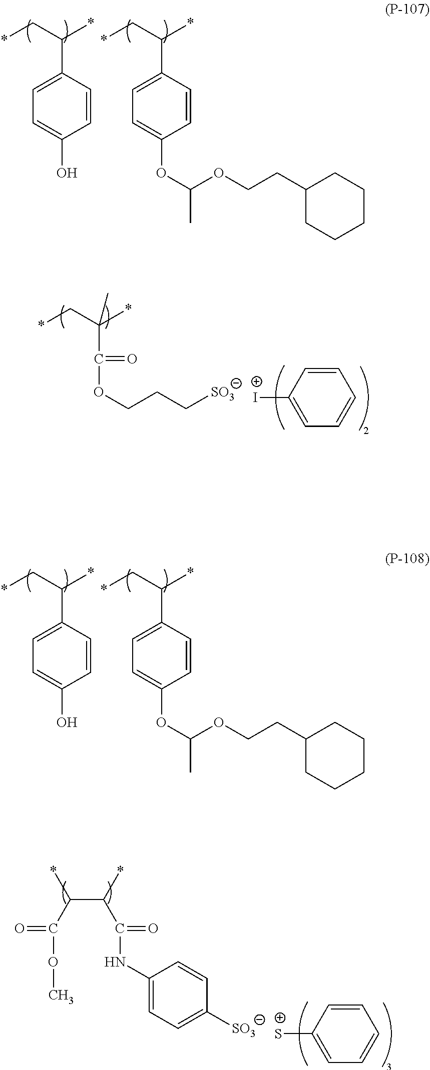

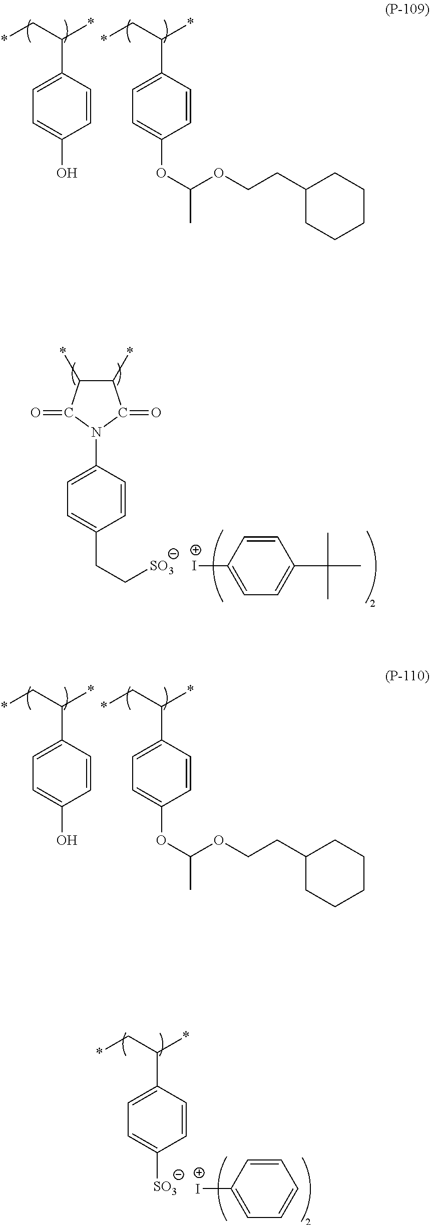

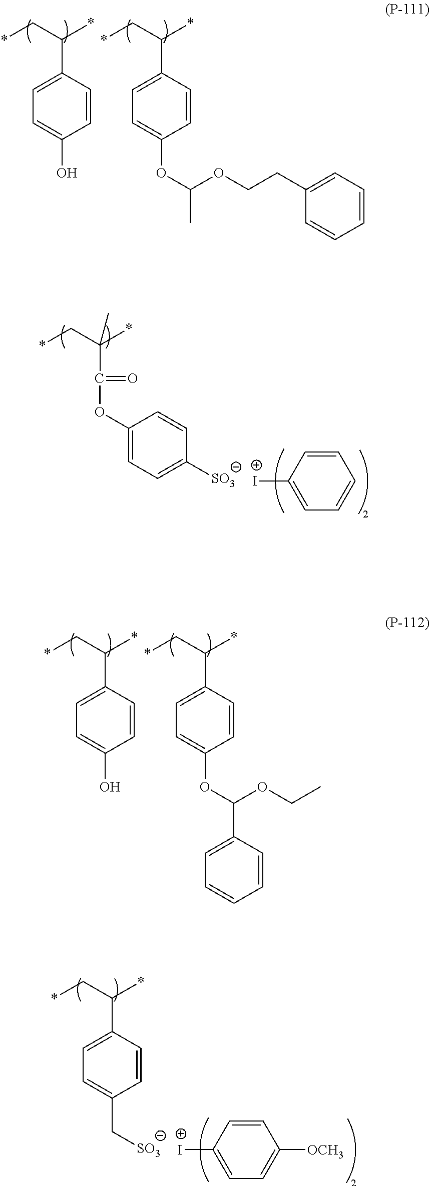

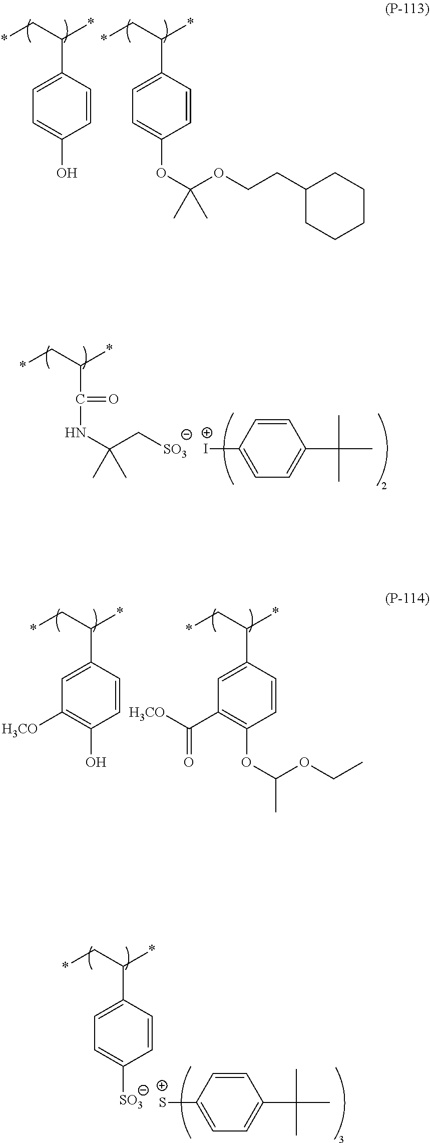

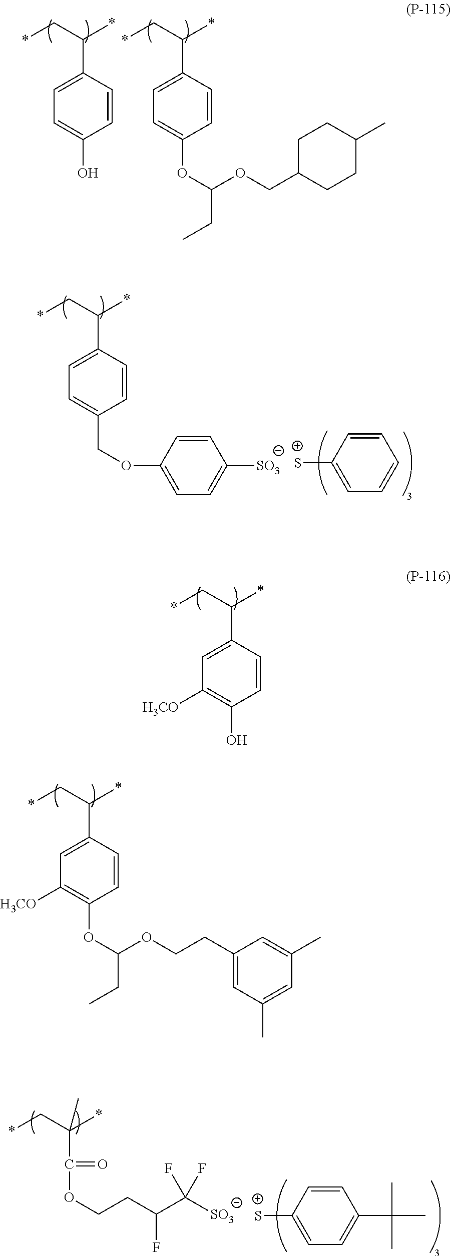

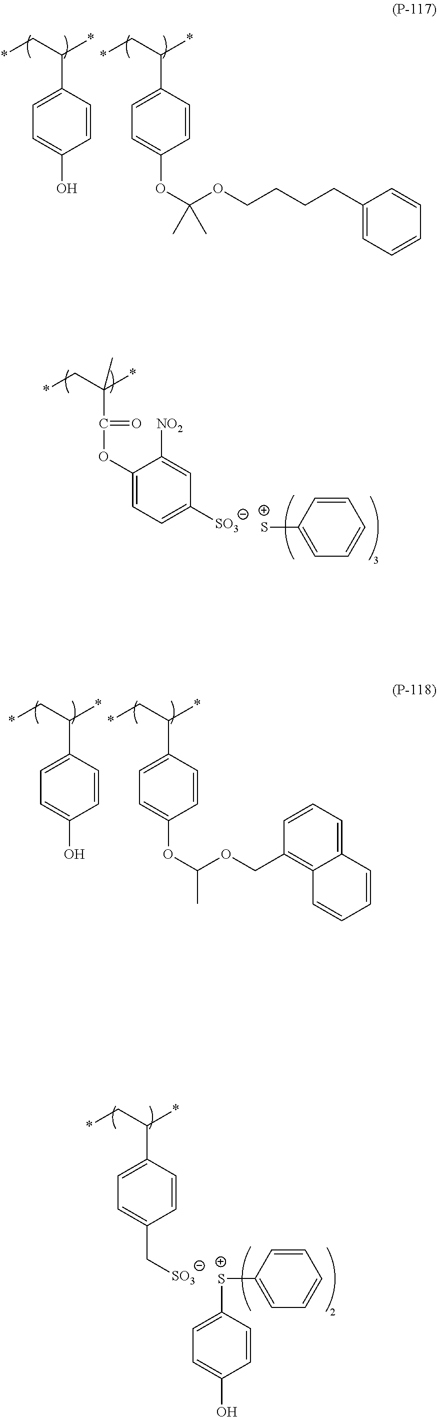

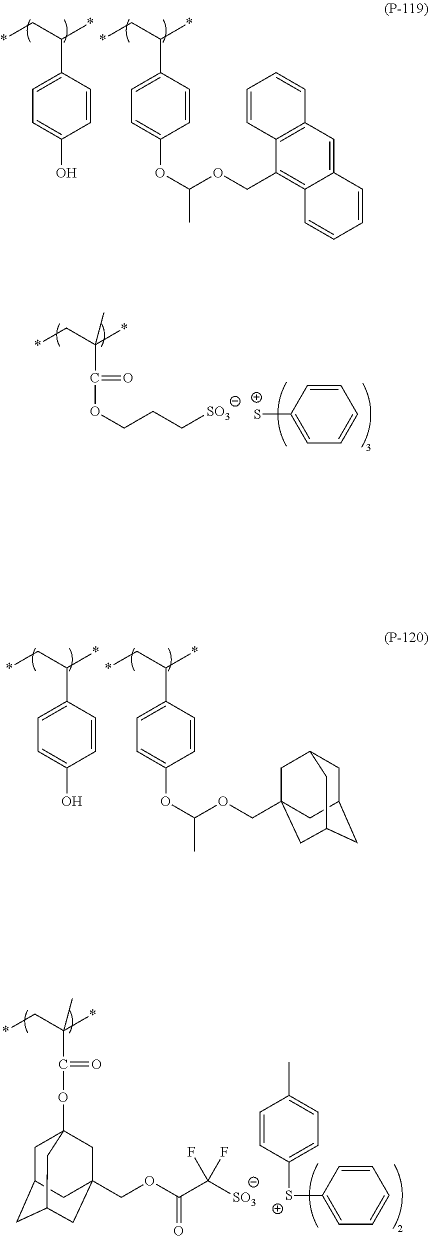

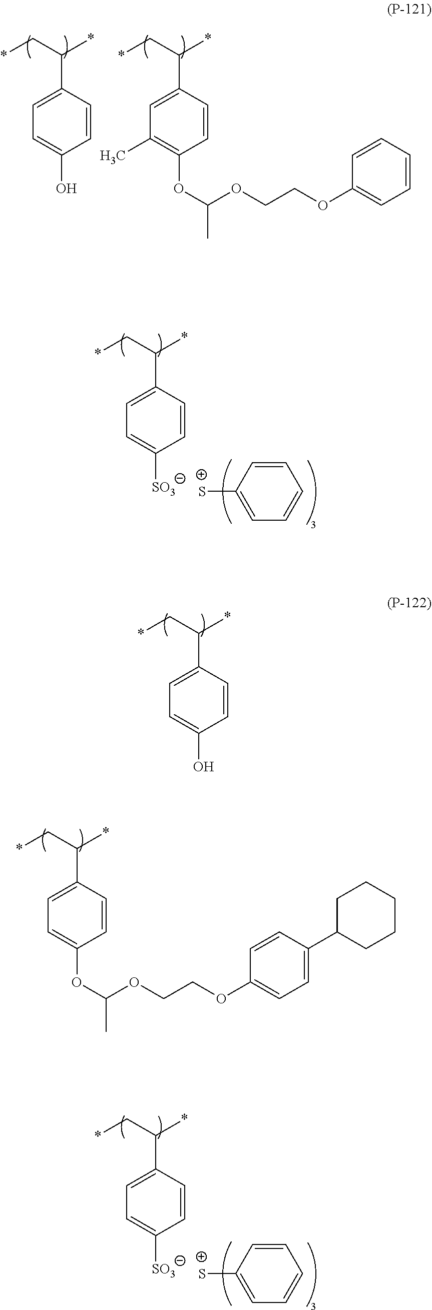

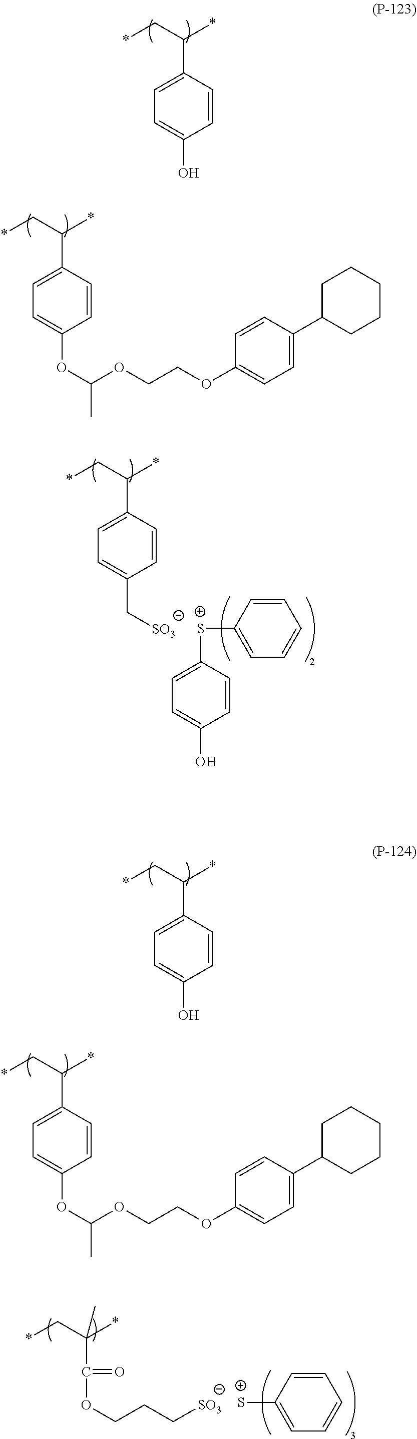

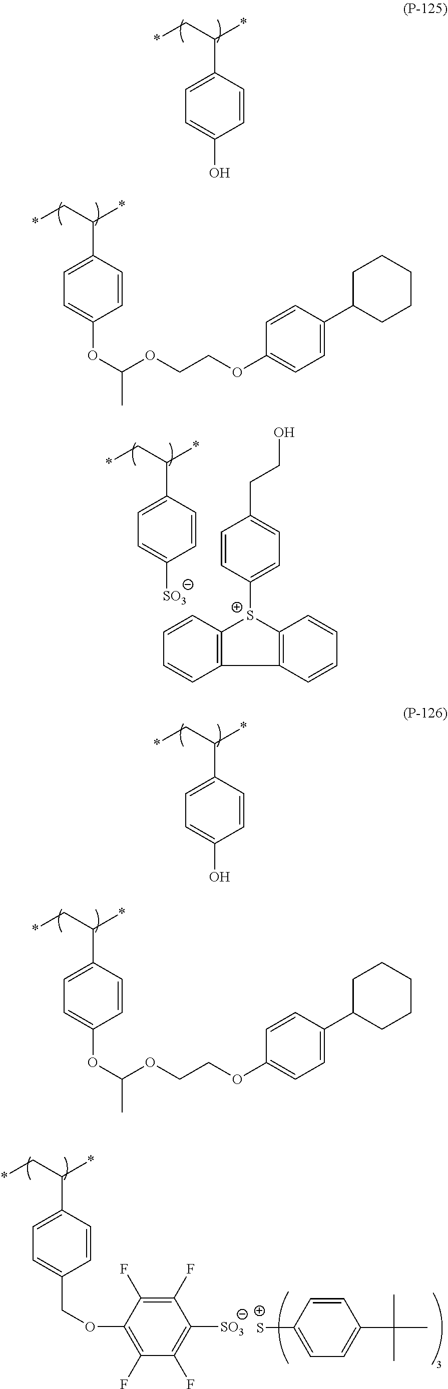

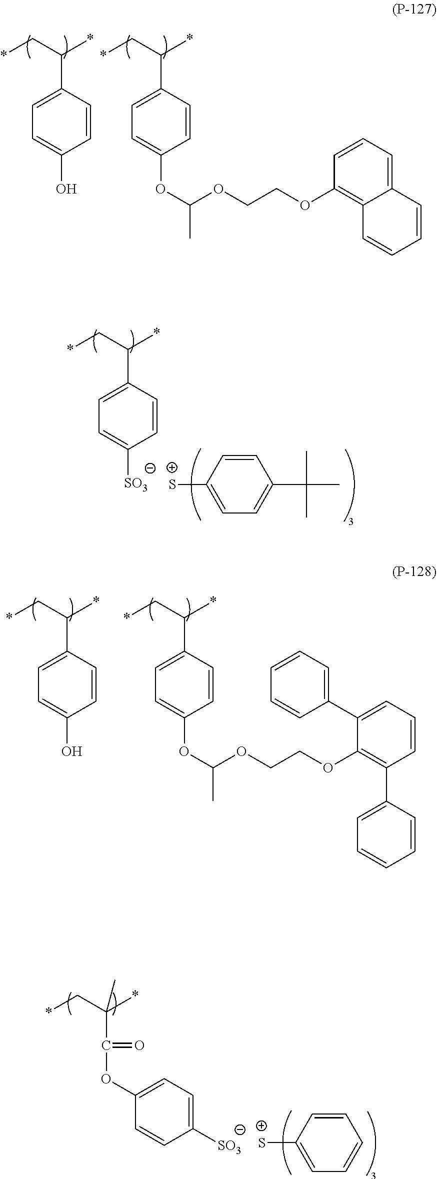

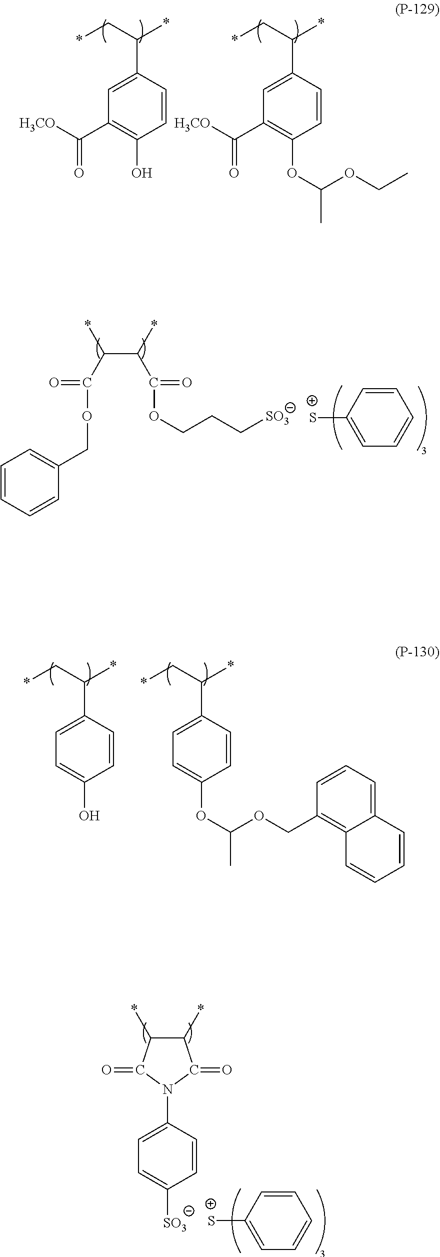

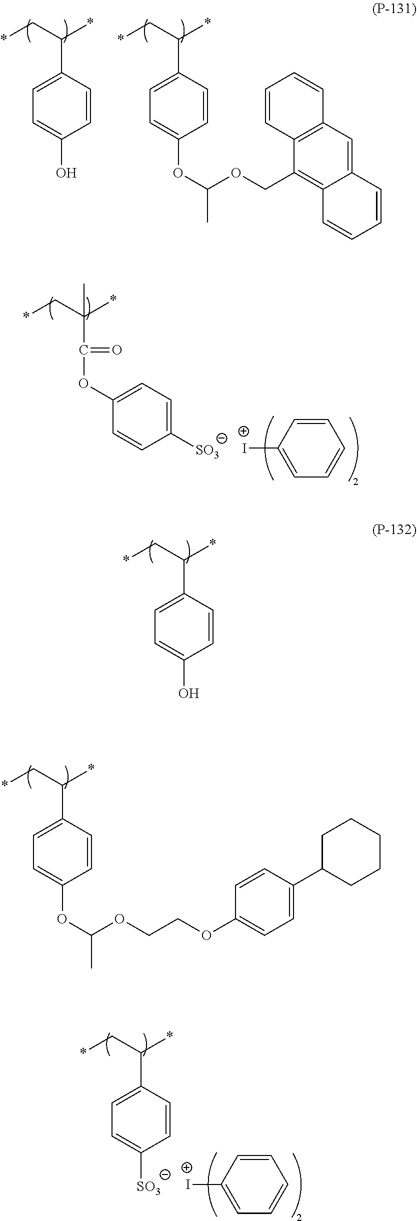

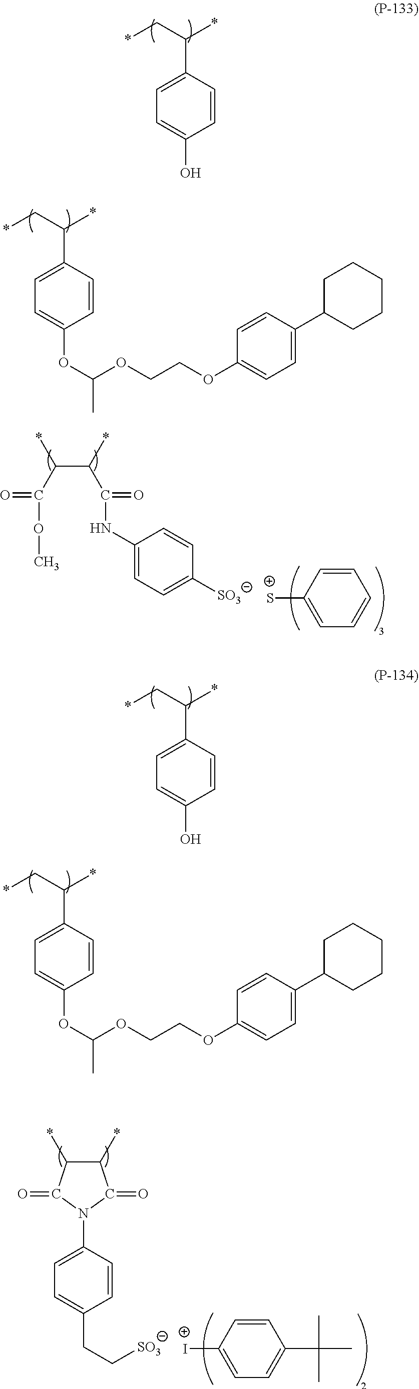

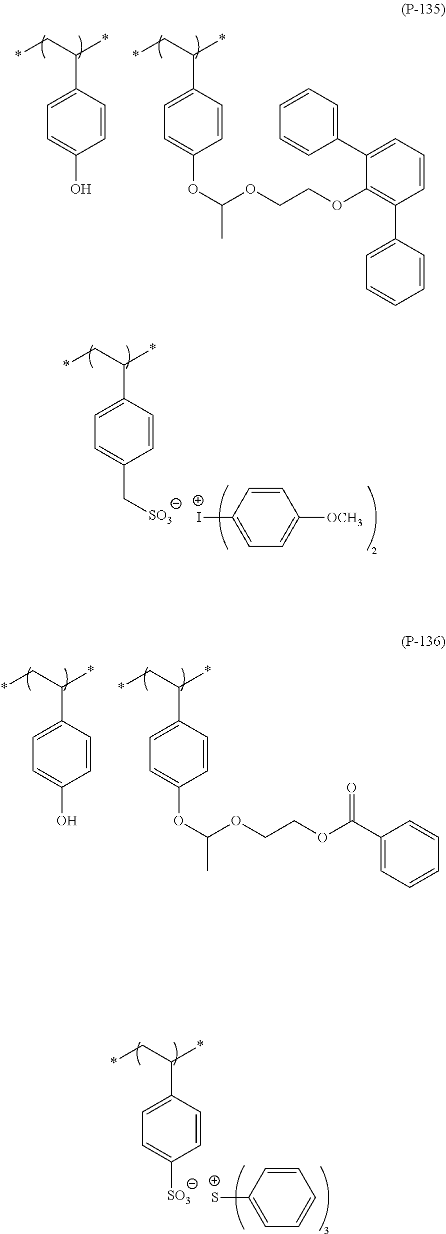

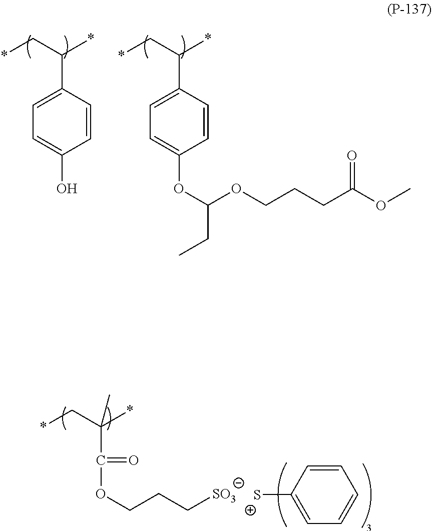

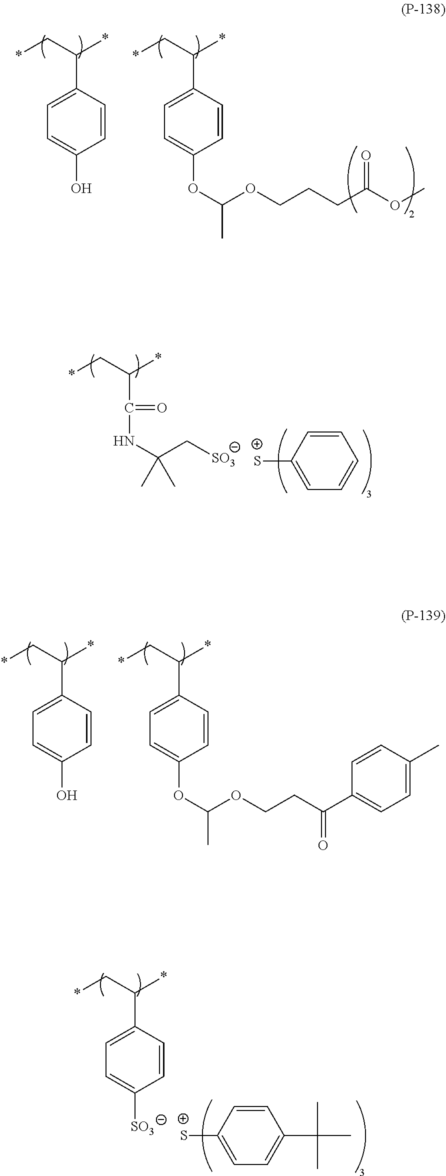

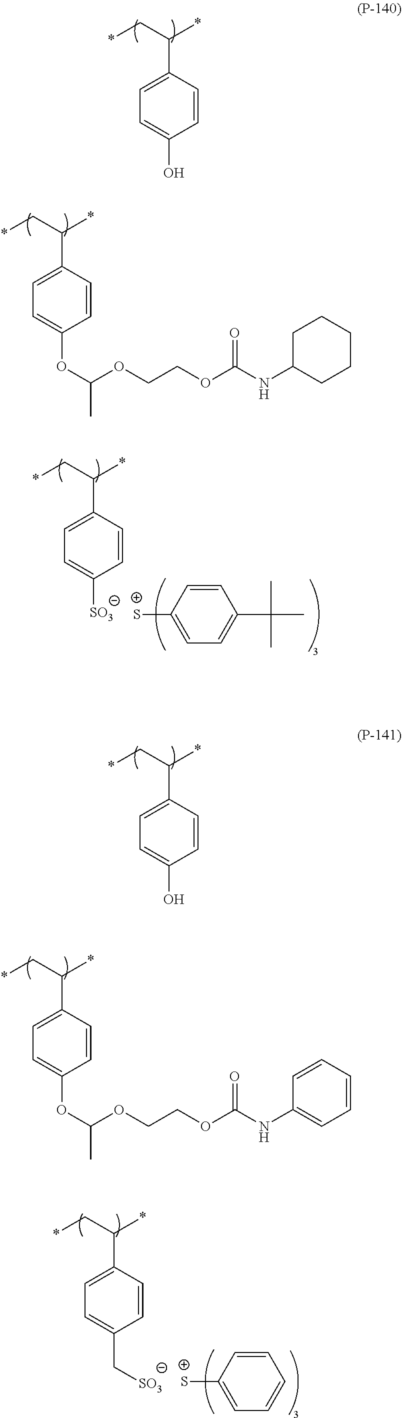

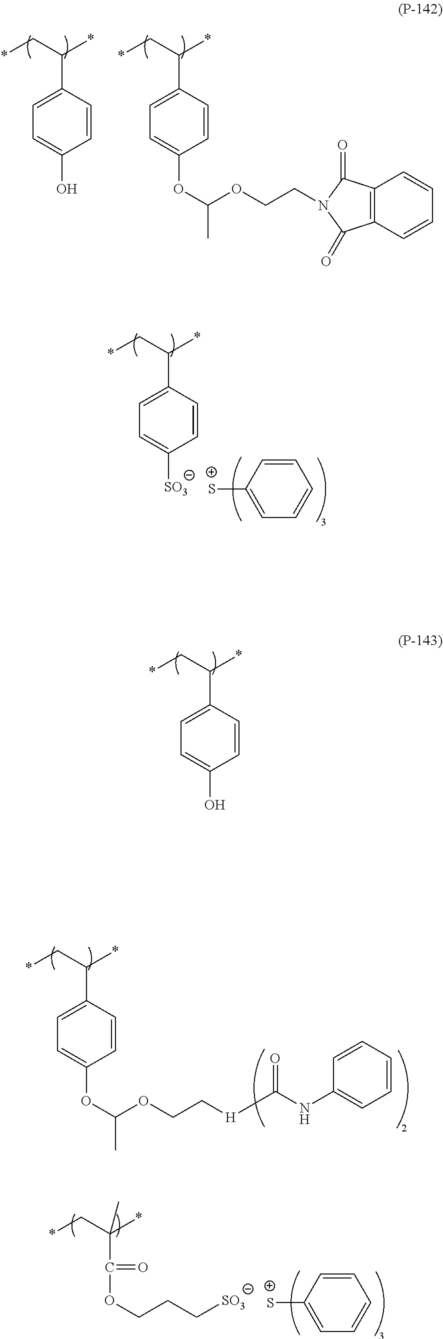

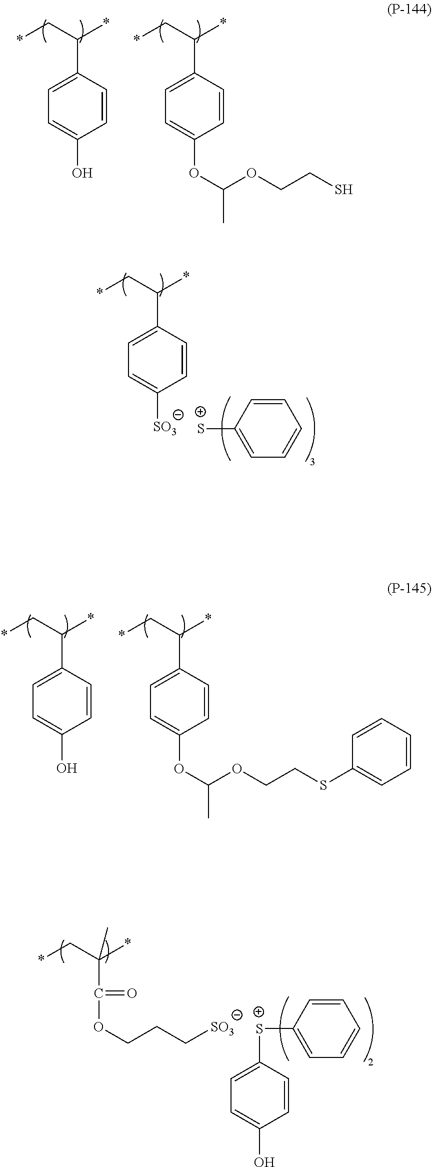

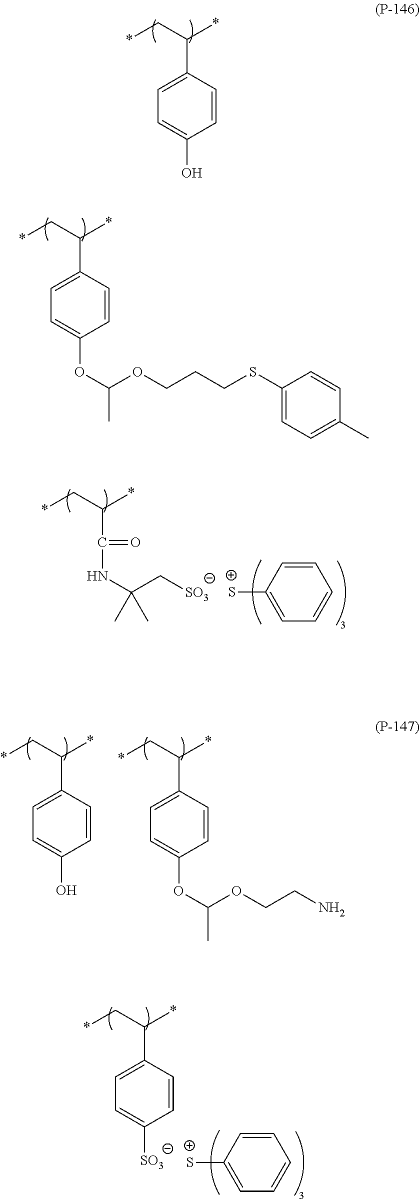

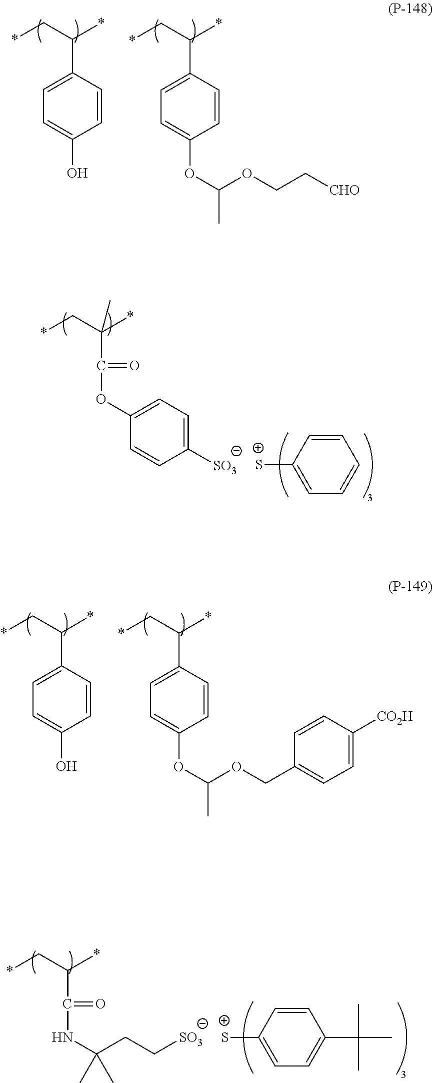

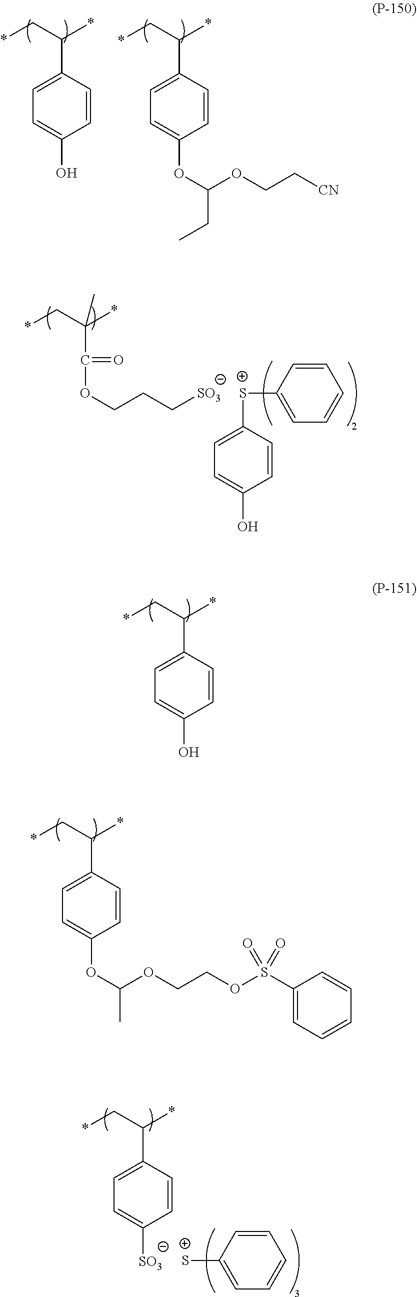

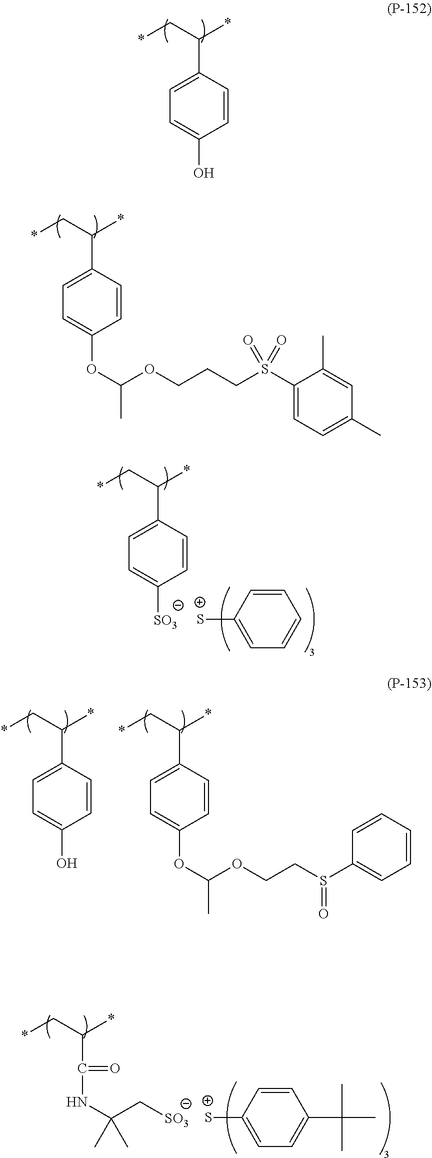

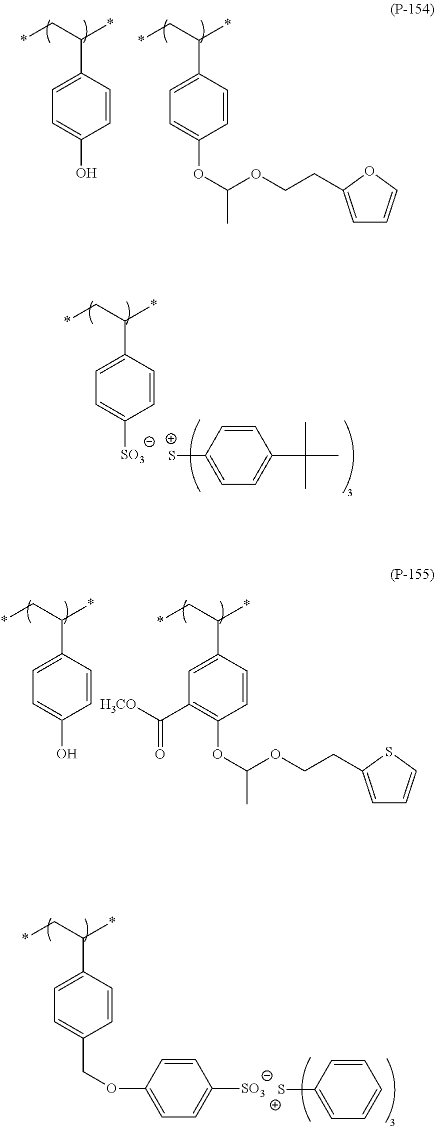

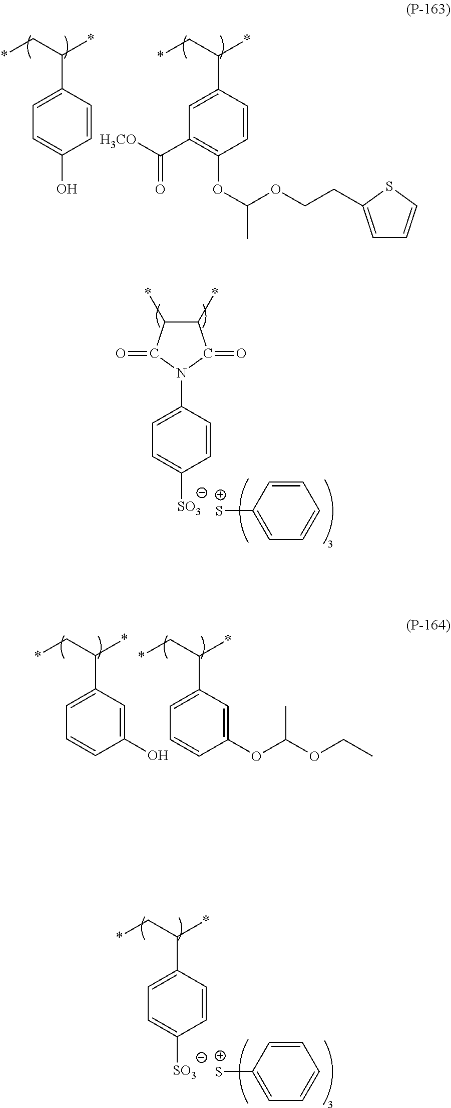

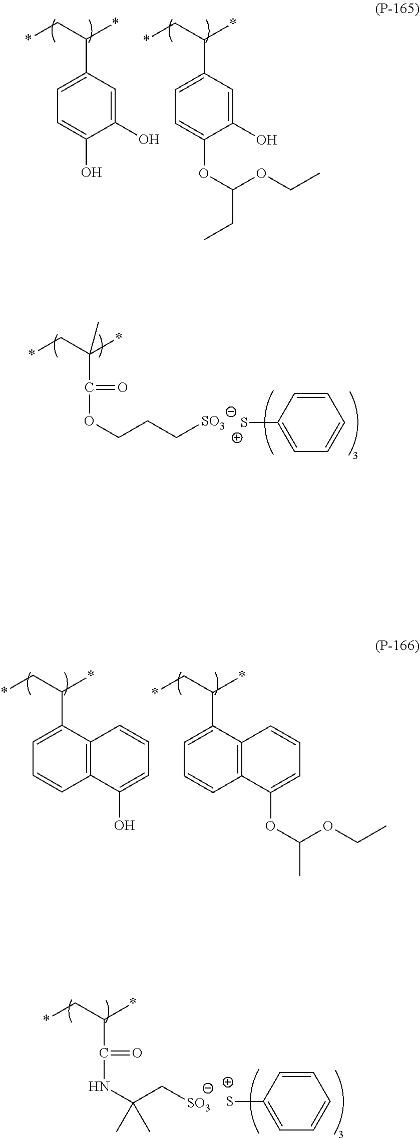

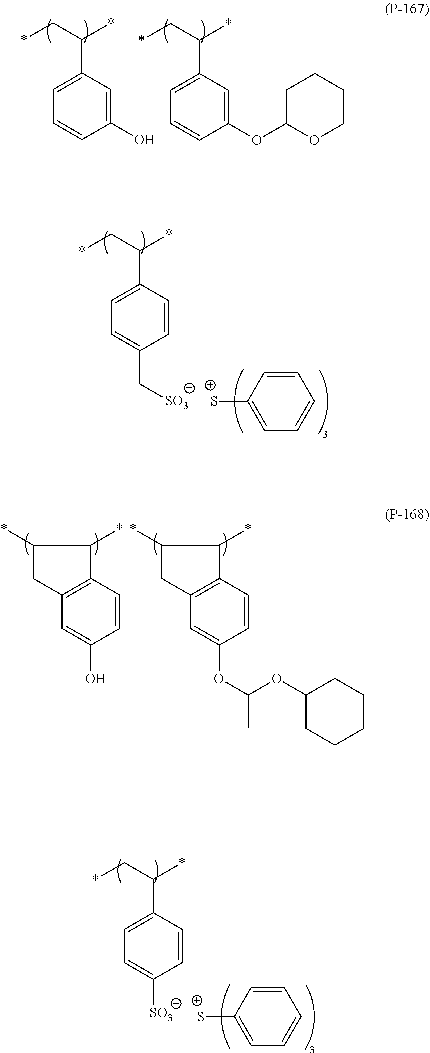

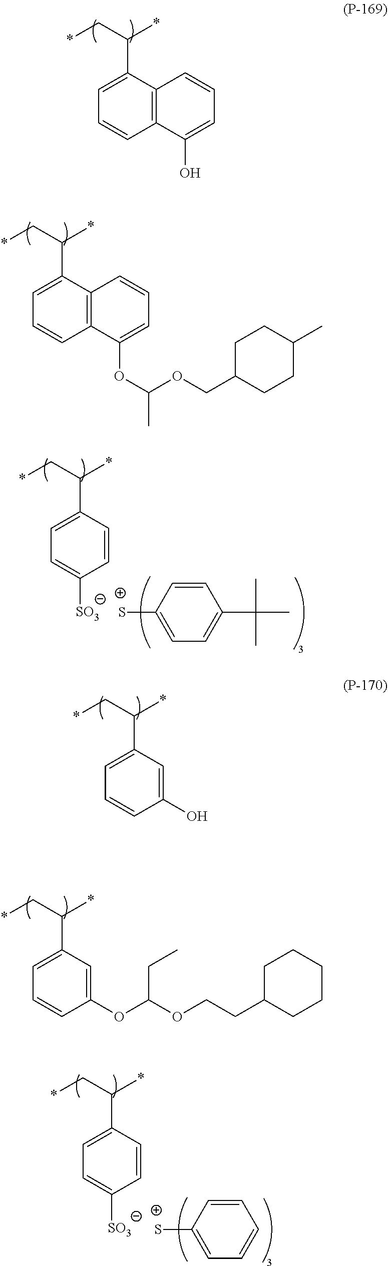

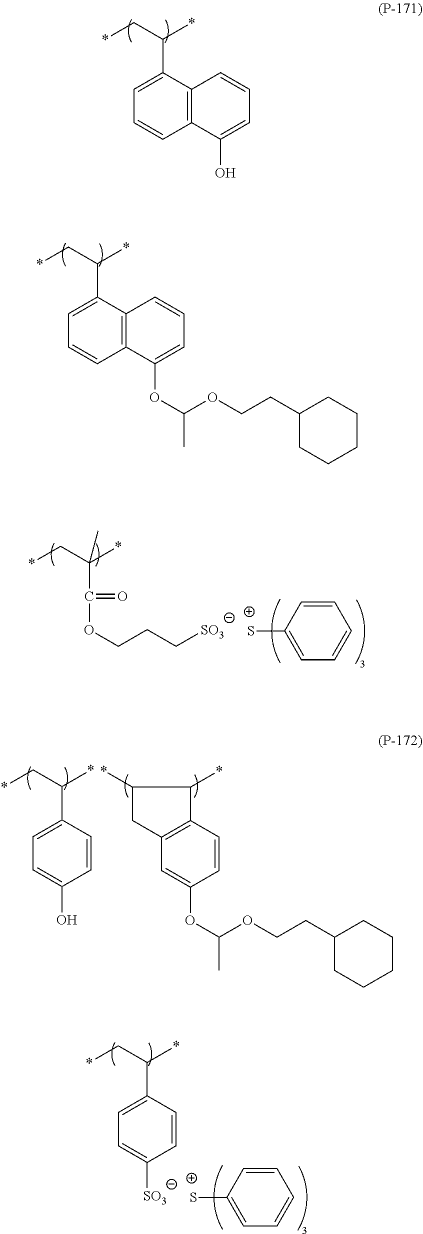

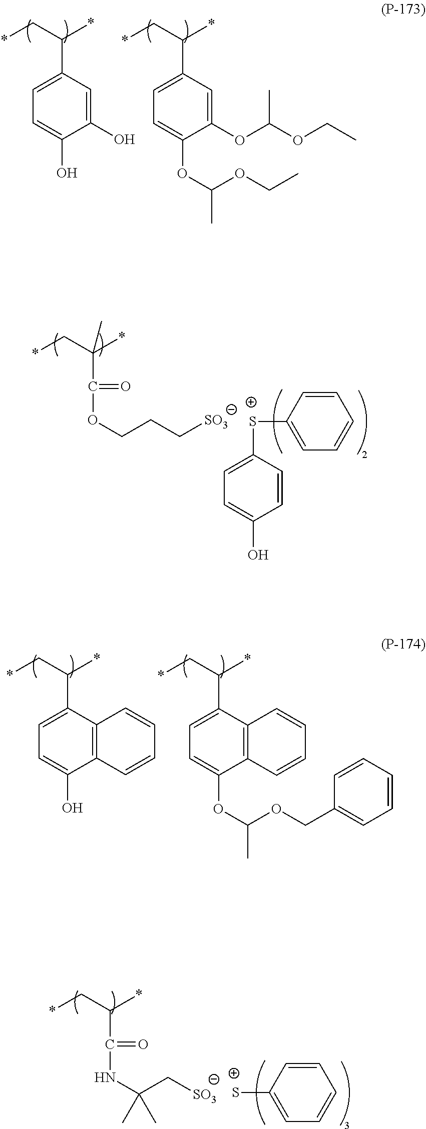

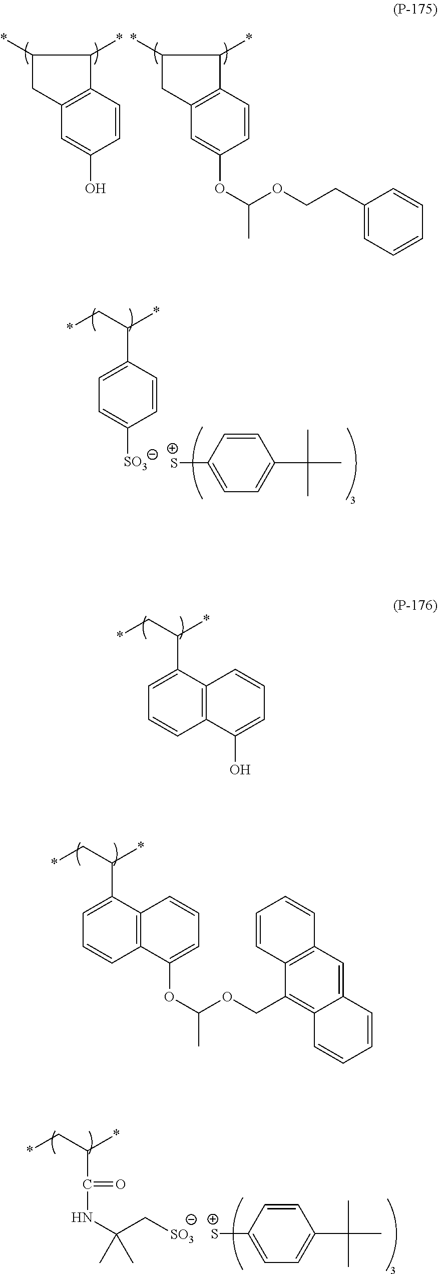

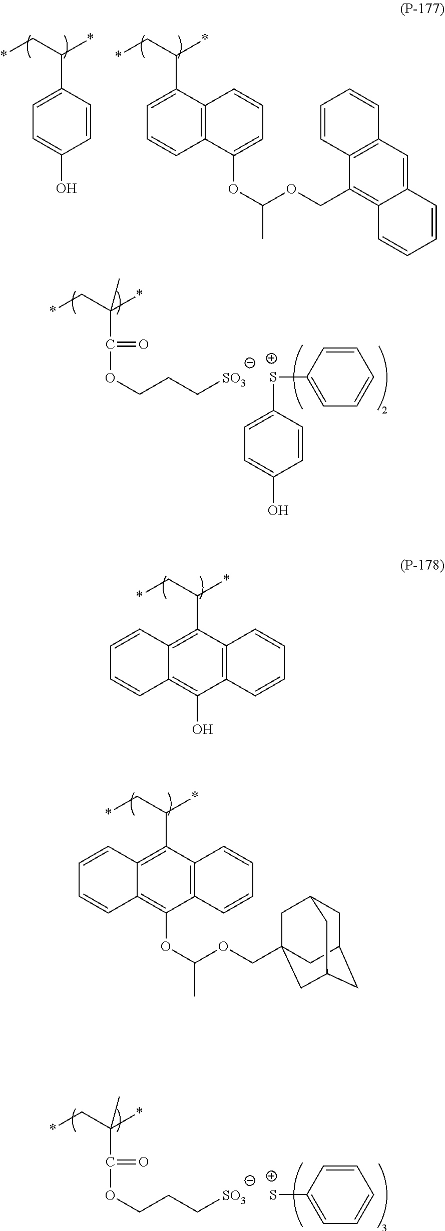

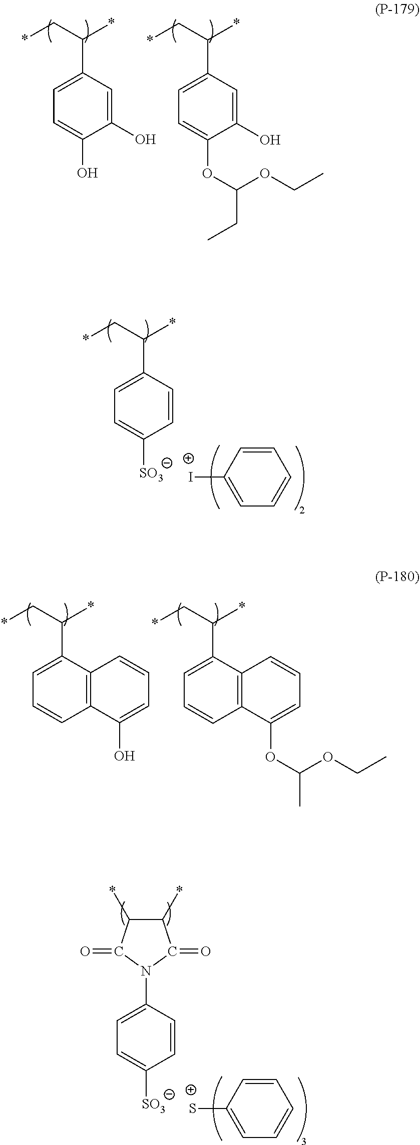

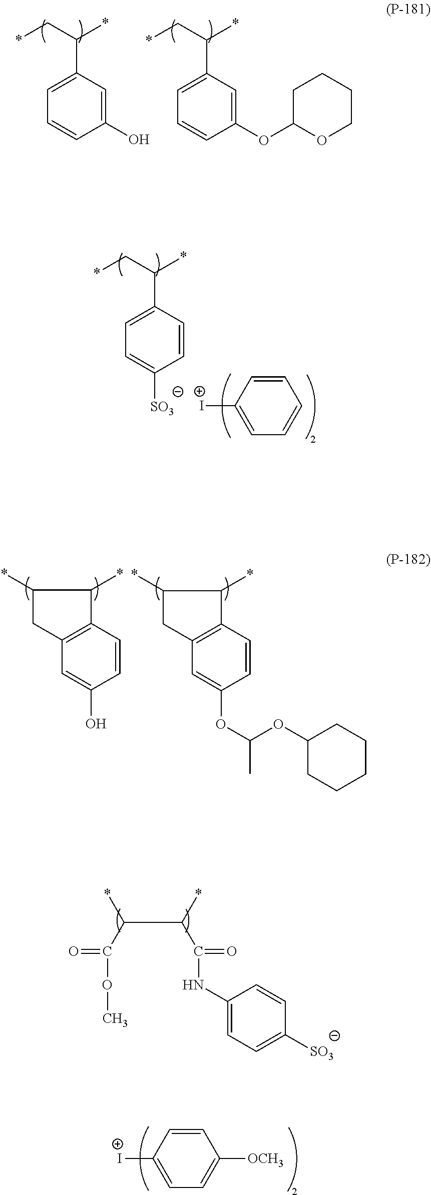

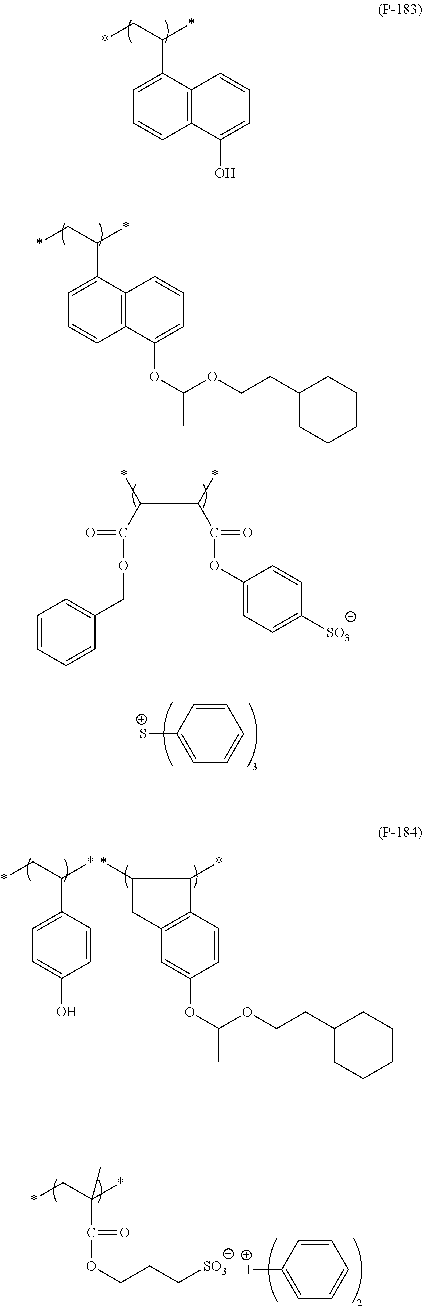

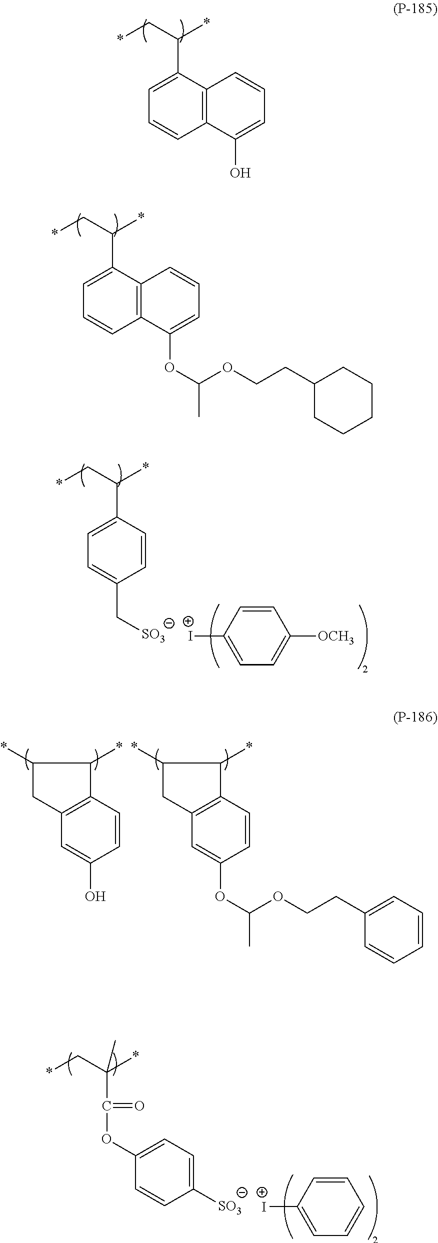

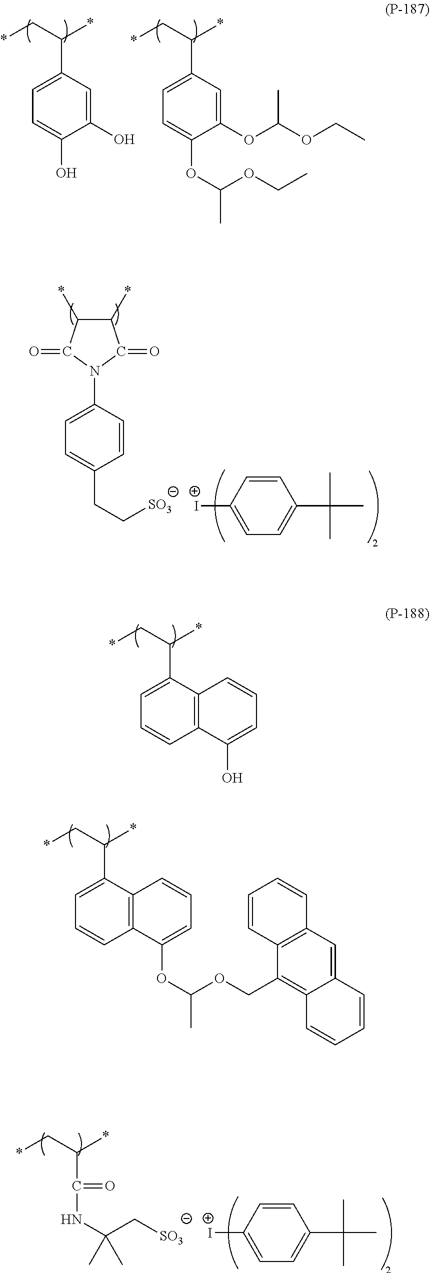

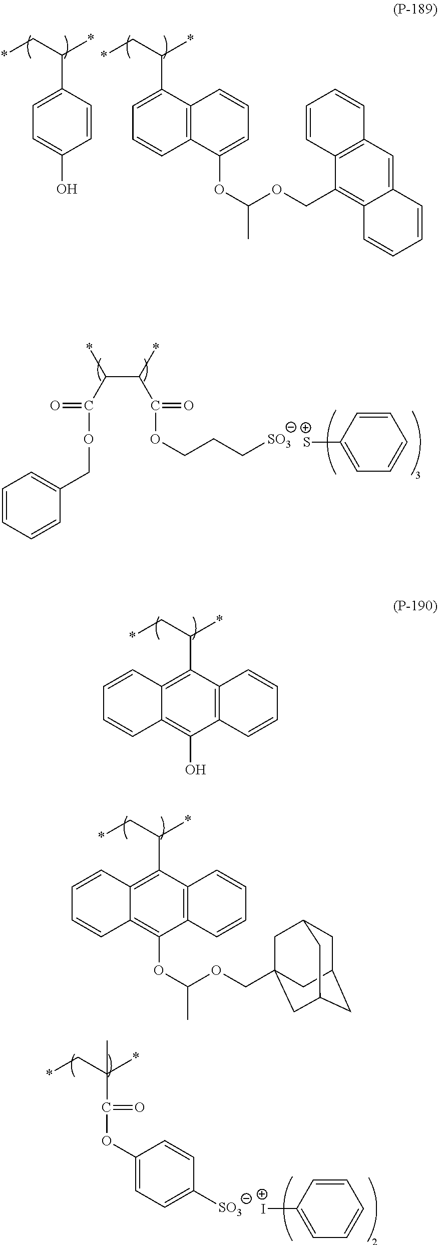

[2]Basic Compound

The composition of the present invention comprises any of basic compounds of general formula (1) below. For example, high sensitivity, high resolving power, favorable roughness characteristic and favorable iso/dense bias characteristic can be simultaneously attained by the incorporation of this basic compound.

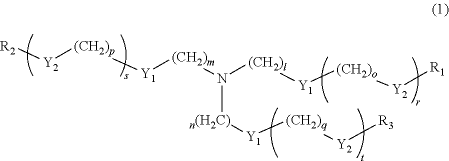

In the formula, each of l, m, o, p and q independently is an integer of 1 or greater;

n is an integer of 2 or greater;

each of r and s independently is an integer of 1 or greater;

t is an integer of 0 or greater;

each of —Y₁- and —Y₂— independently represents —O—, —S— or —CO—;

each of R₁ and R₂ independently represents a hydrogen atom, an alkyl group, an aryl group or an aralkyl group; and

R₃ represents a hydrogen atom, an alkyl group, an aryl group or an aralkyl group when n is 3 or greater and t is 1 or greater, and represents an alkyl group, an aryl group or an aralkyl group when t is 0, and represents an aryl group or an aralkyl group when n is 2.

As mentioned above, each of l, m, o, p and q is an integer of 1 or greater.

Each of l and m independently is an integer of preferably 1 to 5, more preferably 2 or 3 and most preferably 2.

Each of o, p and q independently is an integer of preferably 1 to 5, more preferably 2 or 3 and most preferably 2.

As mentioned above, n is an integer of 2 or greater. It is preferred for n to be an integer of 2 to 10, especially 2 to 6 and further especially 2 or 3. Most preferably, n is 3.

When n is 0 or 1, the basic compound has low boiling point and low hydrophobicity, and the iso/dense bias characteristic of the composition becomes poor. When n is excessively large, the boiling point and hydrophobicity of the basic compound may become excessively high. Further, when n is excessively large, the steric hindrance around amine nitrogen may increase to such an extent that the nucleophilicity of the basic compound is lowered. Consequently, if so, the iso/dense bias characteristic of the composition may be deteriorated.

As mentioned above, each of r and s is an integer of 1 or greater. Each of r and s independently is an integer of preferably 1 to 5, more preferably 1 or 2.

As mentioned above, t is an integer of 0 or greater. It is preferred for t to be an integer of 0 to 5, especially 0 to 2.

As mentioned above, each of —Y₁- and —Y₂-represents —O—, —S— or —CO—. It is preferred for each of —Y₁- and —Y₂- to independently represent —O— or —S—, especially —O—.

As mentioned above, each of R₁ and R₂ represents a hydrogen atom, an alkyl group, an aryl group or an aralkyl group. Preferably, each of R₁ and R₂ independently represents a hydrogen atom or an alkyl group. A hydrogen atom or a methyl group is more preferred, and a hydrogen atom is most preferred. A substituent may further be introduced in these alkyl, aryl and aralkyl groups.

The alkyl groups represented by R₁ and R₂ are, for example, a methyl group, an ethyl group, a propyl group, an isopropyl group, an n-butyl group, a sec-butyl group, a hexyl group, a 2-ethylhexyl group, an octyl group and a dodecyl group. Each of the alkyl groups represented by R₁ and R₂ preferably has 1 to 5 carbon atoms, more preferably 1 to 3 carbon atoms. A methyl group is most preferred.

The aryl groups represented by R₁ and R₂ are, for example, a phenyl group, a tolyl group, a naphthyl group and an anthryl group. Each of the aryl groups represented by R₁ and R₂ preferably has 6 to 15 carbon atoms.

The aralkyl groups represented by R₁ and R₂ are, for example, a benzyl group and a phenethyl group. Each of the aralkyl groups represented by R₁ and R₂ preferably has 6 to 20 carbon atoms.

As a substituent that can be introduced in these alkyl, aryl and aralkyl groups, there can be mentioned, for example, a hydroxyl group; a halogen atom such as a fluorine, chlorine, bromine or iodine atom; a nitro group; a cyano group; an amido group; a sulfonamido group; an alkyl group, such as a methyl group, an ethyl group, a propyl group, an isopropyl group, an n-butyl group, a sec-butyl group, a hexyl group, a 2-ethylhexyl group, an octyl group or a dodecyl group; an alkoxy group, such as a methoxy group, an ethoxy group, a hydroxyethoxy group, a propoxy group, a hydroxypropoxy group or a butoxy group; an alkoxycarbonyl group, such as a methoxycarbonyl group or an ethoxycarbonyl group; an acyl group, such as a formyl group, an acetyl group or a benzoyl group; an acyloxy group, such as an acetoxy group or a butyryloxy group; or a carboxyl group.

When n is 3 or greater and t is 1 or greater, R₃ represents a hydrogen atom, an alkyl group, an aryl group or an aralkyl group. This R₃ is preferably a hydrogen atom or an alkyl group, more preferably a hydrogen atom or a methyl group. A substituent may further be introduced in these alkyl, aryl and aralkyl groups. As particular examples of the alkyl group, aryl group and aralkyl group represented by R₃ and substituents that can further be introduced therein, there can be mentioned, for example, those set forth above in connection with R₁ and R₂.

When t is 0, R₃ represents an alkyl group, an aryl group or an aralkyl group. This R₃ is preferably an alkyl group, more preferably a methyl group. A substituent can further be introduced in these alkyl, aryl and aralkyl groups. As particular examples of the alkyl group, aryl group and aralkyl group represented by R₃ and substituents that can further be introduced therein, there can be mentioned, for example, those set forth above in connection with R₁ and R₂.

When n is 2, R₃ represents an aryl group or an aralkyl group. A substituent can further be introduced in these groups. Namely, in this instance, the basic compound is any of the compounds of general formula (1-Ar) below. When n is 2, if R₃ were a hydrogen atom or an alkyl group, the boiling point and hydrophilicity of the basic compound would be so low that the iso/dense bias characteristic of the composition would be poor.

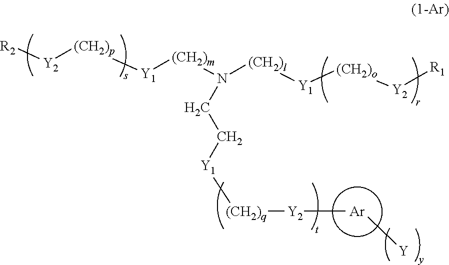

In the formula, Ar represents an aryl group or an aralkyl group.

Y represents a monovalent substituent. When y is 2 or greater, two or more Ys may be identical to or different from each other. At least two of these two or more Ys may be bonded to each other to thereby form a ring.

In the formula, y is an integer of 0 to 5.

The definition of each of l, m, o, p, q, r, s, t, —Y₁-, —Y₂-, R₁ and R₂ is the same as mentioned above in connection with general formula (1).

The aryl group represented by Ar preferably has 6 to 30 carbon atoms. As such, there can be mentioned, for example, a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quaterphenyl group, an o-, m- or p-tolyl group, a xylyl group, an o-, m- or p-cumenyl group, a mesityl group, a pentalenyl group, a binaphthalenyl group, a ternaphthalenyl group, a quaternaphthalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quateranthracenyl group, an anthraquinolyl group, a phenanthryl group, a triphenylenyl group, a pyrenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group or an ovalenyl group.

The aralkyl group represented by Ar preferably has 6 to 20 carbon atoms. As such, there can be mentioned, for example, a benzyl group or a phenethyl group.

Ar is preferably an aryl group, more preferably a phenyl group.

Y can be, for example, any of a hydroxyl group; a halogen atom such as a fluorine, chlorine, bromine or iodine atom; a nitro group; a cyano group; an amido group; a sulfonamido group; an alkyl group, such as a methyl group, an ethyl group, a propyl group, an isopropyl group, an n-butyl group, a sec-butyl group, a hexyl group, a 2-ethylhexyl group, an octyl group or a dodecyl group; an alkoxy group, such as a methoxy group, an ethoxy group, a hydroxyethoxy group, a propoxy group, a hydroxypropoxy group or a butoxy group; an alkoxycarbonyl group, such as a methoxycarbonyl group or an ethoxycarbonyl group; an acyl group, such as a formyl group, an acetyl group or a benzoyl group; an acyloxy group, such as an acetoxy group or a butyryloxy group; and a carboxyl group.

Y is preferably an alkoxy group, more preferably a methoxy group. When Ar is a phenyl group, it is preferred for the substitution with Y to take place at the ortho position (namely, 2- and/or 5-position) of the phenyl group.

In the formula, y is preferably 0 to 3, more preferably 1 to 3 and most preferably 2.

Preferred examples of l, m, o, p, q, r, s, t, —Y₁-, —Y₂-, R₁ and R₂ are the same as mentioned above in connection with general formula (1).

When n is 2, namely, when the basic compound is any of those of general formula (1-Ar), it is especially preferred for t to be 2.

Each of the basic compounds of general formula (1) is a tertiary amine in which a group containing R₁, a group containing R₂ and a group containing R₃ are bonded to a nitrogen atom.

The group containing R₃ is typically different from the group containing R₁ and the group containing R₂. For example, t is typically smaller than r and s. When n is 3 or greater, n is typically larger than l and m. When n is 2, R₃ is typically different from R₁ and R₂. When this arrangement is employed, for example, the resolving power, iso/dense bias characteristic and pattern shape can be enhanced.

Incidentally, the group containing R₁ and the group containing R₂ are typically identical to each other.

As mentioned above, it is preferred for each of R₁ and R₂ to be a hydrogen atom. It is especially preferred for R₁ and R₂ to be simultaneously hydrogen atoms. Namely, it is preferred for the basic compound to be any of the compounds of general formula (1-1) below. General formula (1-1) contains the structure of general formula (1-Ar) above in which R₁ and R₂ are simultaneously hydrogen atoms.

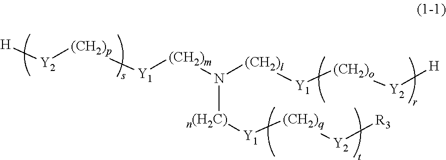

In the formula, the definition of each of l, m, n, o, p, q, r, s, t, —Y₁-, —Y₂- and R₃ is the same as mentioned above in connection with general formula (1). Further, preferred examples thereof are also the same as mentioned above in connection with general formula (1).

For example, the pattern shape can be enhanced by the employment of this structure.

As mentioned above, it is preferred for —Y₁- to be —O—. Particularly preferably, R₁ and R₂ are simultaneously hydrogen atoms, and —Y₁— is —O—. Namely, it is further preferred for the basic compound to be any of the compounds of general formula (1-2) below. General formula (1-2) contains the structure of above general formula (1-Ar) in which R₁ and R₂ are simultaneously hydrogen atoms and —Y₁— is —O—.

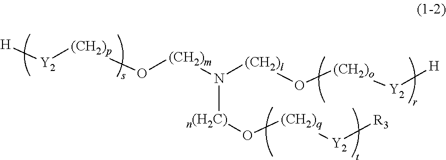

In the formula, the definition of each of l, m, n, o, p, q, r, s, t, —Y₂- and R₃ is the same as mentioned above in connection with general formula (1). Further, preferred examples thereof are also the same as mentioned above in connection with general formula (1).

For example, the pattern shape and focus latitude can be enhanced by the employment of this structure.

As mentioned above, it is preferred for —Y₂- to be —O—. Particularly preferably, R₁ and R₂ are simultaneously hydrogen atoms, —Y₁— is —O—, and —Y₂— is —O—. Namely, it is further preferred for the basic compound to be any of the compounds of general formula (1-3) below. General formula (1-3) contains the structure of above general formula (1-Ar) in which R₁ and R₂ are simultaneously hydrogen atoms and both of —Y₁- and —Y₂— are —O—.

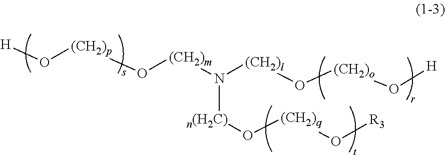

In the formula, the definition of each of l, m, n, o, p, q, r, s, t and R₃ is the same as mentioned above in connection with general formula (1). Further, preferred examples thereof are also the same as mentioned above in connection with general formula (1).

For example, the iso/dense bias characteristic can be enhanced by the employment of this structure.

Examples of the basic compounds of general formula (1) are as follows.

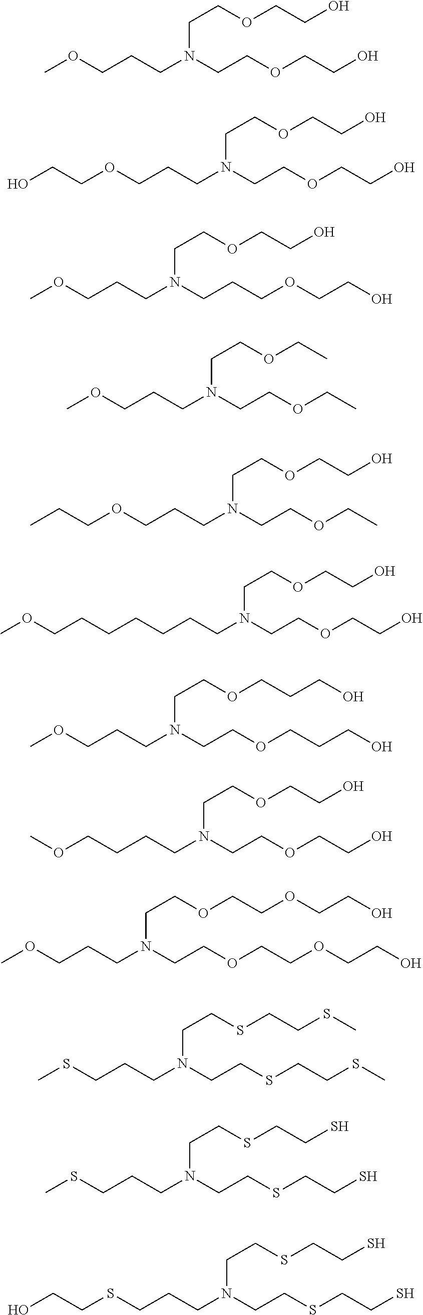

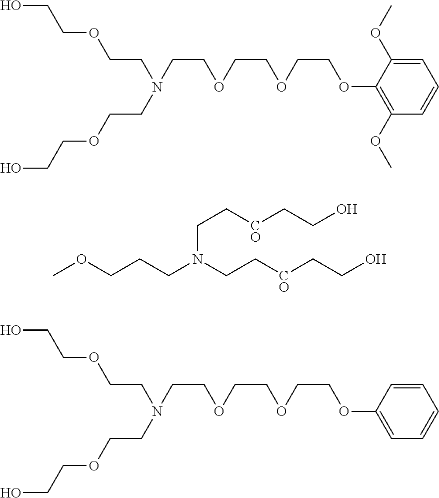

With respect to the above-described basic compounds, one type thereof may be used alone, or two or more types thereof may be used in combination.

The content of basic compounds of general formula (1) based on the total solids of the composition is preferably in the range of 0.01 to 8.0 mass %, more preferably 0.1 to 5.0 mass % and most preferably 0.1 to 4.0 mass %.

The basic compounds of general formula (1) are synthesized in, for example, the following manner.

First, a monoamine comprising a R₃-containing group is provided. Subsequently, this monoamine is caused to react with halides corresponding to a R₁-containing group and a R₂-containing group in an organic solvent in the presence of a base. Thereafter, the thus obtained salt is separated and purified, thereby obtaining a desired basic compound.

The composition of the present invention may further contain a basic compound other than the basic compounds of general formula (1). Namely, this composition may further contain a basic compound other than the compounds of general formula (1).

It is preferred for this other basic compound to be a nitrogen-containing organic compound. The usable basic compounds are not particularly limited. Use can be made of, for example, compounds of categories (1) to (4) below.

(1) Compounds of general formula (BS-1) below

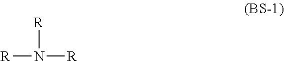

In general formula (BS-1), each of Rs independently represents a hydrogen atom or an organic group, provided that in no event all the three Rs are hydrogen atoms. As the organic group, there can be mentioned a linear or branched alkyl group, a cycloalkyl group (monocyclic or polycyclic), an aryl group and an aralkyl group. The compounds of general formula (BS-1) do not include any of those of general formulae (1).

The number of carbon atoms of the alkyl group represented by R is not particularly limited. However, it is generally in the range of 1 to 20, preferably 1 to 12.

The number of carbon atoms of the cycloalkyl group represented by R is not particularly limited. However, it is generally in the range of 3 to 20, preferably 5 to 15.

The number of carbon atoms of the aryl group represented by R is not particularly limited. However, it is generally in the range of 6 to 20, preferably 6 to 10. In particular, a phenyl group, a naphthyl group and the like can be mentioned.

The number of carbon atoms of the aralkyl group represented by R is not particularly limited. However, it is generally in the range of 7 to 20, preferably 7 to 11. In particular, a benzyl group and the like can be mentioned.

In the alkyl group, cycloalkyl group, aryl group and aralkyl group represented by R, a hydrogen atom thereof may be replaced by a substituent. As the substituent, there can be mentioned, for example, an alkyl group, a cycloalkyl group, an aryl group, an aralkyl group, a hydroxyl group, a carboxyl group, an alkoxy group, an aryloxy group, an alkylcarbonyloxy group, an alkyloxycarbonyl group or the like.

The compounds represented by general formula (BS-1) in which the at least two Rs are the organic groups are preferred.

Specific examples of the compounds of general formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline and the like.

The compounds represented by general formula (BS-1) in which at least one of Rs is a hydroxylated alkyl group are also preferred. Specific examples of the compounds include triethanolamine, N,N-dihydroxyethylaniline and the like.

With respect to the alkyl group represented by R, an oxygen atom may be present in the alkyl chain to thereby form an oxyalkylene chain. The oxyalkylene chain preferably consists of —CH₂CH₂O—. As particular examples thereof, there can be mentioned tris(methoxyethoxyethyl)amine, compounds shown in column 3 line 60 et seq. of U.S. Pat. No. 6,040,112 and the like.

(2) Compounds with Nitrogen-Atom-Containing Heterocyclic Structure

The nitrogen-atom-containing heterocyclic structure optionally may have aromaticity. It may have a plurality of nitrogen atoms, and also may have a heteroatom other than nitrogen. For example, there can be mentioned compounds with an imidazole structure (2-phenylbenzoimidazole, 2,4,5-triphenylimidazole and the like), compounds with a piperidine structure (N-hydroxyethylpiperidine, bis(1,2,2,6,6-pentamethyl-4-piperidyl) sebacate and the like), compounds with a pyridine structure (4-dimethylaminopyridine and the like) and compounds with an antipyrine structure (antipyrine, hydroxyantipyrine and the like).

Further, compounds with two or more ring structures can be appropriately used. For example, there can be mentioned 1,5-diazabicyclo[4.3.0]non-5-ene, 1,8-diazabicyclo[5.4.0]-undec-7-ene and the like.

(3) Ammonium Salt

Ammonium salts can also appropriately be used. The ammonium salts are preferably in the form of a hydroxide or carboxylate. In particular, preferred use is made of a tetraalkylammonium hydroxide, such as tetrabutylammonium hydroxide.

(4) As other compounds usable in the composition of the present invention, there can be mentioned, for example, the compounds synthesized in Examples of JP-A-2002-363146, the compounds (C1-1) to (C3-3) set forth as examples in Section [0066] of US 2007/0224539 A1 and the compounds described in Section 0108 of JP-A-2007-298569.

Further, photosensitive basic compounds may be used as other basic compounds. As photosensitive basic compounds, use can be made of, for example, the compounds described in Jpn. PCT National Publication No. 2003-524799, J. Photopolym. Sci&Tech. Vol. 8, p. 543-553 (1995), etc.

The molecular weight of each of these other basic compounds is preferably in the range of 250 to 2000, more preferably 400 to 1000.

When other basic compounds are further contained, the total amount of basic compounds of general formula (1) and other basic compounds, based on the total solids of the composition, is preferably in the range of 0.01 to 5.0 mass %, more preferably 0.1 to 2.5 mass %.

Further, in this instance, the molar ratio of basic compounds of general formula (1) to other basic compounds is preferably in the range of 90:10 to 20:80, more preferably 90:10 to 50:50.

[3] Other Component

The composition of the present invention may further comprise components other than the foregoing resin (P) and compound (Q).

While the actinic-ray- or radiation-sensitive resin composition of the present invention comprises the resin (P) with a photoacid-generating structure, the composition may further comprise, other than the resin (P), a low-molecular compound (hereinafter also referred to as an “acid generator” or a “photoacid generator”) that when exposed to actinic rays or radiation, generates an acid.

As such an acid generator, use can be made of a member appropriately selected from among a photoinitiator for photocationic polymerization, a photoinitiator for photoradical polymerization, a photo-achromatic agent and photo-discoloring agent for dyes, any of generally known compounds that when exposed to actinic rays or radiation, generate an acid, employed in microresists, etc., and mixtures thereof.

For example, as the acid generator, there can be mentioned an adinium salt, a diazonium salt, a phosphonium salt, a sulfonium salt, an iodonium salt, an imide sulfonate, an oxime sulfonate, diazosulfone, disulfone or o-nitrobenzyl sulfonate. As particular examples of these, there can be mentioned, for example, those set forth in Sections [0164] to [0248] of US Patent Application Publication No. 2008/0241737 A1.

As the low-molecular photoacid generator, use may be made of a salt comprising a cation containing a monocyclic or polycyclic nitrogen-containing heterocycle as mentioned above and an arbitrary anion.

When an acid generator, other than the resin with a photoacid generating structure (P), is used in the composition of the present invention, one type of acid generator can be used alone, or two or more types of acid generators can be used in combination.

The content of such acid generator in the composition, based on the total solids of the composition of the present invention, is preferably in the range of 0 to 20 mass %, more preferably 0 to 10 mass % and further more preferably 0 to 7 mass %. Although the acid generator is not an essential component in the present invention, it is generally used in an amount of 0.01 mass % or more in order to attain the effect of the addition thereof.

For example, it is preferred for the composition of the present invention to further contain a surfactant. The surfactant is preferably a fluorinated and/or siliconized surfactant.

As such a surfactant, there can be mentioned Megafac F176 or Megafac R08 produced by Dainippon Ink & Chemicals, Inc., PF656 or PF6320 produced by OMNOVA SOLUTIONS, INC., Troy Sol S-366 produced by Troy Chemical Co., Ltd., Florad FC430 produced by Sumitomo 3M Ltd., polysiloxane polymer KP-341 produced by Shin-Etsu Chemical Co., Ltd., or the like.

Surfactants other than these fluorinated and/or siliconized surfactants can also be used. In particular, the other surfactants include polyoxyethylene alkyl ethers, polyoxyethylene alkyl aryl ethers and the like. Moreover, generally known surfactants can also be appropriately used. As useful surfactants, there can be mentioned, for example, those described in section [0273] et seq of US 2008/0248425 A1.

These surfactants may be used alone or in combination.

The amount of surfactant added is preferably in the range of 0.0001 to 2 mass %, more preferably 0.001 to 1 mass %, based on the total solids of the composition.

The composition of the present invention may contain a dissolution inhibiting compound of 3000 or less molecular weight that is decomposed by the action of an acid to thereby increase the solubility in an alkali developer (hereinafter referred to as “dissolution inhibiting compound”).

The dissolution inhibiting compound is preferably an alicyclic or aliphatic compound having an acid-decomposable group, such as any of cholic acid derivatives having an acid-decomposable group described in Proceeding of SPIE, 2724, 355 (1996). A compound having a structure resulting from substitution of the phenolic hydroxyl group of a phenol compound with an acid-decomposable group is also preferred. The phenol compound preferably contains 1 to 9 phenol skeletons, more preferably 2 to 6 phenol skeletons.

In the present invention, the molecular weight of each dissolution inhibiting compound is 3000 or less, preferably 300 to 3000 and more preferably 500 to 2500.

The composition of the present invention may further comprise a dye. Suitable dyes are, for example, oil dyes and basic dyes.

The composition of the present invention may further comprise a compound capable of accelerating the dissolution in a developer. As the compound capable of accelerating the dissolution in a developer, there can be mentioned, for example, a low-molecular compound of 1000 or less molecular weight having either two or more phenolic OH groups or one or more carboxyl groups. When a carboxyl group is contained, an alicyclic or aliphatic compound is preferred. As the phenolic compound of 1000 or less molecular weight, there can be mentioned, for example, those described in JP-A's H4-122938 and H2-28531, U.S. Pat. No. 4,916,210 and EP 219294.

Moreover, the compounds having a functional group as a proton acceptor described in, for example, JP-A's 2006-208781 and 2007-286574 can also be appropriately used in the composition of the present invention.

It is preferred for the composition of the present invention to be in the form of a solution containing a solvent. As such a solvent, there can be mentioned an organic solvent, such as an alkylene glycol monoalkyl ether carboxylate, an alkylene glycol monoalkyl ether, an alkyl lactate, an alkyl alkoxypropionate, a cyclolactone, an optionally cyclized monoketone compound, an alkylene carbonate, an alkyl alkoxyacetate or an alkyl pyruvate. Solvents whose normal boiling point is 150° C. or below are especially preferred.

As preferred solvents, there can be mentioned 2-heptanone, cyclopentanone, γ-butyrolactone, cyclohexanone, butyl acetate, ethyl lactate, ethylene glycol monoethyl ether acetate, propylene glycol monomethyl ether acetate, propylene glycol monomethyl ether, ethyl 3-ethoxypropionate, ethyl pyruvate, 2-ethoxyethyl acetate, 2-(2-ethoxyethoxy)ethyl acetate and propylene carbonate. Most preferred solvents are propylene glycol monomethyl ether acetate and propylene glycol monomethyl ether.

In the present invention, any one of these solvents may be used alone, or any two or more thereof may be used in combination.

The amount of solvent used in the whole amount of the composition of the present invention can be appropriately regulated in accordance with the desired film thickness, etc. In general, the amount is so regulated that the total solid concentration of the composition falls in the range of 0.5 to 30 mass %, preferably 1.0 to 20 mass % and more preferably 1.5 to 10 mass %.

With respect to the particulars of the process for fabricating an imprint mold structure with the use of the composition of the present invention, reference can be made to, for example, “Fundamentals of nanoimprint and its technology development/application deployment—technology of nanoimprint substrate and its latest technology deployment” edited by Yoshihiko Hirai, published by Frontier Publishing (issued in June, 2006), Japanese Patent No. 4109085, JP-A-2008-162101, etc.

<Method of Forming Pattern>

The composition of the present invention is typically used in the following manner. Namely, the composition of the present invention is typically applied onto a support, such as a substrate, thereby forming a film. The thickness of the film is preferably in the range of 0.02 to 10.0 μm. The method of application onto a substrate is preferably a spin coating. The spin coating is performed at a rotating speed of preferably 1000 to 3000 rpm.

For example, the composition is applied onto, for example, any of substrates (e.g., silicon/silicon dioxide coating, silicon nitride and chromium-vapor-deposited quartz substrate, etc.) for use in, for example, the production of precision integrated circuit devices, etc. by appropriate application means, such as a spinner or a coater. The thus applied composition is dried, thereby obtaining an actinic-ray- or radiation-sensitive film (hereinafter also referred to as a photosensitive film). The application of the composition can be preceded by the application of a heretofore known antireflection film.

The resultant photosensitive film is exposed to actinic rays or radiation, preferably baked (heated), and developed. A pattern of enhanced quality can be obtained by baking. From the viewpoint of sensitivity and stability, the baking temperature is preferably in the range of 80 to 150° C., more preferably 90 to 130° C.

As the actinic rays or radiation, there can be mentioned, for example, infrared light, visible light, ultraviolet light, far-ultraviolet light, X-rays or electron beams. It is preferred for the actinic rays or radiation to have, for example, a wavelength of 250 nm or shorter, especially 220 nm or shorter. As such actinic rays or radiation, there can be mentioned, for example, a KrF excimer laser (248 nm), an ArF excimer laser (193 nm), an F₂ excimer laser (157 nm), X-rays or electron beams. As preferred actinic rays or radiation, there can be mentioned EUV-rays or electron beams. EUV-rays are especially appropriate.

The exposure in the condition that the interstice between the photosensitive film and a lens is filled with a liquid (for example, pure water) whose refractive index is higher than that of air, namely, liquid-immersion exposure may be carried out in the stage of the exposure to actinic rays or radiation. This liquid-immersion exposure can enhance the resolution.

In the development operation, an alkali developer is generally used. As the alkali developer for the composition of the present invention, use can be made of an alkaline aqueous solution containing, for example, an inorganic alkali such as sodium hydroxide, potassium hydroxide, sodium carbonate, sodium silicate, sodium metasilicate or aqueous ammonia; a primary amine such as ethylamine or n-propylamine; a secondary amine such as diethylamine or di-n-butylamine; a tertiary amine such as triethylamine or methyldiethylamine; an alcoholamine such as dimethylethanolamine or triethanolamine; a quaternary ammonium salt such as tetramethylammonium hydroxide or tetraethylammonium hydroxide; or a cycloamine such as pyrrole or piperidine.

Appropriate amounts of an alcohol and a surfactant may further be added to the above alkali developer before use. The alkali concentration of the alkali developer is generally in the range of 0.1 to 20 mass %. The pH value of the alkali developer is generally in the range of 10.0 to 15.0.

### Example

The present invention will be described in greater detail below by way of its examples. However, the gist of the present invention is in no way limited to these examples.

<Acid-Decomposable Resin>

The following resins (A-1) to (A-5) were provided as the resin (P).

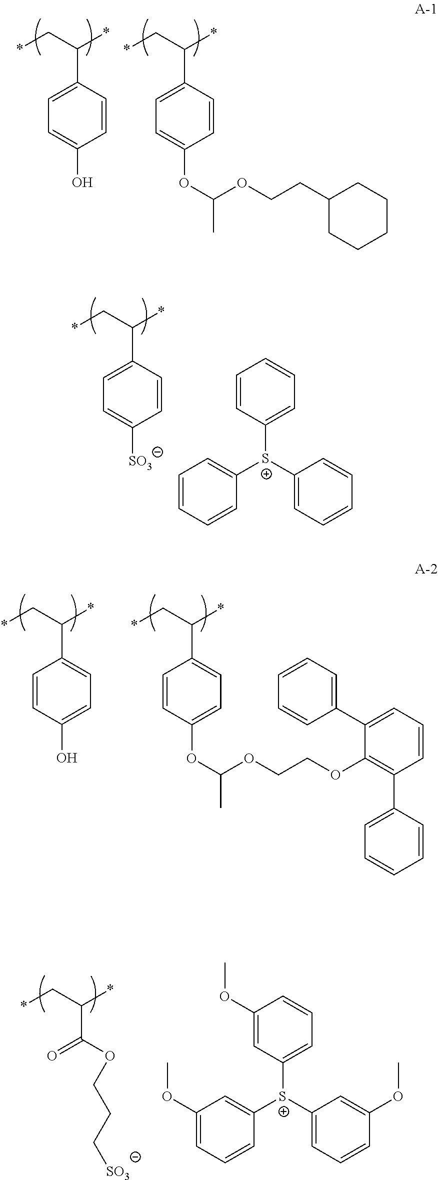

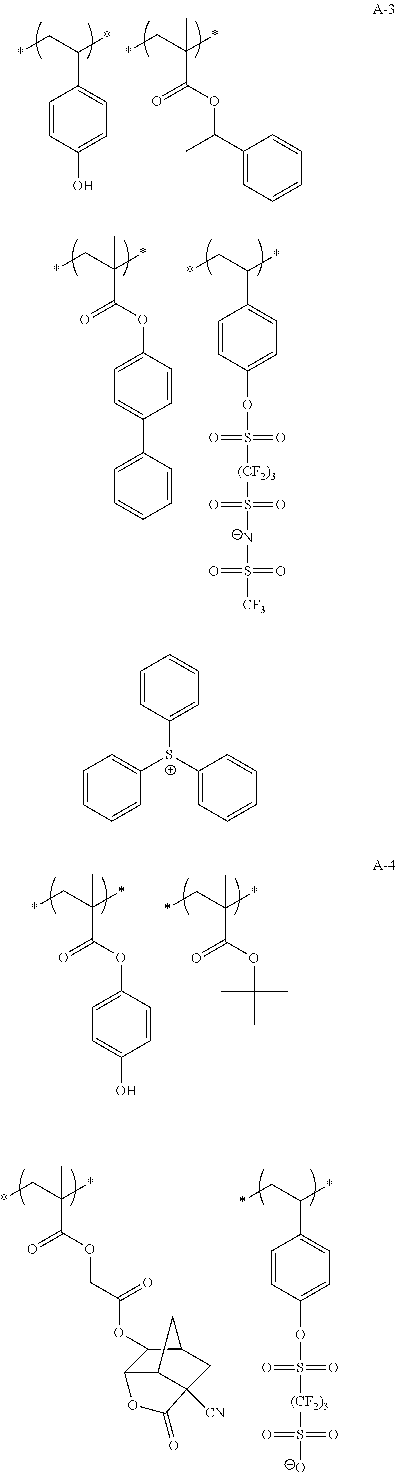

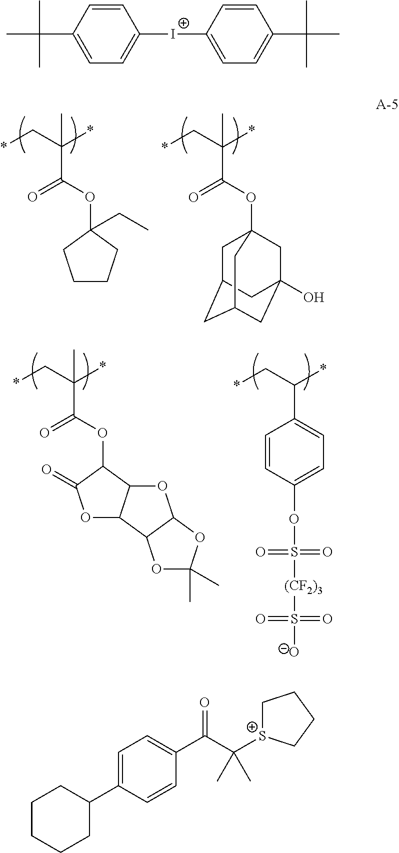

Table 1 below lists the component ratios (molar ratios; corresponding to individual repeating units shown above in order from the left), the weight average molecular weight (Mw) and the polydispersity index (PDI) with respect to each of the above resins (A-1) to (A-5).

TABLE 1

| Resin | Composition ratio | Mw | PDI |
|---|---|---|---|
| A-1 | 53/40/7 | 12000 | 1.64 |
| A-2 | 60/32/8 | 9800 | 1.72 |
| A-3 | 48/32/8/12 | 12500 | 1.59 |
| A-4 | 25/40/27/8 | 13500 | 1.66 |
| A-5 | 35/25/30/10 | 11000 | 1.51 |

<Basic Compound>

The following basic compounds (B-1) to (B-8) were synthesized in the manner to be described below. Further, the following compound (B-9) was provided as a basic compound usable in combination therewith. In addition, for control, the following comparative compounds (B-A) to (B-D) were provided.

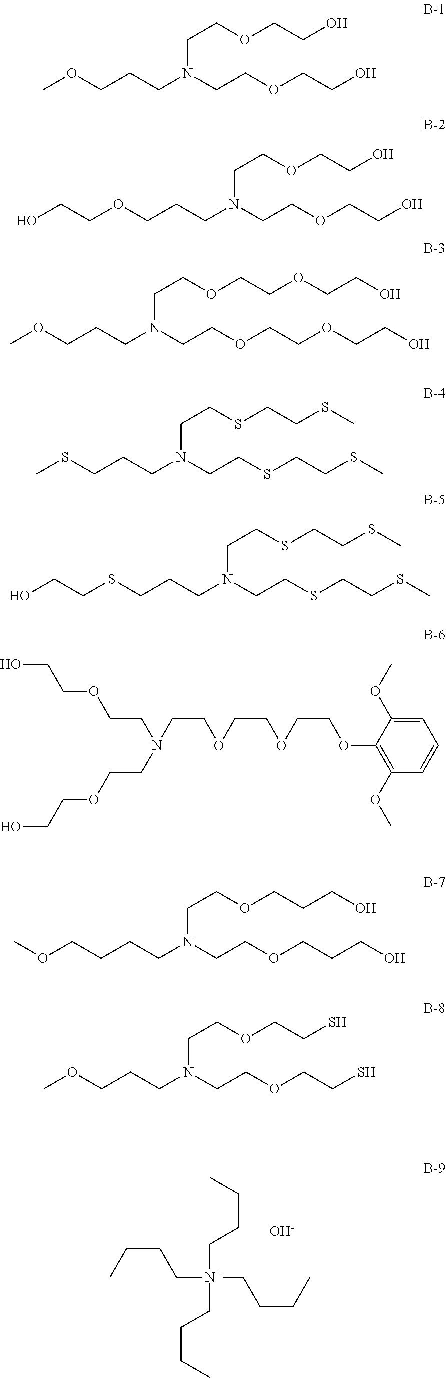

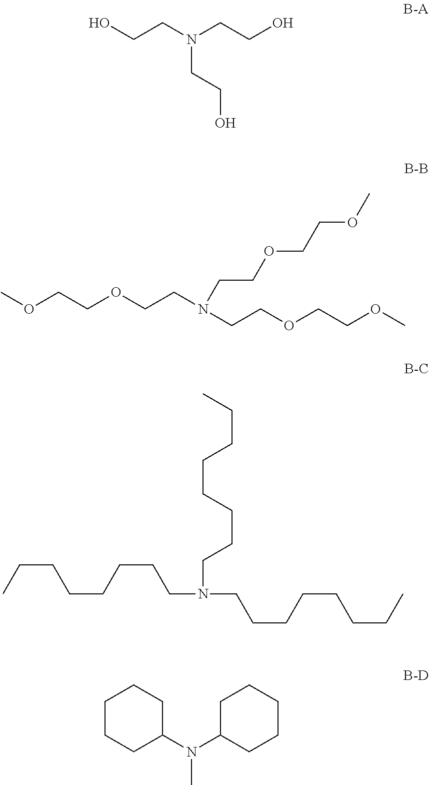

The correlations between these basic compounds (B-1) to (B-8) and various parameters of general formula (1) are as indicated in Table 2 below. In Table 2, “Me” represents a methyl group.

TABLE 2

| Basic compd. | n | t | l | m | o | p | q | r | s | X₁ | X₂ | R₁ | R₂ | R₃ |
|---|---|---|---|---|---|---|---|---|---|---|---|---|---|---|
| B-1 | 3 | 0 | 2 | 2 | 2 | 2 | — | 1 | 1 | O | O | H | H | Me |
| B-2 | 3 | 1 | 2 | 2 | 2 | 2 | 2 | 1 | 1 | O | O | H | H | H |
| B-3 | 3 | 0 | 2 | 2 | 2 | 2 | — | 2 | 2 | O | O | H | H | Me |
| B-4 | 3 | 0 | 2 | 2 | 2 | 2 | — | 1 | 1 | S | S | Me | Me | Me |
| B-5 | 3 | 1 | 2 | 2 | 2 | 2 | 2 | 1 | 1 | S | S, O | H | H | H |
| B-6 | 2 | 2 | 2 | 2 | 2 | 2 | 2 | 1 | 1 | O | O | H | H | 2,5-dimethoxyphenyl |
| | | | | | | | | | | | | | | group |
| B-7 | 4 | 0 | 2 | 2 | 3 | 3 | — | 1 | 1 | O | O | H | H | Me |
| B-8 | 3 | 0 | 2 | 2 | 2 | 2 | — | 1 | 1 | O | S | H | H | Me |

### Synthetic Example 1

### Basic Compound (B-1)

First, 30.0 g (0.3365 mol) of 3-methoxypropylamine, 92.2 g (0.7404 mol) of ethylene glycol mono-2-chloroethyl ether and 107.1 g (1.01 mol) of sodium carbonate were added to 200 ml of toluene. Thereafter, the obtained reaction liquid was heated under reflux over a period of 16 hours, and cooled. The thus precipitated salt was separated by filtration, and the toluene was distilled off in vacuum. Then, purification by silica gel chromatography was performed, thereby obtaining 38 g of basic compound (B-1) (yield: 43%).

(C-1)¹H-NMR (300 MHz, CDCl₃): δ1.73-1.84 (m, 2H), 2.62-2.71 (m, 6H), 3.41 (t, 2H, 6.0 Hz), 3.33 (s, 3H), 3.58-3.80 (m, 12H).

### Synthetic Example 2

### Basic Compound (B-6)

First, 105.6 g (0.370 mol) of 2-(2-(2-(2,6-dimethoxyphenoxy)ethoxy)ethoxy)ethaneamine, 92.2 g (0.740 mol) of ethylene glycol mono-2-chloroethyl ether and 107.1 g (1.01 mol) of sodium carbonate were added to 200 ml of toluene. The mixture was heated under reflux over a period of 16 hours, and cooled. The thus precipitated salt was separated by filtration, and the toluene was distilled off in vacuum. Thereafter, purification by silica gel chromatography was performed, thereby obtaining 50 g of basic compound (B-6) (yield: 29%).

### Synthetic Example 3

### Basic Compounds (B-2) to (B-5) and (B-7) to (B-8)

Basic compounds (B-2) to (B-5), (B-7) and (B-8) were synthesized in the same manner as in Synthetic Example 1 for the synthesis of basic compound (B-1).

<Surfactant>

The following surfactant was used.

W-1: PF6320 (produced by OMNOVA SOLUTIONS, INC., fluorinated).

<Preparation of Resist Composition>

Components of Table 3 below were dissolved in a solvent comprised of a 40:60 mixture of propylene glycol monomethyl ether acetate and propylene glycol monomethyl ether, thereby obtaining solutions each of 3.5 mass % solid content. The solutions were each passed through a polytetrafluoroethylene filter of 0.03 μm pore size, thereby obtaining chemically amplified positive resist compositions (positive resist solutions). In Table 3, the amount of each of the components is expressed by the mass % based on the total solids.

TABLE 3

| | Resin | Basic compd. | Surfactant |
|---|---|---|---|
| Ex. | (mass %) | (mass %) | (mass %) |
| Ex. 1 | A-1 | B-1 | W-1 |
| | (98.93) | (1.06) | (0.01) |
| Ex. 2 | A-1 | B-2 | W-1 |
| | (98.81) | (1.18) | (0.01) |
| Ex. 3 | A-1 | B-3 | W-1 |
| | (98.58) | (1.41) | (0.01) |
| Ex. 4 | A-1 | B-4 | W-1 |
| | (98.49) | (1.50) | (0.01) |
| Ex. 5 | A-1 | B-5 | W-1 |
| | (98.37) | (1.62) | (0.01) |
| Ex. 6 | A-1 | B-6 | W-1 |
| | (98.14) | (1.85) | (0.01) |
| Ex. 7 | A-1 | B-7 | W-1 |
| | (98.76) | (1.23) | (0.01) |
| Ex. 8 | A-1 | B-8 | W-1 |
| | (98.80) | (1.19) | (0.01) |
| Ex. 9 | A-2 | B-3 | W-1 |
| | (98.58) | (1.41) | (0.01) |
| Ex. 10 | A-3 | B-3 | W-1 |
| | (98.58) | (1.41) | (0.01) |
| Ex. 11 | A-4 | B-3 | W-1 |
| | (98.58) | (1.41) | (0.01) |
| Ex. 12 | A-5 | B-3 | W-1 |
| | (98.58) | (1.41) | (0.01) |
| Ex. 13 | A-1 | B-3/B-9 | W-1 |
| | (98.67) | (1.06/0.26) | (0.01) |
| Comp. Ex. 1 | A-1 | B-A | W-1 |
| | (99.39) | (0.60) | (0.01) |
| Comp. Ex. 2 | A-1 | B-B | W-1 |
| | (98.70) | (1.29) | (0.01) |
| Comp. Ex. 3 | A-1 | B-C | W-1 |
| | (98.57) | (1.42) | (0.01) |
| Comp. Ex. 4 | A-1 | B-D | W-1 |
| | (99.21) | (0.78) | (0.01) |

<Evaluation of Resist (EB)>

Each of the above positive resist solutions was applied onto a silicon substrate having undergone a hexamethyldisilazane treatment by means of a spin coater, and baked at 100° C. for 90 seconds. Thus, resist films of 100 nm average thickness were obtained.

Each of the resist films was irradiated with electron beams by means of an electron beam lithography system (HL750 manufactured by Hitachi, Ltd., acceleration voltage 50 KeV), and baked at 110° C. for 60 seconds. The baked film was developed by dipping the same in a 2.38 mass % aqueous TMAH solution for 60 seconds. After the development, the film was rinsed with pure water for 30 seconds and dried. Thus, a line pattern was formed.

[Sensitivity (Eopt)]

The obtained pattern was observed by means of a scanning electron microscope (model S-9260 manufactured by Hitachi, Ltd.). The sensitivity (Eopt) was defined as an exposure amount in which a line of 100 nm width (line:space=1:1) was resolved.

[Resolving Power]

At the resolution of a pattern of line:space=1:1 while fixing the exposure amount at the above Eopt, the minimum of resolvable line width was determined by means of a scanning electron microscope (model S-9260 manufactured by Hitachi, Ltd.). This minimum value was denoted as “resolving power.”

[Roughness Characteristic; LWR]

The above line of 100 nm width was observed by means of a scanning electron microscope (model S-9260, manufactured by Hitachi, Ltd.). The distance between actual edge and a reference line on which edges were to be present was measured at 50 points of equal intervals within 2 μm in the longitudinal direction of the line. The standard deviation of measured distances was determined, and 3σ was computed therefrom. This 3σ was denoted as “LWR.”

[I-D Bias]

Each of the obtained patterns was observed by means of a scanning electron microscope (model S-9260 manufactured by Hitachi, Ltd.). The exposure amount in which a line of 100 nm width (line:space=1:10) was resolved was denoted as “Eopt′.” The difference between the above sensitivity Eopt and this Eopt′ (Eopt−Eopt′) was denoted as “I-D Bias.” The smaller the value of I-D Bias, the more favorable the iso/dense bias characteristic.

The obtained evaluation results are given in Table 4 below.

TABLE 4

| | | Resolving | | |
|---|---|---|---|---|
| | Sensitivity | power | LWR | I-D Bias |
| Ex. | (μC/cm²) | (nm) | (nm) | (μC/cm²) |
| Ex. 1 | 25 | 37.5 | 4.3 | 3 |
| Ex. 2 | 26 | 37.5 | 4.6 | 4 |
| Ex. 3 | 28 | 37.5 | 3.9 | 3 |
| Ex. 4 | 33 | 50 | 5.6 | 8 |
| Ex. 5 | 31 | 50 | 5.1 | 7 |
| Ex. 6 | 24 | 37.5 | 4.4 | 4 |
| Ex. 7 | 30 | 37.5 | 4.6 | 5 |
| Ex. 8 | 35 | 37.5 | 4.7 | 5 |
| Ex. 9 | 27 | 37.5 | 3.7 | 5 |
| Ex. 10 | 30 | 37.5 | 3.9 | 4 |
| Ex. 11 | 31 | 37.5 | 4.1 | 2 |
| Ex. 12 | 36 | 50 | 4.5 | 3 |
| Ex. 13 | 29 | 37.5 | 3.6 | 3 |
| Comp. Ex. 1 | 38 | 100 | 7.5 | 17 |
| Comp. Ex. 2 | 33 | 62.5 | 6.9 | 12 |
| Comp. Ex. 3 | 32 | 75 | 9.1 | 14 |
| Comp. Ex. 4 | 23 | 100 | 10.1 | 10 |

As apparent from Table 4, the compositions of the Examples excelled in the sensitivity, resolving power, roughness characteristic and iso/dense bias characteristic.

<Evaluation of Resist (EUV)>

Each of the above positive resist solutions was applied onto a silicon substrate having undergone a hexamethyldisilazane treatment by means of a spin coater, and dried by heating on a hot plate at 100° C. for 90 seconds. Thus, resist films of 50 nm average thickness were obtained.

Each of the resist films was exposed to EUV light by means of an EUV exposure apparatus (wavelength=13.5 nm, NA=0.3). Immediately after the exposure, the film was baked on a hot plate at 110° C. for 90 seconds. The baked film was developed with a 2.38 mass % aqueous tetramethylammonium hydroxide solution at 23° C. for 30 seconds. After the development, the film was rinsed with pure water for seconds and dried. Thus, a line and space pattern (line:space=1:1) was formed.

(Sensitivity)

The thus obtained line and space pattern was observed by means of a scanning electron microscope (model S-9380 manufactured by Hitachi, Ltd.). The sensitivity (Eopt) was defined as an exposure amount in which a line of 35 nm width (line:space=1:1) was resolved.

(Roughness Characteristic; LWR)

The above 35 nm line pattern (line:space=1:1) was observed by means of a scanning electron microscope (model S-9380, manufactured by Hitachi, Ltd.). The distance between actual edge and a reference line on which edges were to be present was measured at 50 points of equal intervals within 2 μm in the longitudinal direction of the pattern. The standard deviation of measured distances was determined, and 3σ was computed therefrom. This 3∝ was denoted as “LWR (nm).”

The obtained evaluation results are given in Table 5 below.

TABLE 5

| | Sensitivity | LWR |
|---|---|---|
| Ex. | (mJ/cm²) | (nm) |
| Ex. 1 | 11.9 | 4.7 |
| Ex. 2 | 12.3 | 4.9 |
| Ex. 3 | 12.5 | 4.2 |
| Ex. 4 | 13.9 | 5.1 |
| Ex. 5 | 13.6 | 5.0 |
| Ex. 6 | 12.5 | 4.6 |
| Ex. 7 | 12.9 | 4.9 |
| Ex. 8 | 14.1 | 4.3 |
| Ex. 9 | 12.7 | 4.1 |
| Ex. 10 | 13.2 | 4.5 |
| Ex. 11 | 13.5 | 4.8 |
| Ex. 12 | 14.7 | 5.0 |
| Ex. 13 | 12.5 | 3.9 |
| Comp. Ex. 1 | 15.6 | 8.0 |
| Comp. Ex. 2 | 14.0 | 7.4 |
| Comp. Ex. 3 | 13.7 | 8.4 |
| Comp. Ex. 4 | 11.7 | 9.1 |

As apparent from Table 5, the compositions of the Examples also exhibited excellent performance upon exposure to EUV.

What is claimed is:

1. An actinic-ray- or radiation-sensitive resin composition comprising:
a resin (P) comprising a repeating unit (A) containing a group that when exposed to actinic rays or radiation, is decomposed to thereby generate an acid and a repeating unit (B) containing a group that when acted on by an acid, is decomposed to thereby increase its solubility in an alkali developer, and
any of compounds (Q) of general formula (1) below, 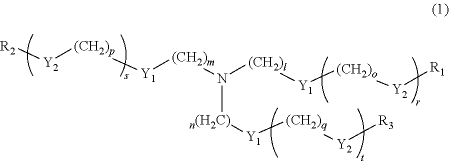
in which
each of l, m, o, p and q independently is an integer of 1 or greater,
n is an integer of 2 or greater,
each of r and s independently is an integer of 1 or greater,
t is an integer of 0 or greater,
each of —Y₁- and —Y₂— independently represents —O—, —S— or —CO—,
each of R₁ and R₂ independently represents a hydrogen atom, an alkyl group, an aryl group or an aralkyl group, and
R₃ represents a hydrogen atom, an alkyl group, an aryl group or an aralkyl group when n is 3 or greater and t is 1 or greater, and represents an alkyl group, an aryl group or an aralkyl group when n is 3 or greater and t is 0, and represents an aryl group or an aralkyl group when n is 2.

2. The composition according to claim 1, wherein the repeating unit (A) is any of repeating units of general formulae (2), (3) and (4) below, 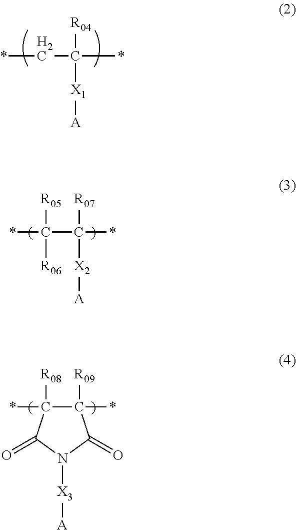
in which
each of R₀₄, R₀₅ and R₀₇ to R₀₉ independently represents a hydrogen atom, an alkyl group, a cycloalkyl group, a halogen atom, a cyano group or an alkoxycarbonyl group,
R₀₆ represents a cyano group, a carboxyl group, —CO—OR₂₅ or —CO—N(R₂₆)(R₂₇) in which R₂₆ and R₂₇ may be bonded to each other to thereby form a ring in cooperation with a nitrogen atom,
each of X₁ to X₃ independently represents a single bond, an arylene group, an alkylene group, a cycloalkylene group, —O—, —SO₂—, —CO—, —N(R₃₃)— or a bivalent connecting group comprised of a combination of these,
R₂₅ represents an alkyl group, a cycloalkyl group, an alkenyl group, an aryl group or an aralkyl group,
each of R₂₆, R₂₇ and R₃₃ independently represents a hydrogen atom, an alkyl group, a cycloalkyl group, an alkenyl group, an aryl group or an aralkyl group, and
A represents a structural moiety that when exposed to actinic rays or radiation, is decomposed to thereby generate an acid.

3. The composition according to claim 1, wherein R₁ and R₂ are hydrogen atoms.

4. The composition according to claim 3, wherein —Y₁— is —O—.

5. The composition according to claim 4, wherein —Y₂— is —O—.

6. The composition according to claim 1, wherein the repeating unit (B) is expressed by general formula (5) or (6) below, 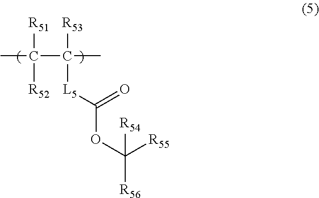
in which
each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents a single bond or a bivalent connecting group,
L₅ represents a single bond or a bivalent connecting group, provided that when a ring is formed in cooperation with R₅₂, L₅ represents a trivalent connecting group, and
R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and provided that R₅₅ and R₅₆ are not simultaneously hydrogen atoms, 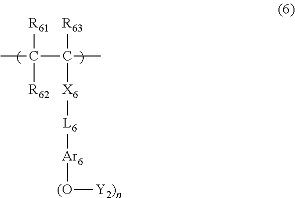
in which,
each of R₆₁, R₆₂ and R₆₃ independently represents a hydrogen atom, an alkyl group, a cycloalkyl group, a halogen atom, a cyano group or an alkoxycarbonyl group, provided that R₆₂ may be bonded to Ar₆ to thereby form a ring, which R₆₂ represents a single bond or a bivalent connecting group,
X₆ represents a single bond, —COO— or —CONR₆₄— in which R₆₄ represents a hydrogen atom or an alkyl group, provided that R₆₄ may be bonded to R₆₂ to thereby form a ring, which R₆₄ represents a single bond or a bivalent connecting group,
L₆ represents a single bond or an alkylene group,
Ar₆ represents a (n+1)-valent aromatic ring group, provided that Ar₆ may be bonded to R₆₂ to thereby form a ring, which Ar₆ represents a (n+2)-valent aromatic ring group,
Y₂, when n≧2 each independently, represents a hydrogen atom or a group that when acted on by an acid, is cleaved, provided that at least one of Y₂s is a group that when acted on by an acid, is cleaved, and
n is an integer of 1 to 4.

7. The composition according to claim 1, wherein the resin (P) further comprises any of repeating units (C) of general formula (7) below, 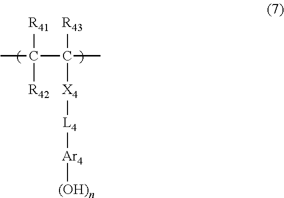
in which
each of R₄₁, R₄₂ and R₄₃ independently represents a hydrogen atom, an alkyl group, a halogen atom, a cyano group or an alkoxycarbonyl group,
X₄ represents a single bond, —COO— or —CONR₆₄— in which R₆₄ represents a hydrogen atom or an alkyl group,
L₄ represents a single bond or an alkylene group,
Ar₄ represents a (n+1)-valent aromatic ring group, provided that Ar₄ may be bonded to R₄₂ to thereby form a ring, which Ar₄ represents a (n+2)-valent aromatic ring group, and
n is an integer of 1 to 4.

8. The composition according to claim 7, wherein the repeating unit (C) has a hydroxystyrene structure.

9. The composition according to claim 1, further comprising a basic compound other than the compounds (Q).

10. The composition according to claim 9, wherein the basic compound contains no hydroxyl group.

11. The composition according to claim 1 for use in a pattern formation including exposure by EUV.

12. An actinic-ray- or radiation-sensitive resin film formed from the composition according to claim 1.

13. A method of forming a pattern, comprising:
exposing the film according to claim 12 to light, and
developing the exposed film.

14. The method according to claim 13, wherein the exposure is carried out by EUV light.
